(19) United States
(12) Patent Application Publication
(10) Pub. No.: US 2016/0233444 A1
(43) Pub. Date: Aug. 11, 2016

(54) POLYCYCLIC PHENYLPYRIDINE IRIDIUM COMPLEXES AND DERIVATIVES THEREOF FOR OLEDS

(71) Applicant: MERCK PATENT GMBH, Darmstadt (DE)

(72) Inventors: Anna Hayer, Mainz (DE); Dominik Joosten, Frankfurt Am Main (DE); Holger Heil, Frankfurt Am Main (DE); Rémi Manouk Anémian, Seoul (KR); Claire Nonancourt, Loupmont (FR)

(73) Assignee: Merck Patent GmbH, Darmstadt (DE)

(21) Appl. No.: 15/022,231

(22) PCT Filed: Aug. 19, 2014
(86) PCT No.: PCT/EP2014/002276

§ 371 Date: Mar. 16, 2016

(30) Foreign Application Priority Data
Sep. 17, 2013 (EP) 13004552.9

(51) Int. Cl. H01L 51/00; C09K 11/02; C07F 15/00; C09K 11/06

(52) U.S. Cl. CPC H01L 51/0085; C09K 11/06; C09K 11/025; H01L 51/0067; H01L 51/0056; C07F 15/0033; H01L 51/5016

(57) ABSTRACT

The present invention relates to metal complexes for use in electronic devices, and to electronic devices, especially organic electroluminescent devices, comprising these metal complexes, especially as emitters. The compounds claimed have the formula: M(L)ₙ(L′)ₘ formula (1), where the compound of the general formula (1) contains a substructure M(L)ₙ of the formula (2) or formula (3), where A is the same or different at each instance and is a group of the formula (A) which follows. Also claimed are processes for preparing such compounds, one of which is shown by way of example (I).

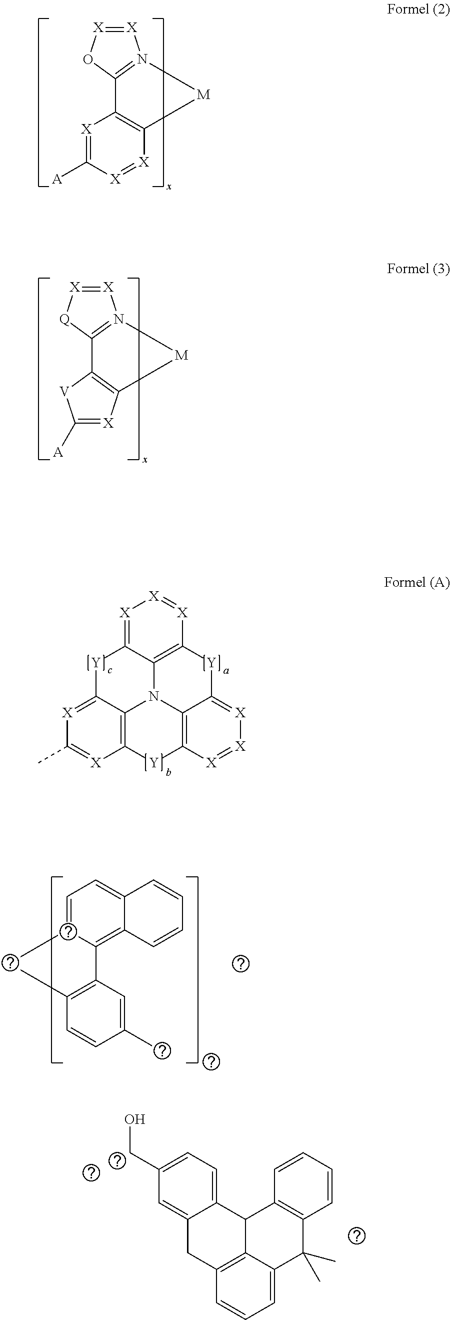

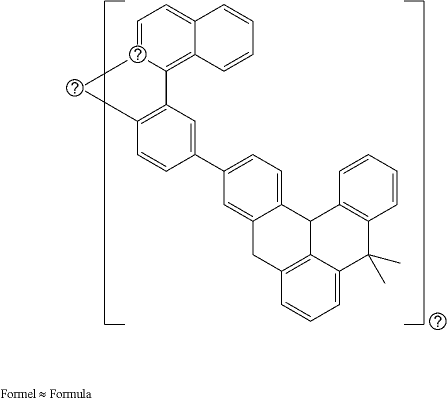

The present invention relates to metal complexes for use in electronic devices and to electronic devices, especially organic electroluminescent devices, comprising these metal complexes, especially as emitters.

The structure of organic electroluminescent devices (OLEDs) in which organic semiconductors are used as functional materials is described, for example, in U.S. Pat. No. 4,539,507, U.S. Pat. No. 5,151,629, EP 0676461 and WO 98/27136. The emitting materials used are frequently phosphorescent organometallic complexes. For quantum-mechanical reasons, up to four times the energy efficiency and power efficiency is possible using organometallic compounds as phosphorescent emitters. In general terms, there is still a need for improvement in OLEDs which exhibit triplet emission, especially with regard to efficiency, operating voltage and lifetime. Furthermore, many phosphorescent emitters do not have a high solubility for processing from solution, and so there is further need for improvement here too.

Triplet emitters used in phosphorescent OLEDs, are especially iridium complexes and platinum complexes, which are typically used in the form of cyclometalated complexes. The ligands here are frequently derivatives of phenylpyridine for green and yellow emission, or derivatives of phenylquinoline or phenylisoquinoline for red emission. However, the solubility of such complexes is frequently low, which complicates or entirely prevents processing from solution.

The prior art discloses iridium complexes substituted on the phenyl ring of the phenylpyridine ligand in the para-position to the coordination to the metal by an optionally substituted carbazole group (WO 2012/007103, WO 2013/072740) or indenocarbazole group (WO 2011/141120). However, there is still further need for improvement here too in relation to the solubility and color purity, i.e. the breadth of the emission, and the photoluminescence quantum efficiency of the complexes.

It has been found that, surprisingly, particular metal chelate complexes described in detail below have an improved color purity of emission. In addition, these complexes have good solubility and exhibit good properties with regard to efficiency and lifetime when used in an organic electroluminescent device. The present invention therefore provides these metal complexes and organic electroluminescent devices comprising these complexes.

The invention thus provides a compound of formula (1)

M(L)ₙ(L′)ₘ formula (1)

where the compound of the general formula (1) contains a substructure M(L)ₙ of the formula (2) or formula (3):

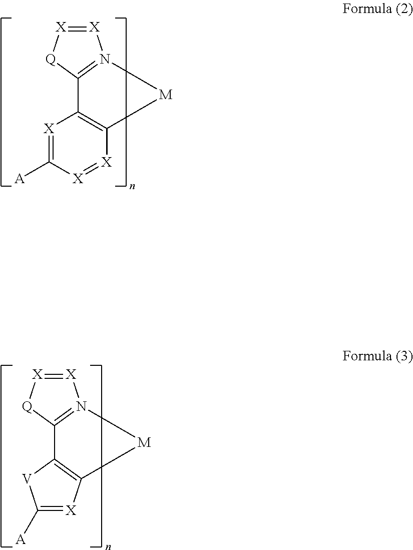

where A is the same or different at each instance and is a group of the following formula (A):

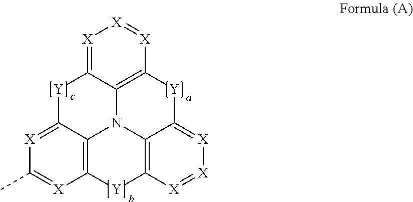

where the dotted bond in formula (A) represents the position of the linkage of this group and the further symbols and indices used are as follows:
M is a metal selected from the group consisting of iridium, rhodium, platinum and palladium;
X is the same or different at each instance and is CR¹ or N;
Q is the same or different at each instance and is R¹C═CR¹, R¹C═N, O, S, Se or NR¹;
V is the same or different at each instance and is O, S, Se or NR¹;
Y is the same or different at each instance and is a single bond or a bivalent group selected from C(R¹)₂, C(═O), O, S, NR¹ and BR¹;
R¹ is the same or different at each instance and is H, D, F, Cl, Br, I, N(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 40 carbon atoms or a straight-chain alkenyl or alkynyl group having 2 to 40 carbon atoms or a branched or cyclic alkyl, alkenyl, alkynyl, alkoxy or thioalkoxy group having 3 to 40 carbon atoms, each of which may be substituted by one or more R² radicals, where one or more nonadjacent CH₂ groups may be replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more hydrogen atoms may be replaced by D, F, Cl, Br, I, CN or NO₂, or an aromatic or heteroaromatic ring system which has 5 to 60 aromatic ring atoms and may be substituted in each case by one or more R² radicals, or an aryloxy or heteroaryloxy group which has 5 to 60 aromatic ring atoms and may be substituted by one or more R² radicals, or a diarylamino group, diheteroarylamino group or arylheteroarylamino group which has 10 to 40 aromatic ring atoms and may be substituted by one or more R² radicals, or a combination of two or more of these groups; at the same time, two or more R¹ radicals together may also form a mono- or polycyclic, aliphatic, aromatic and/or benzofused ring system;
R² is the same or different at each instance and is H, D, F, Cl, Br, I, N(R³)₂, CN, NO₂, Si(R³)₃, B(OR³)₂, C(═O)R³, P(═O)(R³)₂, S(═O)R³, S(═O)₂R³, OSO₂R³, a straight-chain alkyl, alkoxy or thioalkoxy group having 1 to 40 carbon atoms or a straight-chain alkenyl or alkynyl group having 2 to 40 carbon atoms or a branched or cyclic alkyl, alkenyl, alkynyl, alkoxy or thioalkoxy group having 3 to 40 carbon atoms, each of which may be substituted by one or more R³ radicals, where one or more nonadjacent CH₂ groups may be replaced by R³C═CR³, C≡C, Si(R³)₂, Ge(R³)₂, Sn(R³)₂, C═O, C═S, C═Se, C═NR³, P(═O)(R³), SO, SO₂, NR³, O, S or CONR³ and where one or more hydrogen atoms may be replaced by D, F, Cl, Br, I, CN or NO₂, or an aromatic or heteroaromatic ring system which has 5 to 60 aromatic ring atoms and may be substituted in each case by one or more R³ radicals, or an aryloxy or heteroaryloxy group which has 5 to 60 aromatic ring atoms and may be substituted by one or more R³ radicals, or a diarylamino group, diheteroarylamino group or arylheteroarylamino group which has 10 to 40 aromatic ring atoms and may be substituted by one or more R³ radicals, or a combination of two or more of these groups; at the same time, two or more adjacent R² radicals together may form a mono- or polycyclic, aliphatic, aromatic and/or benzofused ring system;
R³ is the same or different at each instance and is H, D, F or an aliphatic, aromatic and/or heteroaromatic hydrocarbyl radical having 1 to 20 carbon atoms, in which one or more hydrogen atoms may also be replaced by F; at the same time, two or more R³ substituents together may also form a mono- or polycyclic aliphatic, aromatic and/or benzofused ring system;
L′ is the same or different at each instance and is a coligand;
n is 1, 2 or 3 when M is iridium or rhodium and is 1 or 2 when M is platinum or palladium;
m is 0, 1, 2, 3 or 4;
a, b, c is the same or different at each instance and is 0 or 1, where a=0 or b=0 or c=0 means that the respective Y group is absent and, instead, an R¹ radical is bonded to the corresponding carbon atoms in each case,
   with the proviso that a+b+c≧2;
   at the same time, it is also possible for two or more ligands L to be joined to one another or for L to be joined to L′ via any bridge Z, thus forming a tridentate, tetradentate, pentadentate or hexadentate ligand system.

In this compound, the indices n and m are chosen such that the coordination number on the metal when M is iridium or rhodium corresponds to 6, and when M is platinum or palladium corresponds to 4.

An aryl group in the context of this invention contains 6 to 40 carbon atoms; a heteroaryl group in the context of this invention contains 2 to 40 carbon atoms and at least one heteroatom, with the proviso that the sum total of carbon atoms and heteroatoms is at least 5. The heteroatoms are preferably selected from N, O and/or S. An aryl group or heteroaryl group is understood here to mean either a simple aromatic cycle, i.e. benzene, or a simple heteroaromatic cycle, for example pyridine, pyrimidine, thiophene, etc., or a fused aryl or heteroaryl group, for example naphthalene, anthracene, phenanthrene, quinoline, isoquinoline, etc.

An aromatic ring system in the context of this invention contains 6 to 60 carbon atoms in the ring system. A heteroaromatic ring system in the context of this invention contains 2 to 60 carbon atoms and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for two or more aryl or heteroaryl groups to be interrupted by a nonaromatic unit (preferably less than 10% of the atoms other than H), for example an sp³-hybridized carbon, nitrogen or oxygen atom or a carbonyl group. For example, systems such as 9,9′-spirobifluorene, 9,9-diarylfluorene, triarylamine, diaryl ethers, stilbene, etc. are also to be regarded as aromatic ring systems in the context of this invention, and likewise systems in which two or more aryl groups are interrupted, for example, by a linear or cyclic alkyl group or by a silyl group.

A cyclic alkyl, alkoxy or thioalkoxy group in the context of this invention is understood to mean a monocyclic, bicyclic or polycyclic group.

In the context of the present invention, a C₁- to C₄₀-alkyl group in which individual hydrogen atoms or CH₂ groups may be replaced by the abovementioned groups are understood, for example, to mean the methyl, ethyl, n-propyl, i-propyl, n-butyl, i-butyl, s-butyl, t-butyl, 2-methylbutyl, n-pentyl, s-pentyl, tert-pentyl, 2-pentyl, neopentyl, cyclopentyl, n-hexyl, s-hexyl, tert-hexyl, 2-hexyl, 3-hexyl, neohexyl, cyclohexyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, trifluoromethyl, pentafluoroethyl or 2,2,2-trifluoroethyl radicals. An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is understood to mean, for example, ethynyl, propynyl, butynyl, pentynyl, hexynyl, heptynyl or octynyl. A C₁- to C₄₀-alkoxy group is understood to mean, for example, methoxy, trifluoromethoxy, ethoxy, n-propoxy, i-propoxy, n-butoxy, i-butoxy, s-butoxy, t-butoxy or 2-methylbutoxy. An aromatic or heteroaromatic ring system which has 5-60 aromatic ring atoms and may also be substituted in each case by the abovementioned R radicals and which may be joined to the aromatic or heteroaromatic system via any desired positions is understood to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

When two adjacent R¹ or R² radicals together form a ring system, the ring systems formed are aliphatic or aromatic rings fused onto the ligands. Examples of such ring systems are fused-on cyclohexyl groups or fused-on phenyl groups. It is also possible here that radicals which bind to the two different aromatic rings of the ligand, i.e., for example, to the phenyl group and the pyridine group, together form a ring, which can lead, for example, to azafluorene structures or benzo[h]quinoline structures. In addition, it is possible, for example, when Q is CR¹═CR¹, that these radicals together form an aromatic ring, such that, for example, an isoquinoline structure is formed overall.

Preference is given to compounds of formula (1), characterized in that they are uncharged, i.e. electrically neutral. This is achieved in a simple manner by selecting the charge of the ligands L and L′ such that they compensate for the charge of the complexed metal atom M.

Preference is further given to compounds of formula (1) characterized in that the sum total of the valence electrons around the metal atom is 16 for platinum and palladium, and 18 for iridium or rhodium. The reason for this preference is the exceptional stability of these metal complexes.

In a preferred embodiment of the invention, M is iridium or platinum. More preferably, M is iridium.

When M is platinum or palladium, the index n is 1 or 2. When the index n=1, one bidentate or two monodentate ligands L′, preferably one bidentate ligand L′, are also coordinated to the metal M. Correspondingly, for one bidentate ligand L′, the index m=1, and for two monodentate ligands L′, the index m=2. When the index n=2, the index m=0.

When M is iridium or rhodium, the index n is 1, 2 or 3, preferably 2 or 3. When the index n=1, four monodentate or two bidentate or one bidentate and two monodentate or one tridentate and one monodentate or one tetradentate ligand L′, preferably two bidentate ligands L′, are also coordinated to the metal. Correspondingly, the index m, according to the ligand L′, is 1, 2, 3 or 4. When the index n=2, one bidentate or two monodentate ligands L′, preferably one bidentate ligand L′, are also coordinated to the metal. Correspondingly, the index m, according to the ligand L′, is 1 or 2. When the index n=3, the index m=0.

In a preferred embodiment of the invention, not more than one symbol X per cycle is N and the other symbols X are CR¹. More preferably, the symbol X is the same or different at each instance and is CR¹.

In a further preferred embodiment of the invention, the symbol Q is the same or different at each instance and is R¹C═CR¹ or R¹C═N, more preferably R¹C═CR¹.

In a further preferred embodiment of the invention, the symbol V is the same or different at each instance and is O, S or NR¹, more preferably S.

In a further preferred embodiment of the invention, in the group of the formula (A), two of the indices a, b and c=1 and the third index=0. Suitable combinations here are as follows:

a=b=1 and c=0; or
b=c=1 and a=0.

In a particularly preferred embodiment of the invention, a=b=1 and c=0.

In a further preferred embodiment of the invention, the symbol Y is the same or different at each instance and is a single bond or a bivalent group selected from C(R¹)₂, NR¹ and O, where preferably not more than one of the Y groups is a single bond.

Preferred A groups are the groups of the following formulae (A-1), (A-2) and (A-3):

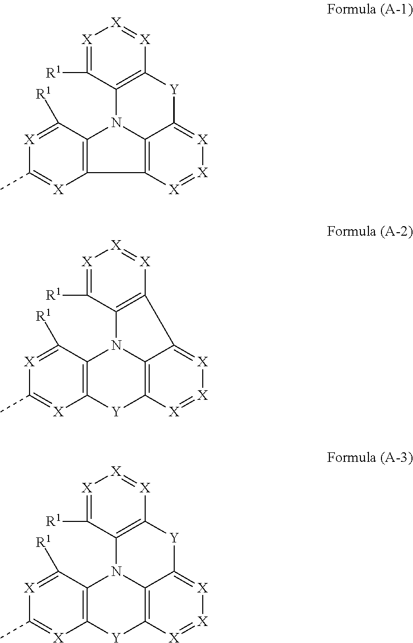

where Y is C(R¹)₂, NR¹, O or S and the further symbols used have the definitions given above.

Particularly preferred embodiments of the A group are the structures of the following formulae (A-1a), (A-2a) and (A-3a):

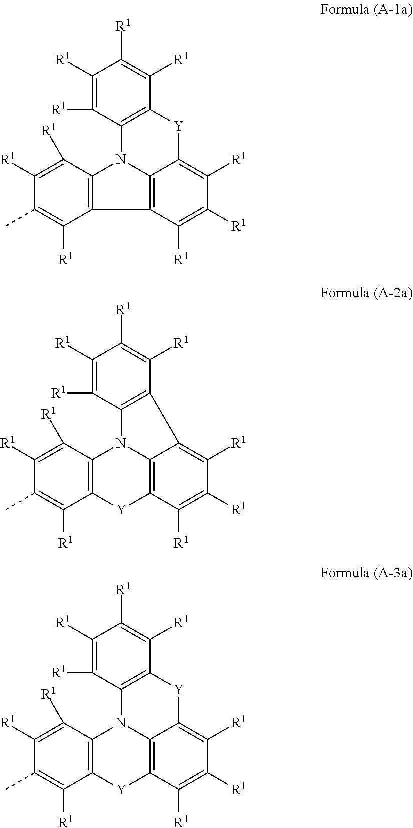

where Y is C(R¹)₂, NR¹ or O and the further symbols used have the definitions given above.

Very particularly preferred embodiments of the A group are the structures of the following formulae (A-1b), (A-2b) and (A-3b):

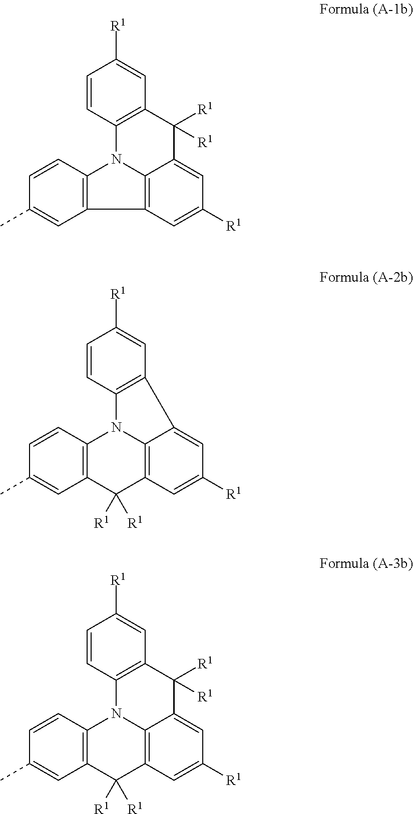

where the symbols used have the definitions given above.

It is particularly preferable when the abovementioned preferences apply simultaneously. In a particularly preferred embodiment of the invention, therefore, the symbols used are as follows:
M is iridium or platinum;
A is the same or different at each instance and is a group of the abovementioned formula (A-1a) or (A-2a) or (A-3a);
X is the same or different at each instance and is CR¹;
Q is the same or different at each instance and is R¹C═CR¹ or R¹C═N;
V is the same or different at each instance and is O, S or NR¹;
Y is the same or different at each instance and is C(R¹)₂, NR¹ or O.

In a very particularly preferred embodiment of the invention, the symbols used are as follows:
M is iridium;
A is the same or different at each instance and is a group of the abovementioned (A-1b) or (A-2b) or (A-3b);
X is the same or different at each instance and is CR¹;
Q is the same or different at each and is R¹C═CR¹;
V is S;
Y is the same or different at each instance and is C(R¹)₂, NR¹ or O.

In a particularly preferred embodiment of the invention, the substructures of the formula (2) and (3) are therefore selected from the substructures of the following formulae (4) and (5):

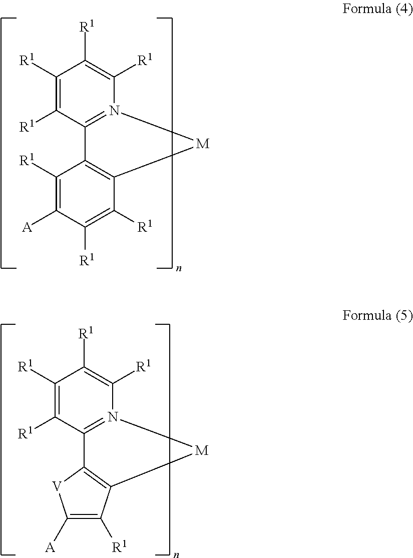

where the symbols and indices used have the definitions given above, especially the preferred definitions given above.

As already mentioned above, it is also possible here for adjacent R¹ radicals to form a ring with one another. For example, quinoline or isoquinoline structures which may be substituted by one or more R² radicals are obtainable from the pyridine rings, or the two coordinating cycles are bridged to one another.

Preferred structures which arise by virtue of adjacent R¹ radicals together forming a ring are the structures of the following formulae (4-1), (4-2), (4-3), (4-4), (5-1), (5-2) and (5-3):

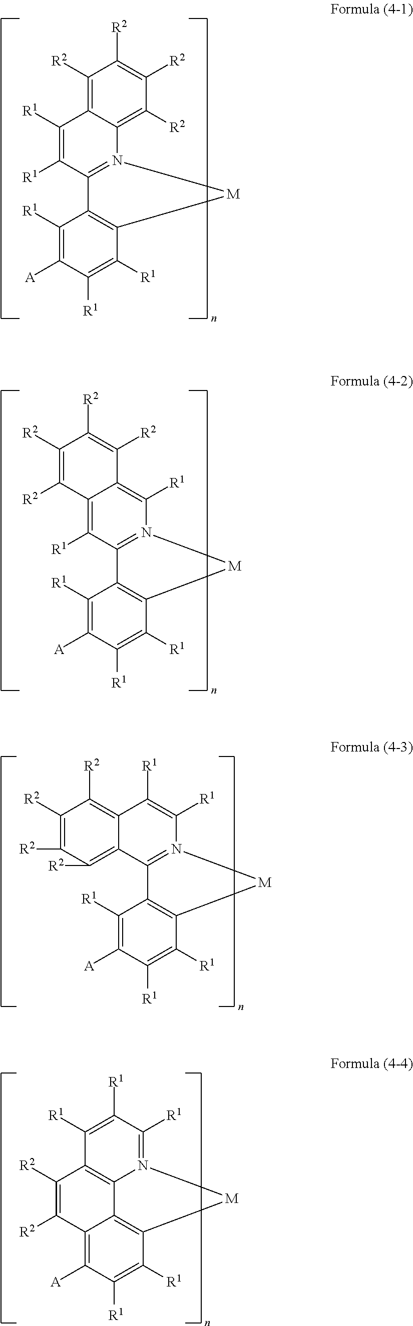

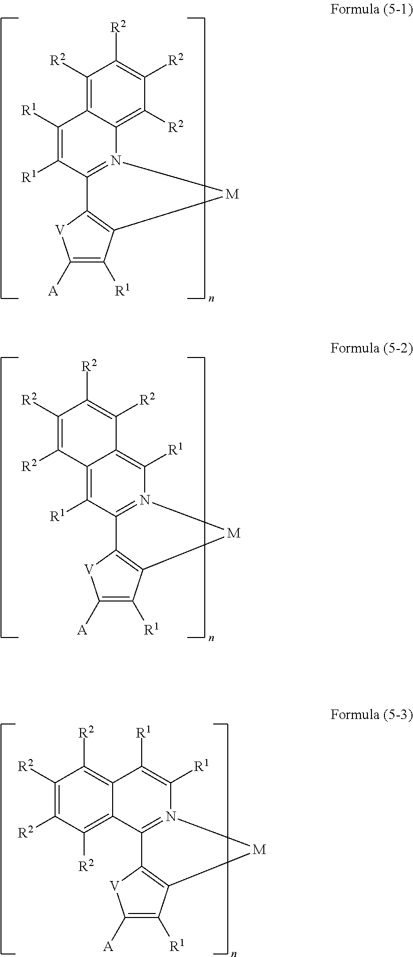

where the symbols and indices used have the definitions given above.

At the same time, in the structures of formula (4) or (4-1) to (4-4) and (5) or (5-1) to (5-3), the A group is preferably selected from the structures of the formulae (A-1a) or (A-2a) or (A-3a) and more preferably from the structures of the formulae (A-1b) or (A-2b) or (A-3b).

It may be preferable when one of the R¹ radicals, either in the compounds of the formula (4), (4-1) to (4-4), (5) and (5-1) to (5-3) or in the A groups of the formula (A), is a styryl group or a terminal alkenyl group. Groups of this kind are suitable for the crosslinking of the compounds of the invention in the layer. Such crosslinking may be advisable in order to be able to produce multilayer devices from solution.

As described above, instead of one of the R¹ radicals, it is also possible for a bridging Z unit to be present, which joins this ligand L to one or more further ligands L or L′. In a preferred embodiment of the invention, instead of one of the R¹ radicals, a bridging Z unit is present, such that the ligands have tridentate or polydentate or polypodal character. It is also possible for two bridging Z units of this kind to be present. This leads to the formation of macrocyclic ligands or to the formation of cryptates.

Preferred structures having polydentate ligands are the metal complexes of the following formulae (6) to (9):

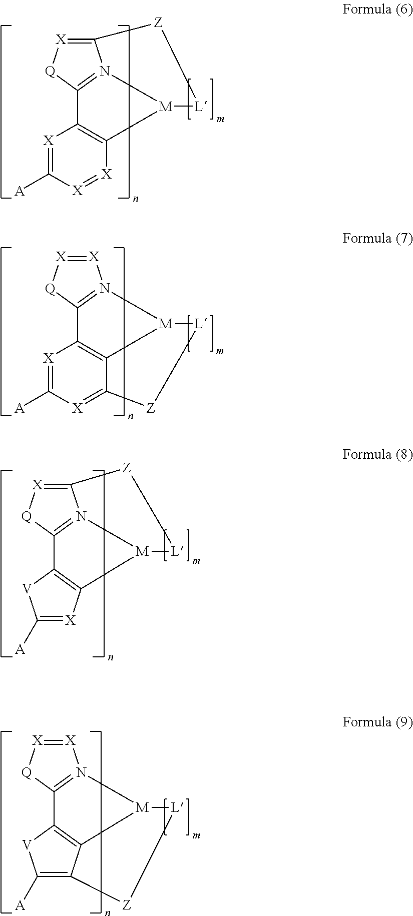

where the symbols used have the definitions given above and Z is preferably a bridging unit containing 1 to 80 atoms from the third, fourth, fifth and/or sixth main group (group 13, 14, 15 or 16 according to IUPAC) or a 3- to 6-membered homo- or heterocycle which covalently bonds the subligands L to one another or L to L′. In this case, the bridging V unit may also have an unsymmetric structure, meaning that the linkage of Z to L and L′ need not be identical. The bridging Z unit may be uncharged, singly, doubly or triply negatively charged, or singly, doubly or triply positively charged. Preferably, Z is uncharged or singly negatively or singly positively charged. In this case, the charge of Z is preferably chosen so as to result in an uncharged complex overall.

The exact structure and chemical composition of the Z group does not have any significant influence on the electronic properties of the complex, since the function of this group is essentially to increase the chemical and thermal stability of the complexes by the bridging of L to one another or to L′.

When Z is a trivalent group, i.e. bridges three ligands L to one another or two ligands L to L′ or one ligand L to two ligands L′, Z is preferably the same or different at each instance and is selected from the group consisting of B, B(R²)⁻, B(C(R²)₂)₃, (R²)B(C(R²)₂)₃⁻, B(O)₃, (R²)B(O)₃⁻, B(C(R²)₂C(R²)₂)₃, (R²)B(C(R²)₂C(R²)₂)₃⁻, B(C(R²)₂O)₃, (R²)B(C(R²)₂O)₃⁻, B(OC(R²)₂)₃, (R²)B(OC(R²)₂)₃⁻, C(R²), CO⁻, CN(R²)₂, (R²)C(C(R²)₂)₃, (R²)C(O)₃, (R²)C(C(R²)₂C(R²)₂)₃, (R²)C(C(R²)₂O)₃, (R²)C(OC(R²)₂)₃, (R²)C(Si(R²)₂)₃, (R²)C(Si(R²)₂C(R²)₂)₃, (R²)C(C(R²)₂Si(R²)₂)₃, Si(R²), (R²)Si(C(R²)₂)₃, (R²)Si(O)₃, (R²)Si(C(R²)₂C(R²)₂)₃, (R²)Si(OC(R²)₂)₃, (R²)Si(C(R²)₂O)₃, N, NO, N(R²)⁺, N(C(R²)₂)₃, (R²)N(C(R²)₂)₃⁺, N(C═O)₃, N(C(R²)₂C(R²)₂)₃, (R²)N(C(R²)₂C(R²)₂), P, PO, P(O)₃, PO(O)₃, P(OC(R²)₂)₃, PO(OC(R²)₂)₃, P(C(R²)₂)₃, P(R²)(C(R²)₂)₃⁺, PO(C(R²)₂)₃, P(C(R²)₂C(R²)₂)₃, PO(C(R²)₂C(R²)₂)₃,

or a unit of formula (10), (11), (12) or (13)

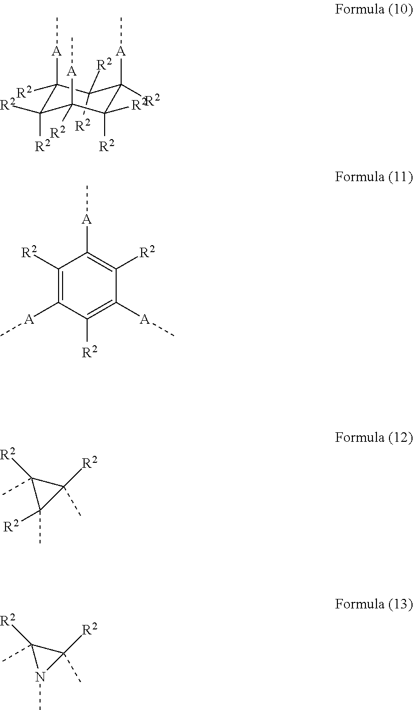

where the dotted bonds each indicate the bond to the subligands L or L′ and A is the same or different at each instance and is selected from the group consisting of a single bond, O, S, S(═O), S(═O)₂, NR², PR², P(═O)R², P(═NR²), C(R²)₂, C(═O), C(═NR²), C(═C(R²)₂), Si(R²)₂ and BR². The further symbols used are as defined above.

When Z is a bivalent group, i.e. bridges two ligands L to one another or one ligand L to L′, Z is preferably the same or different at each instance and is selected from the group consisting of BR², C(R²)₂, C(═O), Si(R²)₂, NR², PR², P(═O)(R²), O, S and a unit of formula (14) to (22)

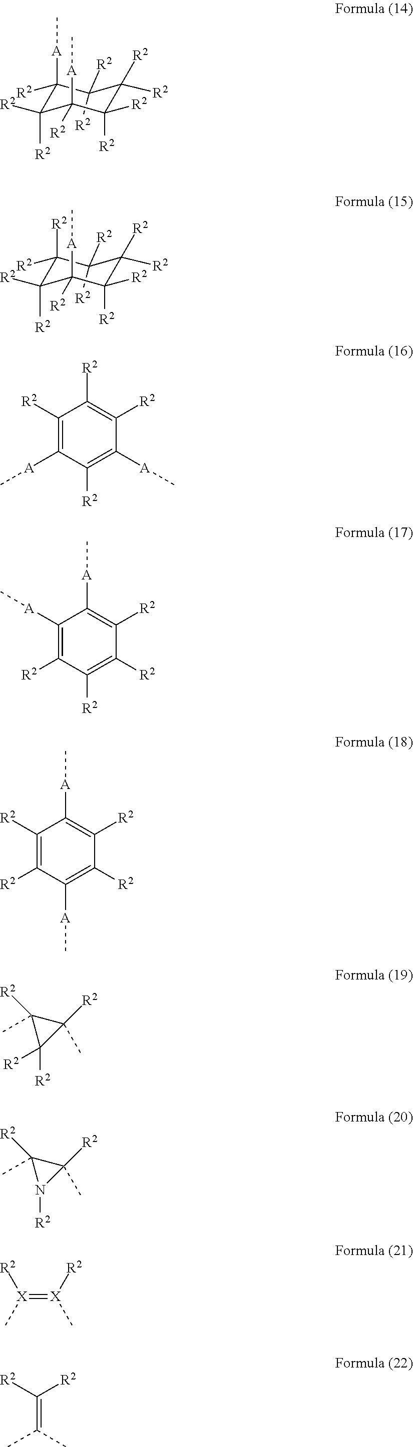

where the dotted bonds each indicate the bond to the subligands L or L′ and the further symbols used each have the meanings detailed above.

There follows a description of preferred ligands L′ as occur in formula (1). It is also possible to choose the ligand groups L′ correspondingly when they are bonded to L via a bridging Z unit.

The ligands L′ are preferably uncharged, monoanionic, dianionic or trianionic ligands, more preferably uncharged or monoanionic ligands. They may be monodentate, bidentate, tridentate or tetradentate and are preferably bidentate, i.e. preferably have two coordination sites. As described above, the ligands L′ may also be bonded to L via a bridging Z group.

Preferred uncharged monodentate ligands L′ are selected from carbon monoxide, nitrogen monoxide, alkyl cyanides, for example acetonitrile, aryl cyanides, for example benzonitrile, alkyl isocyanides, for example methyl isonitrile, aryl isocyanides, for example benzoisonitrile, amines, for example trimethylamine, triethylamine, morpholine, phosphines, especially halophosphines, trialkylphosphines, triarylphosphines or alkylarylphosphines, for example trifluorophosphine, trimethylphosphine, tricyclohexylphosphine, tri-tert-butylphosphine, triphenylphosphine, tris(pentafluorophenyl)phosphine, phosphites, for example trimethyl phosphite, triethyl phosphite, arsines, for example trifluoroarsine, trimethylarsine, tricyclohexylarsine, tri-tert-butylarsine, triphenylarsine, tris(pentafluorophenyl)arsine, stibines, for example trifluorostibine, trimethylstibine, tricyclohexylstibine, tri-tert-butylstibine, triphenylstibine, tris(pentafluorophenyl)stibine, nitrogen-containing heterocycles, for example pyridine, pyridazine, pyrazine, pyrimidine, triazine, and carbenes, especially Arduengo carbenes.

Preferred monoanionic monodentate ligands L′ are selected from hydride, deuteride, the halides F⁻, Cl⁻, Br⁻ and I⁻, alkylacetylides, for example methyl-C≡C⁻, tert-butyl-C≡C⁻, arylacetylides, for example phenyl-C≡C⁻, cyanide, cyanate, isocyanate, thiocyanate, isothiocyanate, aliphatic or aromatic alkoxides, for example methoxide, ethoxide, propoxide, iso-propoxide, tert-butoxide, phenoxide, aliphatic or aromatic thioalkoxides, for example methanethiolate, ethanethiolate, propanethiolate, iso-propanethiolate, tert-thiobutoxide, thiophenoxide, amides, for example dimethylamide, diethylamide, di-iso-propylamide, morpholide, carboxylates, for example acetate, trifluoroacetate, propionate, benzoate, aryl groups, for example phenyl, naphthyl, and anionic nitrogen-containing heterocycles such as pyrrolide, imidazolide, pyrazolide. At the same time, the alkyl groups in these groups are preferably C₁-C₂₀-alkyl groups, more preferably C₁-C₁₀-alkyl groups, most preferably C₁-C₄-alkyl groups. An aryl group is also understood to mean heteroaryl groups. These groups are as defined above.

Preferred di- or trianionic ligands are O²⁻, S²⁻, carbides which lead to a coordination of the R—C≡M form, and nitrenes which lead to a coordination of the R—N=M form, where R is generally a substituent, or N³⁻.

Preferred uncharged or mono- or dianionic, bidentate or higher polydentate ligands L′ are selected from diamines, for example ethylenediamine, N,N,N′,N′-tetramethylethylenediamine, propylenediamine, N,N,N′,N′-tetramethylpropylenediamine, cis- or trans-diaminocyclohexane, cis- or trans-N,N,N′,N′-tetramethyldiaminocyclohexane, imines, for example 2-[(1-(phenylimino)ethyl]pyridine, 2-[(1-(2-methylphenylimino)ethyl]pyridine, 2-[(1-(2,6-di-iso-propylphenylimino)ethyl]pyridine, 2-[(1-(methylimino)ethyl]pyridine, 2-[(1-(ethylimino)ethyl]pyridine, 2-[(1-(iso-propylimino)ethyl]pyridine, 2-[(1-(tert-butylimino)ethyl]pyridine, diimines, for example 1,2-bis(methylimino)ethane, 1,2-bis(ethylimino)ethane, 1,2-bis(iso-propylimino)ethane, 1,2-bis(tert-butylimino)ethane, 2,3-bis(methylimino)butane, 2,3-bis(ethylimino)butane, 2,3-bis(iso-propylimino)butane, 2,3-bis(tert-butylimino)butane, 1,2-bis(phenylimino)ethane, 1,2-bis(2-methylphenylimino)ethane, 1,2-bis(2,6-di-iso-propylphenylimino)ethane, 1,2-bis(2,6-di-tert-butylphenylimino)ethane, 2,3-bis(phenylimino)butane, 2,3-bis(2-methylphenylimino)butane, 2,3-bis(2,6-di-iso-propylphenylimino)butane, 2,3-bis(2,6-di-tert-butylphenylimino)butane, heterocycles containing two nitrogen atoms, for example 2,2′-bipyridine, o-phenanthroline, diphosphines, for example bis(diphenylphosphino)methane, bis(diphenylphosphino)ethane, bis(diphenylphosphino)propane, bis(diphenylphosphino)butane, bis(dimethylphosphino)methane, bis(dimethylphosphino)ethane, bis(dimethylphosphino)propane, bis(diethylphosphino)methane, bis(diethylphosphino)ethane, bis(diethylphosphino)propane, bis(di-tert-butylphosphino)methane, bis(di-tert-butylphosphino)ethane, bis(tert-butylphosphino)propane, 1,3-diketonates derived from 1,3-diketones, for example acetylacetone, benzoylacetone, 1,5-diphenylacetylacetone, dibenzoylmethane, bis(1,1,1-trifluoroacetyl)methane, 3-ketonates derived from 3-ketoesters, for example ethyl acetoacetate, carboxylates derived from aminocarboxylic acids, for example pyridine-2-carboxylic acid, quinoline-2-carboxylic acid, glycine, N,N-dimethylglycine, alanine, N,N-dimethylaminoalanine, salicyliminates derived from salicylimines, for example methylsalicylimine, ethylsalicylimine, phenylsalicylimine, dialkoxides derived from dialcohols, for example ethylene glycol, 1,3-propylene glycol, and dithiolates derived from dithiols, for example ethylene-1,2-dithiol, propylene-1,3-dithiol.

Preferred tridentate ligands are borates of nitrogen-containing heterocycles, for example tetrakis(1-imidazolyl)borate and tetrakis(1-pyrazolyl)borate.

Particular preference is further given to bidentate monoanionic ligands L′ having, together with the metal, a cyclometalated five-membered ring or six-membered ring having at least one metal-carbon bond, especially a cyclometalated five-membered ring. These are especially ligands as generally used in the field of phosphorescent metal complexes for organic electroluminescent devices, i.e. ligands of the phenylpyridine, naphthylpyridine, phenylquinoline, phenylisoquinoline type, etc., each of which may be substituted by one or more R¹ radicals. The person skilled in the art in the field of phosphorescent electroluminescent devices is aware of a multitude of such ligands, and will be able without exercising inventive skill to select further ligands of this kind as ligand L′ for compounds of formula (1). It is generally the case that a particularly suitable combination for the purpose is that of two groups as shown by the formulae (23) to (50) which follow, where one group binds via an uncharged nitrogen atom or a carbene atom and the other group via a negatively charged carbon atom or a negatively charged nitrogen atom. The ligand L′ can then be formed from the groups of the formulae (23) to (50) by virtue of these groups each binding to one another at the position indicated by #. The positions at which the groups coordinate to the metal are indicated by *. These groups may also be bonded to the ligands L via one or two bridging Z units.

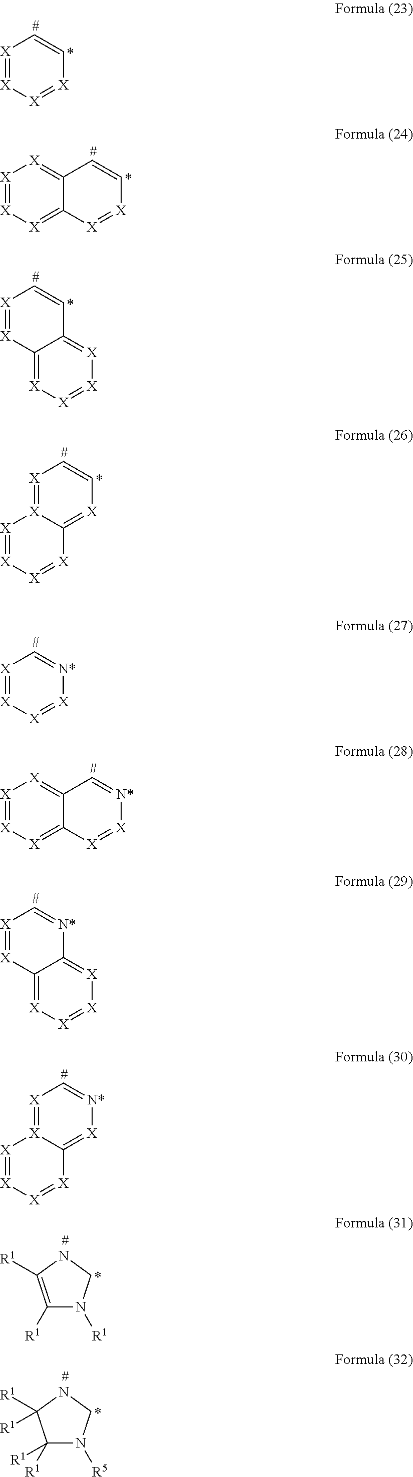

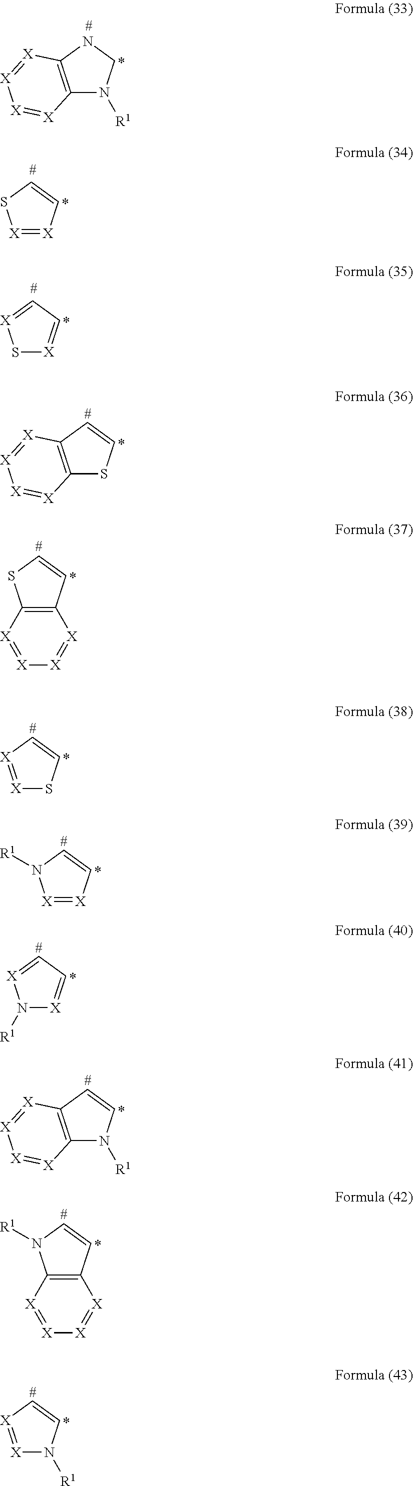

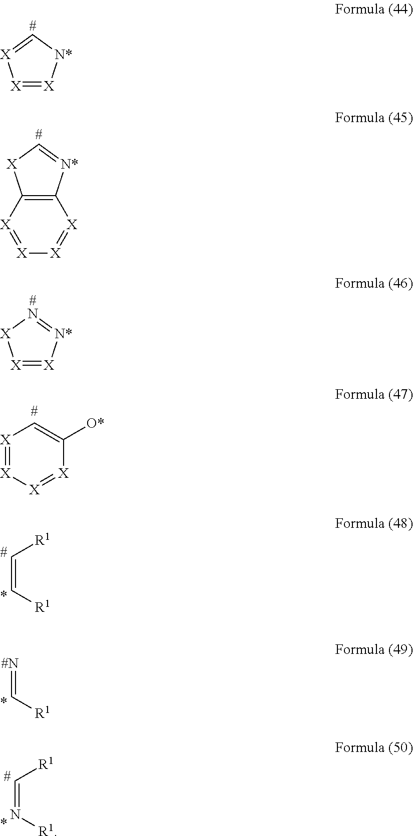

In these formulae, the symbols used have the same meaning as described above, and preferably not more than three X symbols in each group are N, more preferably not more than two X symbols in each group are N, and even more preferably not more than one X symbol in each group is N. Especially preferably, all X symbols are the same or different at each instance and are CR¹. In addition, the groups of formula (34) to (38) may also contain O rather than S.

Likewise preferred ligands L′ are η⁵-cyclopentadienyl, η⁵-pentamethylcyclopentadienyl, η⁶-benzene or η⁷-cycloheptatrienyl, each of which may be substituted by one or more R¹ radicals.

Likewise preferred ligands L′ are 1,3,5-cis-cyclohexane derivatives, especially of the formula (51), 1,1,1-tri(methylene)methane derivatives, especially of the formula (52), and 1,1,1-trisubstituted methanes, especially of the formula (53) and (54)

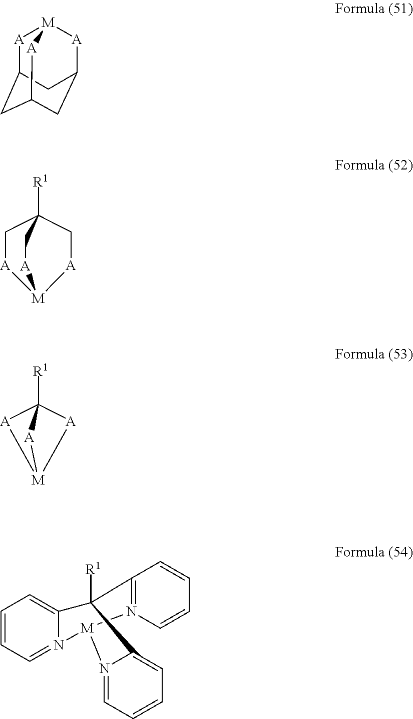

where, in each of the formulae, the coordination to the metal M is shown, R¹ is as defined above and A is the same or different at each instance and is O⁻, S⁻, COO⁻, P(R¹)₂ or N(R¹)₂.

Preferred R¹ radicals in the structures listed above and in the preferred embodiments mentioned above are the same or different at each instance and are selected from the group consisting of H, D, F, Br, N(R²)₂, CN, B(OR²)₂, C(═O)R², P(═O)(R²)₂, a straight-chain alkyl group having 1 to 10 carbon atoms or a straight-chain alkenyl or alkynyl group having 2 to 10 carbon atoms or a branched or cyclic alkyl, alkenyl or alkynyl group having 3 to 10 carbon atoms, each of which may be substituted by one or more R² radicals, where one or more hydrogen atoms may be replaced by F, or an aromatic or heteroaromatic ring system which has 5 to 14 aromatic ring atoms and may be substituted in each case by one or more R² radicals; at the same time, two or more R¹ radicals together may also form a mono- or polycyclic, aliphatic, aromatic and/or benzofused ring system. Particularly preferred R¹ radicals are the same or different at each instance and are selected from the group consisting of H, F, Br, CN, B(OR²)₂, a straight-chain alkyl group having 1 to 6 carbon atoms, especially methyl, or a branched or cyclic alkyl group having 3 to 10 carbon atoms, especially isopropyl or tert-butyl, where one or more hydrogen atoms may be replaced by F, or an aromatic or heteroaromatic ring system which has 5 to 12 aromatic ring atoms and may be substituted in each case by one or more R² radicals; at the same time, two or more R¹ radicals together may also form a mono- or polycyclic, aliphatic, aromatic and/or benzofused ring system.

The metal complexes of the invention are preparable in principle by various processes. However, the processes described hereinafter have been found to be particularly suitable.

Therefore, the present invention further provides a process for preparing the metal complexes of formula (1) by reacting the corresponding free ligands with metal alkoxides of the formula (55), with metal ketoketonates of the formula (56), with metal halides of the formula (57) or with dimeric metal complexes of the formula (58)

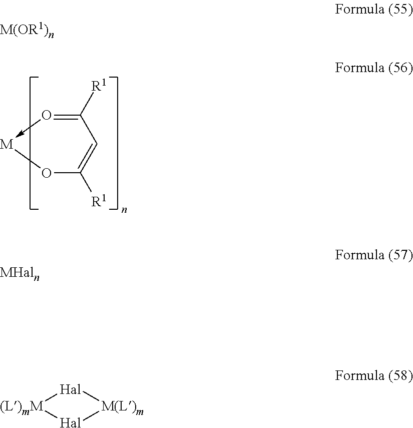

where the symbols M, m, n and R¹ have the definitions given above and Hal=F, Cl, Br or I.

It is likewise possible to use metal compounds, especially iridium compounds, bearing both alkoxide and/or halide and/or hydroxyl and ketoketonate radicals. These compounds may also be charged. Corresponding iridium compounds of particular suitability as reactants are disclosed in WO 2004/085449. [IrCl₂(acac)₂]⁻ is particularly suitable, for example Na[IrCl₂(acac)₂].

The synthesis of heteroleptic complexes preferably proceeds from the chloro-bridged dimer, i.e. for iridium complexes from [(L)₂IrCl]₂ or [(L′)₂IrCl]₂. In this case, it may be preferable to react the latter with the ligand L′ or L using a Lewis acid, a silver salt and/or an acid. A particularly suitable reaction has been found to be that with trifluorosulfonic acid, followed by the reaction with the ligand L or L′.

The synthesis of the complexes is preferably conducted as described in WO 2002/060910 and in WO 2004/085449. Heteroleptic complexes can be synthesized, for example, according to WO 2005/042548 as well. In this case, the synthesis can, for example, also be activated by thermal or photochemical means, by microwave radiation and/or in an autoclave.

It is possible by these processes to obtain the inventive compounds of formula (1) in high purity, preferably more than 99% (determined by means of ¹H NMR and/or HPLC).

For the processing of the inventive compounds from the liquid phase, for example by spin-coating or by printing methods, formulations of the inventive compounds are required. These formulations may, for example, be solutions, dispersions or emulsions. For this purpose, it may be preferable to use mixtures of two or more solvents. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention therefore further provides a formulation, especially a solution or dispersion, comprising at least one compound of formula (1) or as per the preferred embodiments detailed above and at least one further compound, especially a solvent. In this case, the formulation, apart from the compound of formula (1) and the solvent(s), may also comprise further compounds, for example one or more matrix materials.

The above-described complexes of formula (1) and the above-detailed preferred embodiments can be used as active component in an electronic device. The present invention therefore further provides for the use of a compound of formula (1) or according to one of the preferred embodiments in an electronic device. In addition, the compounds of the invention can be used for production of singlet oxygen, in photocatalysis or in oxygen sensors.

The present invention still further provides an electronic device comprising at least one compound of formula (1) or according to the preferred embodiments.

An electronic device is understood to mean any device comprising anode, cathode and at least one layer, said layer comprising at least one organic or organometallic compound. The electronic device of the invention thus comprises anode, cathode and at least one layer comprising at least one compound of the above-detailed formula (1). Preferred electronic devices are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs) and organic laser diodes (O-lasers), comprising at least one compound of the above-detailed formula (1) in at least one layer. Particular preference is given to organic electroluminescent devices. Active components are generally the organic or inorganic materials introduced between the anode and cathode, for example charge injection, charge transport or charge blocker materials, but especially emission materials and matrix materials. The compounds of the invention exhibit particularly good properties as emission material in organic electroluminescent devices. A preferred embodiment of the invention is therefore organic electroluminescent devices.

The organic electroluminescent device comprises cathode, anode and at least one emitting layer. Apart from these layers, it may comprise further layers, for example in each case one or more hole injection layers, hole transport layers, hole blocker layers, electron transport layers, electron injection layers, exciton blocker layers, electron blocker layers, charge generation layers and/or organic or inorganic p/n junctions. It is likewise possible for interlayers to be introduced between two emitting layers, these having, for example, an exciton-blocking function and/or controlling the charge balance in the electroluminescent device. However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. A preferred embodiment is three-layer systems where the three layers exhibit blue, green and orange or red emission (see, for example, WO 2005/011013), or systems having more than three emitting layers. A further preferred embodiment is two-layer systems where the two layers exhibit either blue and yellow emission or blue-green and orange emission. Two-layer systems are of interest especially for lighting applications. Embodiments of this kind are particularly suitable with the compounds of the invention, since they frequently exhibit yellow or orange emission. The white-emitting electroluminescent devices can be used for lighting applications or as a backlight for displays or with color filters as a display.

In a preferred embodiment of the invention, the organic electroluminescent device comprises the compound of formula (1) or the above-detailed preferred embodiments as emitting compound in one or more emitting layers.

When the compound of formula (1) is used as emitting compound in an emitting layer, it is preferably used in combination with one or more matrix materials. The mixture of the compound of formula (1) and the matrix material contains between 1% and 99% by volume, preferably between 2% and 90% by volume, more preferably between 3% and 40% by volume and especially between 5% and 15% by volume of the compound of formula (1), based on the overall mixture of emitter and matrix material. Correspondingly, the mixture contains between 99% and 1% by volume, preferably between 98% and 10% by volume, more preferably between 97% and 60% by volume and especially between 95% and 85% by volume of the matrix material(s), based on the overall mixture of emitter and matrix material.

The matrix material used may generally be any materials which are known for the purpose according to the prior art. The triplet level of the matrix material is preferably higher than the triplet level of the emitter.

Suitable matrix materials for the compounds of the invention are ketones, phosphine oxides, sulfoxides and sulfones, for example according to WO 2004/013080, WO 2004/093207, WO 2006/005627 or WO 2010/006680, triarylamines, carbazole derivatives, e.g. CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example according to WO 2007/063754 or WO 2008/056746, indenocarbazole derivatives, for example according to WO 2010/136109 or WO 2011/000455, azacarbazoles, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, diazasilole derivatives, for example according to WO 2010/054729, diazaphosphole derivatives, for example according to WO 2010/054730, triazine derivatives, for example according to WO 2010/0.15306, WO 2007/063754 or WO 2008/056746, zinc complexes, for example according to EP 652273 or WO 2009/062578, beryllium complexes, dibenzofuran derivatives, for example according to WO 2009/148015, or bridged carbazole derivatives, for example according to US 2009/0136779, WO 2010/050778, WO 2011/042107 or WO 2011/088877.

It may also be preferable to use a plurality of different matrix materials as a mixture. Especially suitable for this purpose are mixtures of at least one electron-transporting matrix material and at least one hole-transporting matrix material or mixtures of at least two electron-transporting matrix materials or mixtures of at least one hole- or electron-transporting matrix material and at least one further material which has a large bandgap and is thus substantially electrically inert and is not involved to a substantial extent, if any, in the charge transport, as described, for example, in WO 2010/108579. A preferred combination is, for example, the use of an aromatic ketone or a triazine derivative with a triarylamine derivative or a carbazole derivative as mixed matrix for the metal complex of the invention.

It is further preferable to use a mixture of two or more triplet emitters together with a matrix. In this case, the triplet emitter having the shorter-wave emission spectrum serves as co-matrix for the triplet emitter having the longer-wave emission spectrum. For example, it is possible to use blue- or green-emitting triplet emitters as co-matrix for the inventive complexes of formula (1).

The compounds of the invention are especially also suitable as phosphorescent emitters in organic electroluminescent devices, as described, for example, in WO 98/24271, US 2011/0248247 and US 2012/0223633. In these multicolor display components, an additional blue emission layer is applied by vapor deposition over the full area to all pixels, including those having a color other than blue. It was found here that the compounds of the invention, when they are used as emitters for the red and/or green pixels, led to very good emission together with the blue emission layer applied by vapor deposition.

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. On the other hand, metal/metal oxide electrons (e.g. Al/Ni/NiOₓ, Al/PtOₓ) may also be preferred. For some applications, at least one of the electrodes has to be transparent in order to enable the irradiation of the organic material (O-SC) or the emission of light (OLED/PLED, O-laser). A preferred structure uses a transparent anode. Preferred anode materials here are conductive mixed metal oxides. Particular preference is given to indium tin oxide (ITO) or indium zinc oxide (IZO). Preference is further given to conductive doped organic materials, especially conductive doped polymers.

In the further layers, it is generally possible to use any materials as used according to the prior art for the layers, and the person skilled in the art is able, without exercising inventive skill, to combine any of these materials with the materials of the invention in an electronic device.

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapor deposition in vacuum sublimation systems at an initial pressure of typically less than 10⁻⁵ mbar, preferably less than 10⁻⁶ mbar. It is also possible that the initial pressure is even lower, for example less than 10⁻⁷ mbar.

Preference is likewise given to an organic electroluminescent device, characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured (for example, M. S. Arnold et al., Appl. Phys. Lett. 2008, 92, 053301).

Preference is additionally given to an organic electroluminescent device, characterized in that one or more layers are produced from solution, for example by spin-coating, or by any printing method, for example screen printing, flexographic printing or offset printing, but more preferably LITI (light-induced thermal imaging, thermal transfer printing) or inkjet printing. For this purpose, soluble compounds are needed, which are obtained, for example, through suitable substitution.

The organic electroluminescent device can also be produced as a hybrid system by applying one or more layers from solution and applying one or more other layers by vapor deposition. For example, it is possible to apply an emitting layer comprising a compound of formula (1) and a matrix material from solution, and to apply a hole blocker layer and/or an electron transport layer thereto by vapor deposition under reduced pressure.

These methods are known in general terms to those skilled in the art and can be applied without difficulty to organic electroluminescent devices comprising compounds of formula (1) or the above-detailed preferred embodiments.

The electronic devices of the invention, especially organic electroluminescent devices, are notable for the following surprising advantages over the prior art:
1. The compounds of formula (1) have good solubility in a multitude of commonly used organic solvents and are therefore of very good suitability for processing from solution.
2. The compounds have a high photoluminescence quantum efficiency.
3. The compounds have a narrower emission spectrum than compounds substituted by similar carbazole derivatives according to the prior art. This results in greater color purity.

These abovementioned advantages are not accompanied by a deterioration in the further electronic properties.

The invention is illustrated in detail by the examples which follow, without any intention of restricting it thereby. The person skilled in the art will be able to use the details given, without exercising inventive skill, to produce further electronic devices of the invention and hence to execute the invention over the entire scope disclosed.

### EXAMPLES

All syntheses are conducted under a protective gas atmosphere in dried solvents, unless stated otherwise. The figures in square brackets relate to the CAS numbers of the compounds known from the literature.

### A) Preparation of Precursors

### Homoleptic Brominated Iridium Complexes

### A.1) Ir(L1Br)₃/tris[1-(3-bromophenyl)isoquinolinato]iridium(III)

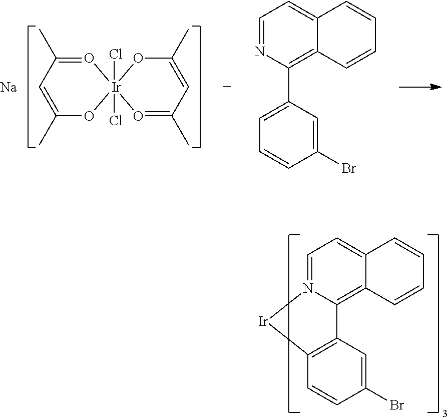

A mixture of 4.84 g (10.0 mmol) of sodium bis(acetylacetonato)dichloroiridate(III) [770720-50-8] and 14.45 g (50.9 mmol) of 1-(3-bromophenyl)isoquinoline [936498-09-8] is heated under reflux in 200 mL of ethylene glycol for 48 h. After cooling, the precipitate formed is removed using a glass filter frit and washed three times with 50 mL each time of water and three times with 50 mL each time of methanol. The crude product is recrystallized twice from about 200 mL of DMSO, and washed three times with about 50 mL each time of methanol and dried under reduced pressure. This leaves 7.50 g (7.20 mmol, 72% of theory) of Ir(L1Br)₃ as a red solid.

In an analogous manner, it is possible to prepare the precursors Ir(L2Br)₃ and Ir(L3)₃ from Na[Ir(acac)₂Cl₂] and the appropriate ligand L:

| | Ligand L | | |
|---|---|---|---|
| Ex. | [CAS] | Product | Yield |
| Ir(L2Br)₃ | 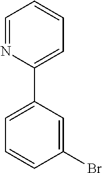 [SMILES: Brc1cccc(-c2ccccn2)c1] L2Br [4373-60-8] | 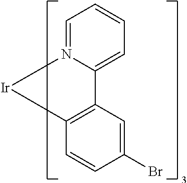 | 78% |
| Ir(L3)₃ | 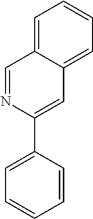 [SMILES: c1ccc(-c2cc3ccccc3cn2)cc1] L3 [37993-76-3] | 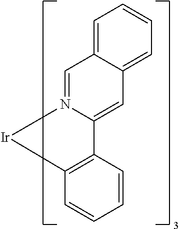 | 61% |

### A.2) Ir(L4)₃/tris(6-tert-butyl-9,10-dimethylbenzo[4,5]imidazo[1,2-c]quinazolinato)iridium(III)

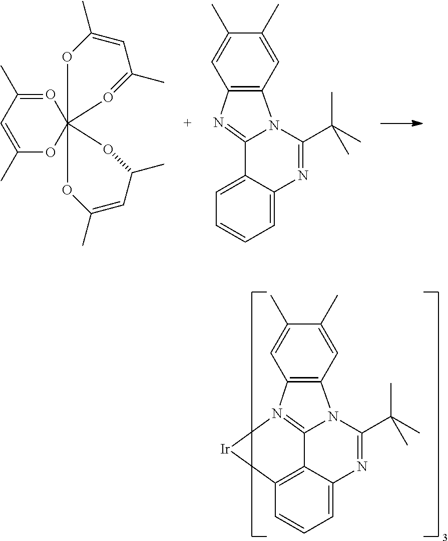

Tris(6-tert-butyl-9,10-dimethylbenzo[4,5]imidazo[1,2-c]quinazolinato)iridium(III) can be prepared as described in the application WO 2011/157339: A mixture of 4.90 g (10.1 mmol) of tris(acetylacetonato)iridium(III) [15635-87-7] and 18.20 g (60.0 mmol) of 6-tert-butyl-9,10-dimethylbenzo[4,5]imidazo[1,2-c]quinazoline [1352330-29-0] together with a glass-ensheathed magnetic stirrer bar is sealed by melting in a thick-wall 50 mL glass ampoule under reduced pressure (pressure about 10⁻⁵ mbar). The ampoule is heated at 270° C. for 100 h while stirring. After cooling, the ampoule is opened (CAUTION: the ampoules are usually under pressure). The sinter cake is stirred with 100 g of glass beads (diameter 3 mm) in 100 mL of dichloromethane for 3 h, in the course of which it is mechanically digested. The fine suspension is decanted off from the glass beads, and the solids are filtered off with suction using a glass filter frit and dried under reduced pressure. The dried crude product is extracted with about 500 mL of THF in a hot extractor over alumina (basic, activity level 1). The solvent is concentrated to about 100 mL under reduced pressure and the metal complex is precipitated by gradual dropwise addition of about 200 mL of methanol. The solids are filtered off with suction and dried under reduced pressure. This leaves 5.72 g (5.20 mmol, 52% of theory) as a yellow powder.

### A.3) Ir(L3Br)₃/tris[3-(3-bromophenyl)isoquinolinato]iridum(III)

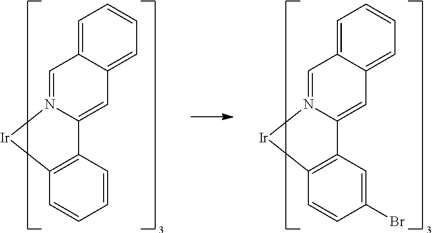

5.88 g (33.0 mmol) of N-bromosuccinimide are added while cooling with ice to a mixture of 8.04 g (10.0 mmol) of Ir(L3)₃ in 150 mL of THF in such a way that the temperature does not exceed 5° C. The mixture is stirred at 0° C. for 1 h, then the cooling is removed and the mixture is stirred for a further 24 h. The solvent is removed under reduced pressure and the remaining residue is extracted by stirring three times at 60° C. with 50 mL of ethanol each time. This leaves 9.72 g (9.33 mmol, 93% of theory) of Ir(L3Br)₃ as a red solid.

In an analogous manner, it is possible to prepare Ir(L4Br)₃ by bromination of Ir(L4)₃:

| Ex. | Reactant | Product | Yield |
|---|---|---|---|
| Ir(L4Br)₃ | 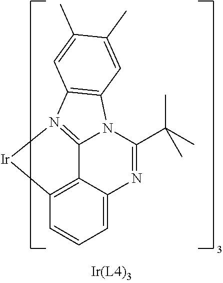 | 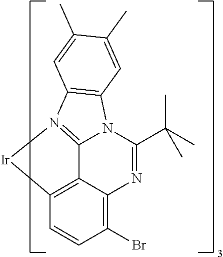 | 87% |

### B) Preparation of Precursors

### Chloro Dimers

Dimeric chlorine-bridged iridium complexes can be prepared in analogy to S. Sprouse, K. A. King, P. J. Spellane, R. J. Watts, J. Am. Chem. Soc. 106, 6647-6653 (1984):

### [Ir(L1Br)₂Cl]₂/tetrakis(1-(3-bromophenyl)isoquinolinato)(μ-dichloro)diiridium(III)

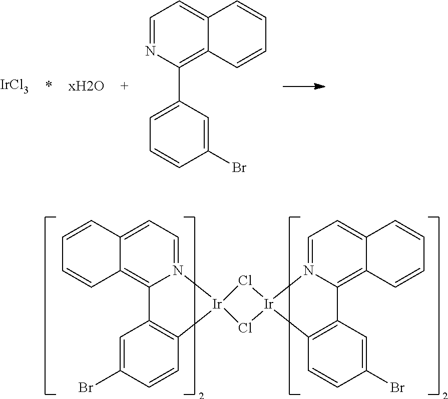

3.53 g (10.0 mmol) of iridium trichloride hydrate [14996-61-3] are heated to reflux together with 6.29 g (22.1 mmol) of 1-(3-bromophenyl)isoquinoline [936498-09-8] in a mixture of 300 mL of ethoxyethanol and 100 mL of water for 24 h. After cooling to room temperature, the solids formed are separated off using a glass filter frit and washed three times with 50 mL each time of ethanol. This leaves 10.06 g (6.34 mmol, 63% of theory) as a red solid.

In an analogous manner, it is possible to prepare the precursors [Ir(L2Br)₂Cl]₂ and [Ir(L5Br)₂Cl]₂ from iridium trichloride hydrate and the appropriate ligand L.

| | Ligand L | | |
|---|---|---|---|
| Ex. | [CAS] | Product | Yield |
| [Ir(L2Br)₂Cl]₂ | 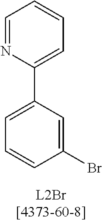 [SMILES: Brc1cccc(-c2ccccn2)c1] | 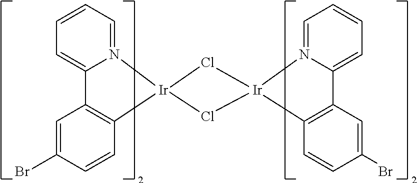 | 68% |
| [Ir(L5Br)₂]Cl₂ | 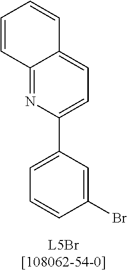 [SMILES: Brc1cccc(-c2ccc3ccccc3n2)c1] | 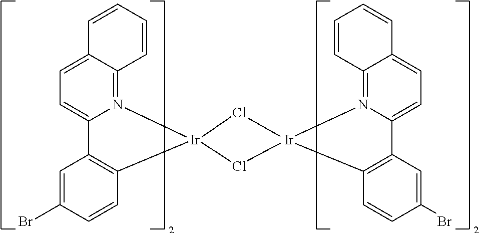 | 55% |

### C) Preparation of Precursors

### Boronic Ester

### BS1/8,8-dimethyl-3-phenyl-6-(4,4,5,5-tetramethyl-[1,3,2]dioxaborolan-2-yl)-H-indolo[3,2,1-de]acridine

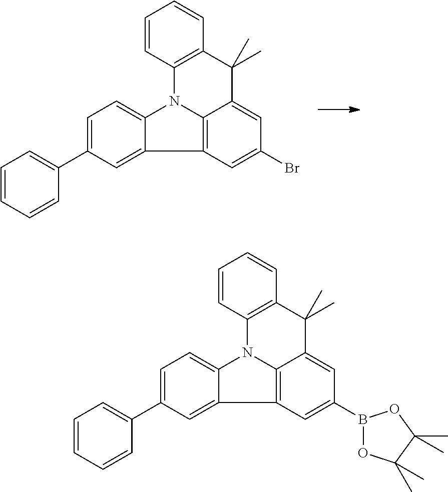 [SMILES: CC1(C)c2ccccc2-n2c3ccc(-c4ccccc4)cc3c3cc(Br)cc1c32 ; CC1(C)c2ccccc2-n2c3ccc(-c4ccccc4)cc3c3cc(B4OC(C)(C)C(C)(C)O4)cc1c32]

To an initial charge of 19.7 g (45 mmol) of 6-bromo-8,8-dimethyl-3-phenyl-8H-indolo[3,2,1-de]acridine [1342816-23-2] in 350 mL of THF are added 9.8 g (100 mmol) of potassium acetate, 24.1 g (95 mmol) of bis(pinacolato)diborane and 920 mg (1.1 mmol) of 1,1′-bis(diphenylphosphinoferrocene)palladium(II) chloride-dichloromethane complex. The mixture is heated to reflux for 18 h. After cooling, 300 mL of ethyl acetate and 300 mL of water are added. The organic phase is removed, washed three times with 150 mL each time of water and dried over magnesium sulfate. The solvent is removed under reduced pressure. The residue is extracted with 150 mL of toluene in a hot extractor over about 25 g of alumina (basic, activity level 1). After cooling, the mixture is concentrated under reduced pressure to about 50 mL, and 150 mL of ethanol are added gradually. The solids formed are filtered off with suction and dried under reduced pressure. This leaves 17.4 g (36 mmol, 80% of theory) as a yellow solid.

In an analogous manner, it is possible to prepare the boronic esters BS2 to BS9:

| Ex. | Bromide [CAS] | Product | Yield |
|---|---|---|---|
| BS2 | 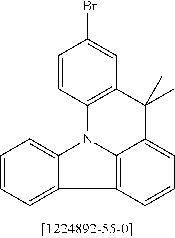 [SMILES: CC1(C)c2cc(Br)ccc2-n2c3ccccc3c3cccc1c32] | 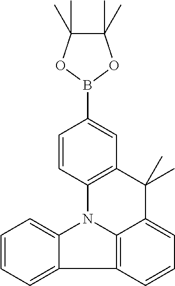 [SMILES: CC1(C)c2cc(B3OC(C)(C)C(C)(C)O3)ccc2-n2c3ccccc3c3cccc1c32] | 77% |
| BS3 | 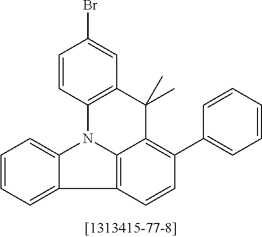 [SMILES: CC1(C)c2cc(Br)ccc2-n2c3ccccc3c3ccc(-c4ccccc4)c1c32] | 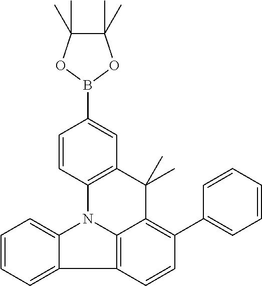 [SMILES: CC1(C)c2cc(B3OC(C)(C)C(C)(C)O3)ccc2-n2c3ccccc3c3ccc(-c4ccccc4)c1c32] | 89% |
| BS4 | 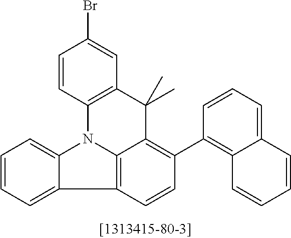 [SMILES: CC1(C)c2cc(Br)ccc2-n2c3ccccc3c3ccc(-c4cccc5ccccc45)c1c32] | 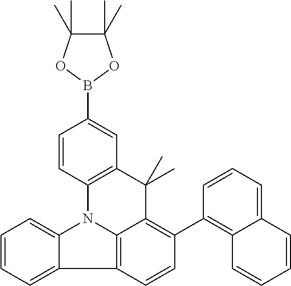 [SMILES: CC1(C)c2cc(B3OC(C)(C)C(C)(C)O3)ccc2-n2c3ccccc3c3ccc(-c4cccc5ccccc45)c1c32] | 72% |
| BS5 | 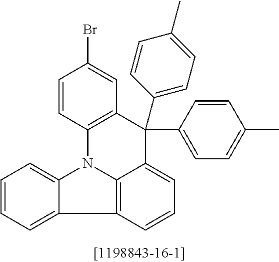 [SMILES: Cc1ccc(C2(c3ccc(C)cc3)c3cc(Br)ccc3-n3c4ccccc4c4cccc2c43)cc1] | 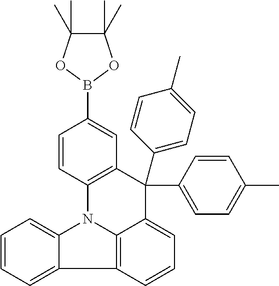 [SMILES: Cc1ccc(C2(c3ccc(C)cc3)c3cc(B4OC(C)(C)C(C)(C)O4)ccc3-n3c4ccccc4c4cccc2c43)cc1] | 76% |
| BS6 | 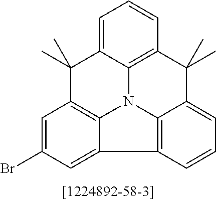 [SMILES: CC1(C)c2cccc3c2-n2c4c1cccc4c1cc(Br)cc(c12)C3(C)C] | 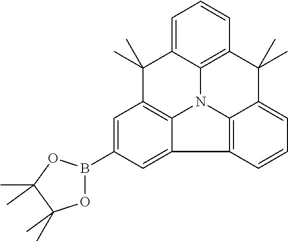 | 63% |
| BS7 | 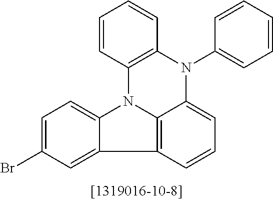 [SMILES: Brc1ccc2c(c1)c1cccc3c1n2-c1ccccc1N3c1ccccc1] | 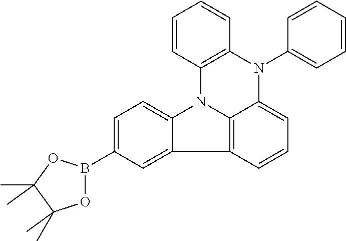 [SMILES: CC1(C)OB(c2ccc3c(c2)c2cccc4c2n3-c2ccccc2N4c2ccccc2)OC1(C)C] | 81% |
| BS8 | 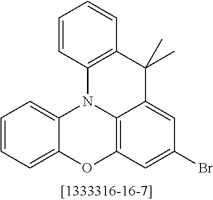 [SMILES: CC1(C)c2ccccc2N2c3ccccc3Oc3cc(Br)cc1c32] | 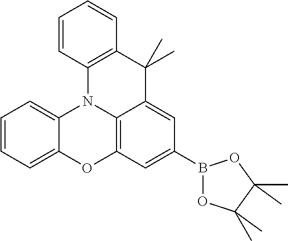 [SMILES: CC1(C)c2ccccc2N2c3ccccc3Oc3cc(B4OC(C)(C)C(C)(C)O4)cc1c32] | 60% |
| BS9 | 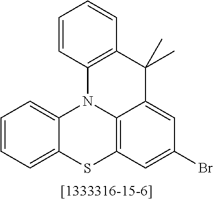 [SMILES: CC1(C)c2ccccc2N2c3ccccc3Sc3cc(Br)cc1c32] | 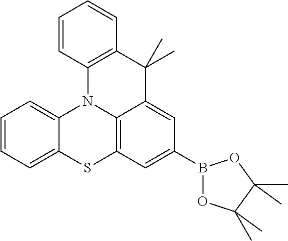 [SMILES: CC1(C)c2ccccc2N2c3ccccc3Sc3cc(B4OC(C)(C)C(C)(C)O4)cc1c32] | 39% |

### D) Preparation of Precursors

### Ligands

### L6/1-(Isoquinolin-1-yl)-3-(8,8-dimethyl-8H-Indolo[3,2,1-de]acridin-3-yl)phenyl

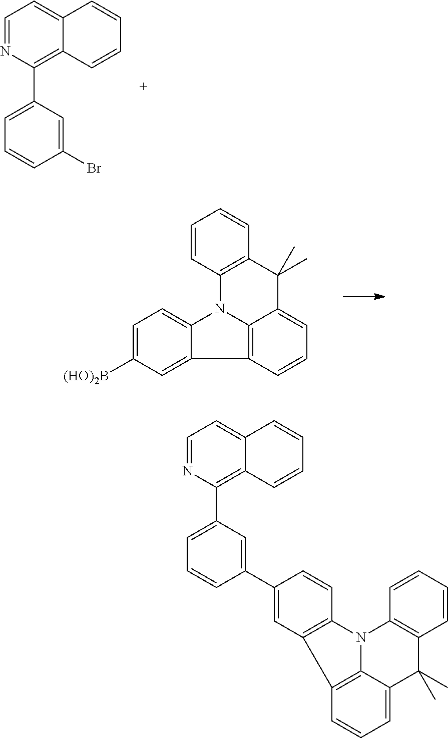

29.8 g (10.5 mmol) of 1-(3-bromophenyl)isoquinoline [936498-09-8] are initially charged together with 4.5 g (13.8 mmol) of 8,8-dimethyl-8H-indolo[3,2,1-de]acridin-3-ylboronic acid [1307793-50-5], 4.4 g (31.8 mmol) of potassium carbonate and 0.3 g (0.25 mmol) of tetrakis(triphenylphosphine)palladium(0) in a mixture of 150 mL of toluene and 100 mL of water and heated to reflux with vigorous stirring for 5 h. After cooling to room temperature, the phases are separated. The organic phase is washed three times with 100 mL each time of water, dried over magnesium sulfate and concentrated to dryness under reduced pressure. The residue is sublimed under high vacuum (pressure about 10⁻⁶ mbar) at 300° C. This leaves 37.5 g (7.7 mmol, 73% of theory) of the product, which is clean by ¹H NMR, as a light brown powder.

In an analogous manner, it is possible to prepare the ligands L7 to L16:

| Ex. | Bromide | Boronic acid/ester [CAS] or Ex. | Product | Yield |
|---|---|---|---|---|
| L7 | 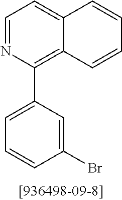 [SMILES: Brc1cccc(-c2nccc3ccccc23)c1] | 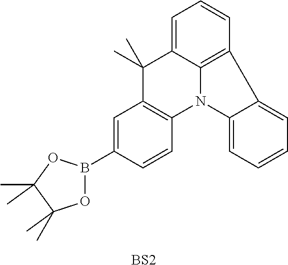 [SMILES: CC1(C)c2cc(B3OC(C)(C)C(C)(C)O3)ccc2-n2c3ccccc3c3cccc1c32 ; "BS2"] | 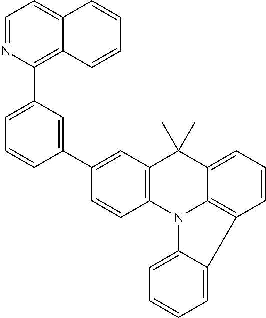 [SMILES: CC1(C)c2cc(-c3cccc(-c4nccc5ccccc45)c3)ccc2-n2c3ccccc3c3cccc1c32] | 81% |
| L8 | 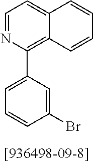 [SMILES: Brc1cccc(-c2nccc3ccccc23)c1] | 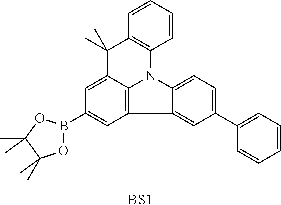 [SMILES: CC1(C)c2ccccc2-n2c3ccc(-c4ccccc4)cc3c3cc(B4OC(C)(C)C(C)(C)O4)cc1c32 ; "BS1"] | 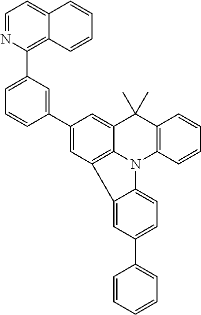 [SMILES: CC1(C)c2ccccc2-n2c3ccc(-c4ccccc4)cc3c3cc(-c4cccc(-c5nccc6ccccc56)c4)cc1c32] | 75% |
| L9 | 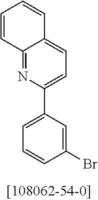 [SMILES: Brc1cccc(-c2ccc3ccccc3n2)c1] | 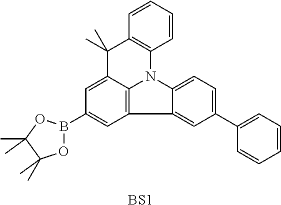 [SMILES: CC1(C)c2ccccc2-n2c3ccc(-c4ccccc4)cc3c3cc(B4OC(C)(C)C(C)(C)O4)cc1c32 ; "BS1"] | 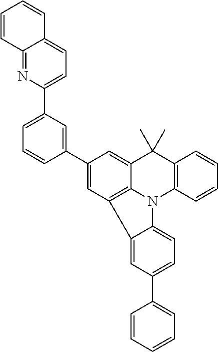 [SMILES: CC1(C)c2ccccc2-n2c3ccc(-c4ccccc4)cc3c3cc(-c4cccc(-c5ccc6ccccc6n5)c4)cc1c32] | 65% |
| L10 | 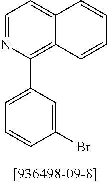 [SMILES: Brc1cccc(-c2nccc3ccccc23)c1] | 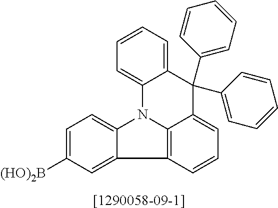 | 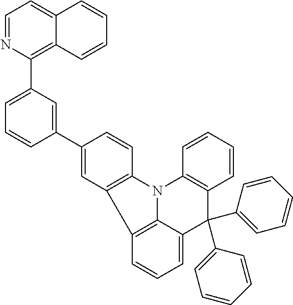 [SMILES: c1ccc(C2(c3ccccc3)c3ccccc3-n3c4ccc(-c5cccc(-c6nccc7ccccc67)c5)cc4c4cccc2c43)cc1] | 68% |
| L11 | 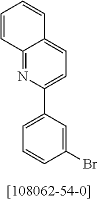 [SMILES: Brc1cccc(-c2ccc3ccccc3n2)c1] | 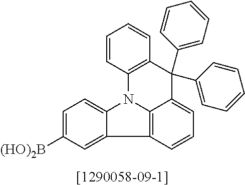 | 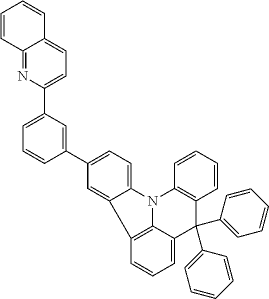 [SMILES: c1ccc(C2(c3ccccc3)c3ccccc3-n3c4ccc(-c5cccc(-c6ccc7ccccc7n6)c5)cc4c4cccc2c43)cc1] | 47% |
| L12 | 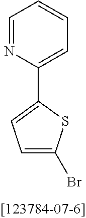 [SMILES: Brc1ccc(-c2ccccn2)s1] | 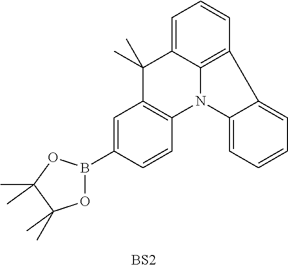 [SMILES: CC1(C)c2cc(B3OC(C)(C)C(C)(C)O3)ccc2-n2c3ccccc3c3cccc1c32 ; "BS2"] | 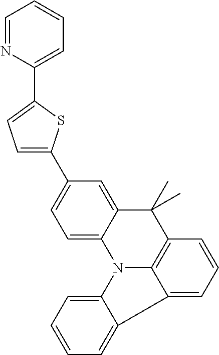 [SMILES: CC1(C)c2cc(-c3ccc(-c4ccccn4)s3)ccc2-n2c3ccccc3c3cccc1c32] | 63% |
| L13 | 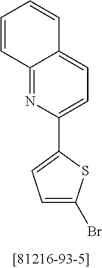 [SMILES: Brc1ccc(-c2ccc3ccccc3n2)s1] | 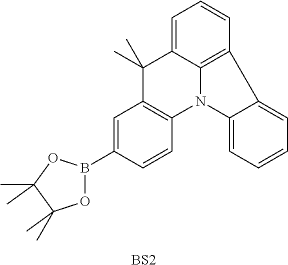 [SMILES: CC1(C)c2cc(B3OC(C)(C)C(C)(C)O3)ccc2-n2c3ccccc3c3cccc1c32 ; "BS2"] | 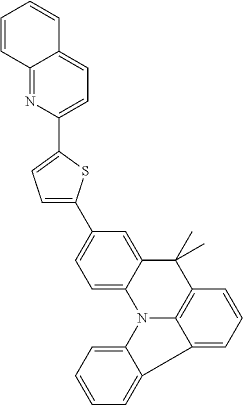 [SMILES: CC1(C)c2cc(-c3ccc(-c4ccc5ccccc5n4)s3)ccc2-n2c3ccccc3c3cccc1c32] | 60% |
| L14 | 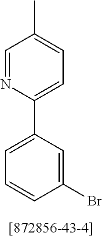 | 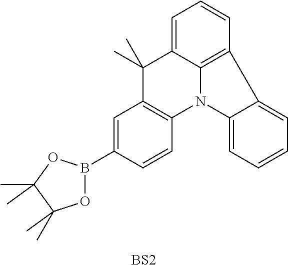 [SMILES: CC1(C)c2cc(B3OC(C)(C)C(C)(C)O3)ccc2-n2c3ccccc3c3cccc1c32 ; "BS2"] | 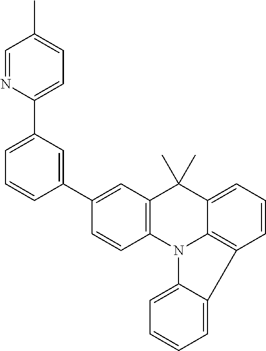 [SMILES: Cc1ccc(-c2cccc(-c3ccc4c(c3)C(C)(C)c3cccc5c6ccccc6n-4c35)c2)nc1] | 77% |
| L15 | 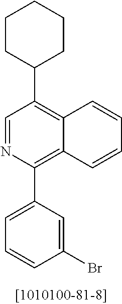 [SMILES: Brc1cccc(-c2ncc(C3CCCCC3)c3ccccc23)c1] | 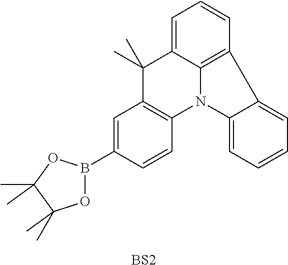 [SMILES: CC1(C)c2cc(B3OC(C)(C)C(C)(C)O3)ccc2-n2c3ccccc3c3cccc1c32 ; "BS2"] | 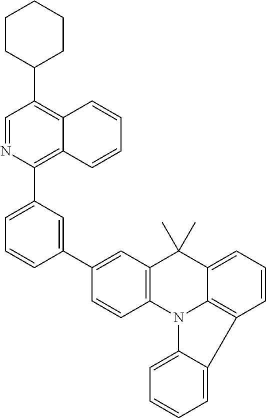 [SMILES: CC1(C)c2cc(-c3cccc(-c4ncc(C5CCCCC5)c5ccccc45)c3)ccc2-n2c3ccccc3c3cccc1c32] | 67% |
| L16 | 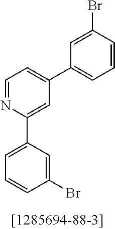 [SMILES: Brc1cccc(-c2ccnc(-c3cccc(Br)c3)c2)c1] | 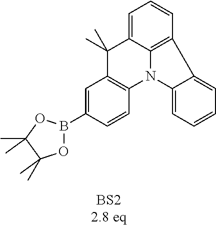 [SMILES: CC1(C)c2cc(B3OC(C)(C)C(C)(C)O3)ccc2-n2c3ccccc3c3cccc1c32 ; "BS22.8 eq"] | 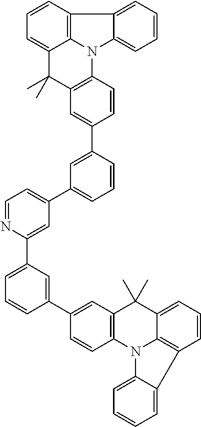 [SMILES: CC1(C)c2cc(-c3cccc(-c4ccnc(-c5cccc(-c6ccc7c(c6)C(C)(C)c6cccc8c9ccccc9n-7c68)c5)c4)c3)ccc2-n2c3ccccc3c3cccc1c32] | 42% |

### E) Preparation of Precursors

### Heteroleptic Brominated Iridium Complexes

### E.1) Ir(L1Br)₂(CL1)/bis[1-(3-bromophenyl)isoquinolinato]iridium(III) acetylacetonate

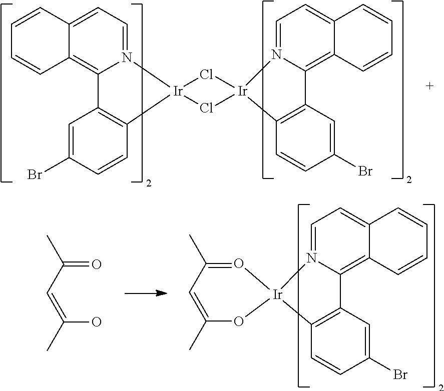

9.96 g (6.3 mmol) of tetrakis(1-(3-bromophenyl)isoquinolinato)(p-dichloro)diiridium [Ir(L1Br)₂Cl]₂ are suspended in a mixture of 75 mL of 2-ethoxyethanol and 25 mL of water, 1.35 g (13.5 mmol) of acetylacetone [1522-20-9] and 1.59 g (15.0 mmol) of sodium carbonate are added and the mixture is heated to reflux for 20 h. The heating is removed, and 75 mL of water are gradually added dropwise to the still-warm mixture. After cooling, the solids formed are removed by means of a glass filter frit, washed three times with 50 mL of water and three times with 50 mL of methanol and dried under reduced pressure. The solids are extracted with 400 mL of toluene in a hot extractor over about 50 g of alumina (basic, activity level 1). After cooling, the suspension is concentrated under reduced pressure to about 100 mL, 200 mL of methanol are added and the mixture is stirred for a further 1 h. The solids are filtered off with suction, washed twice with 50 mL of methanol and dried under reduced pressure. If the purity is then below 99% by ¹H NMR and/or HPLC, the hot extraction step is correspondingly repeated. This leaves 8.97 g (10.4 mmol, 83% of theory) as a red powder.

In an analogous manner, it is possible to prepare the complexes Ir(L1Br)₂(CL2) to Ir(L2Br)₂(CL3).

| Ex. | Reactant | Co-ligand CL [CAS] | Product | Yield |
|---|---|---|---|---|
| Ir(L1Br)₂(CL2) | [Ir(L1Br)₂Cl]₂ | 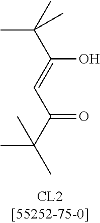 | 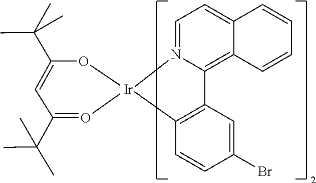 | 79% |
| Ir(L1Br)₂(CL3) | [Ir(L1Br)₂Cl]₂ | 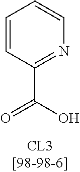 | 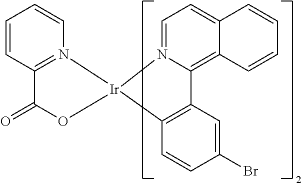 | 70% |
| Ir(L1Br)₂(CL4) | [Ir(L1Br)₂Cl]₂ | 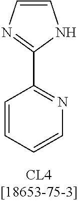 [SMILES: c1ccc(-c2ncc[nH]2)nc1] | 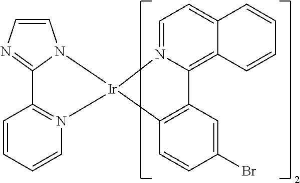 | 73% |
| Ir(L1Br)₂(CL5) | [Ir(L1Br)₂Cl]₂ | 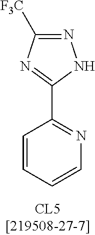 [SMILES: FC(F)(F)c1n[nH]c(-c2ccccn2)n1] | 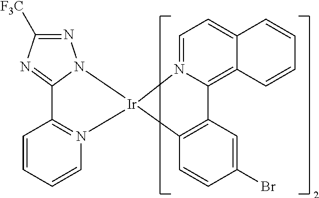 | 61% |
| Ir(L1Br)₂(CL6) | [Ir(L1Br)₂Cl]₂ | 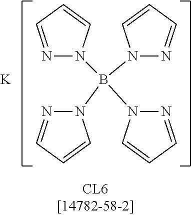 | 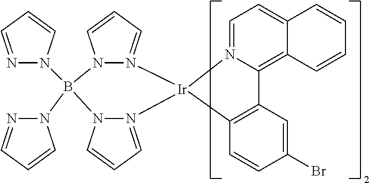 | 60% |
| Ir(L5Br)₂(CL1) | [Ir(L5Br)₂Cl]₂ | 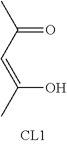 | 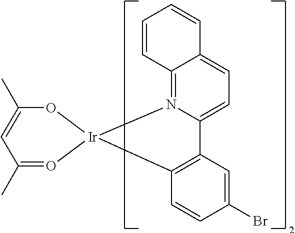 | 78% |
| Ir(L5Br)₂(CL2) | [Ir(L5Br)₂Cl]₂ | 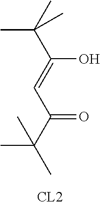 | 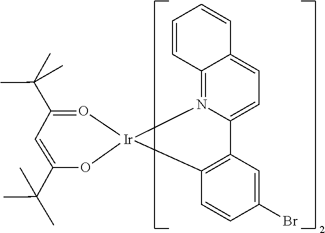 | 73% |
| Ir(L2Br)₂(CL1) | [Ir(L2Br)₂Cl]₂ | 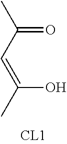 | 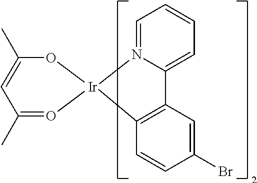 | 85% |
| Ir(L2Br)₂(CL2) | [Ir(L2Br)₂Cl]₂ | 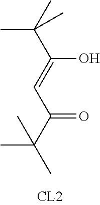 | 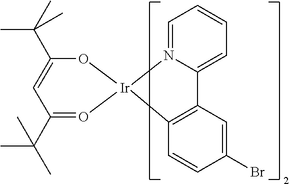 | 86% |
| Ir(L2Br)₂(CL3) | [Ir(L2Br)₂Cl]₂ | 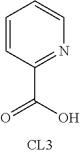 | 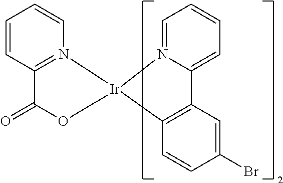 | 75% |

### E.2) Ir(L1Br)₂(CL7)/bis-[1-(3-bromophenyl)isoquinolinato](2-phenylpyridinato)iridium(III)

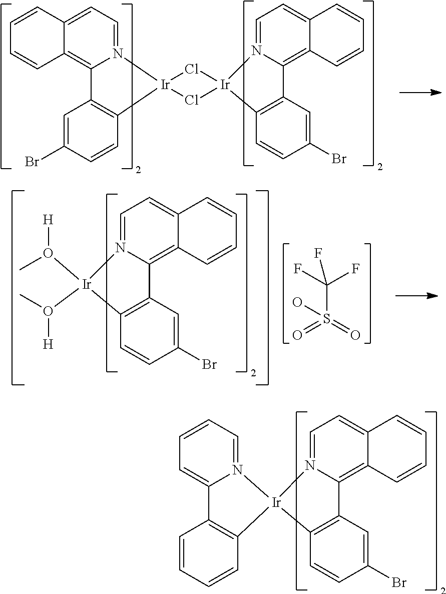

9.53 g (6.0 mmol) of [Ir(L1Br)₂Cl]₂ are initially charged in 400 mL of dichloromethane and stirred with 3.13 g (12.2 mmol) of silver trifluoromethylsulfonic acid and 8 mL (6.34 g, 198 mmol) of methanol at room temperature for 15 h. The suspension is filtered through Celite and the filtrate is concentrated down to about 50 mL under reduced pressure. 200 mL of heptane are added to the mixture, which is stirred for 1 h. The solids formed are removed by means of a glass filter frit, washed twice with about 75 mL of heptane and dried under high vacuum (pressure about 10⁻⁵ mbar). The remaining residue is suspended in 500 mL of ethanol, 1.83 g (11.8 mmol) of 2-phenylpyridine and 1.54 g (14.4 mmol) of 2,6-dimethylpyridine are added and the mixture is heated to reflux for 48 h. The solids are removed by means of a glass filter frit, washed three times with about 50 mL of ethanol and dried under reduced pressure. The remaining residue is suspended in 250 mL of ethylene glycol and heated to 190° C. for 8 h. The heating is removed; after cooling to about 80° C., 400 mL of ethanol are added and the mixture is stirred for 24 h. The solids are removed by means of a glass filter frit, washed twice with about 50 mL of ethanol and dried under high vacuum (pressure about 10⁻⁵ mbar). This leaves 6.71 g (7.3 mmol, 61% of theory) of the product, which is about 98% pure by ¹H NMR, as a red powder.

In an analogous manner, it is possible to prepare the precursors Ir(L5Br)₂(CL7) to Ir(L2Br)₂(L16).

| Ex. | Reactant | Co-ligand CL [CAS] | Product | Yield |
|---|---|---|---|---|
| Ir(L5Br)₂(CL7) | [Ir(L5Br)₂Cl]₂ | 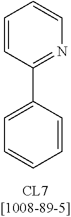 [SMILES: c1ccc(-c2ccccn2)cc1] | 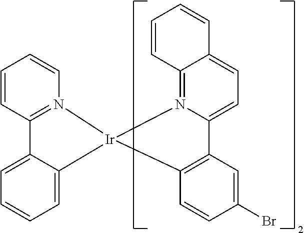 | 52% |
| Ir(L1Br)₂(CL8) | [Ir(L1Br)₂Cl]₂ | 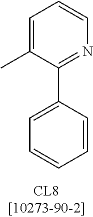 | 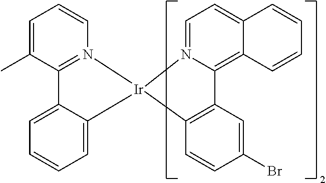 | 65% |
| Ir(L1Br)₂(CL9) | [Ir(L1Br)₂Cl]₂ | 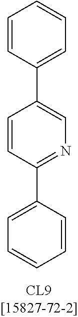 [SMILES: c1ccc(-c2ccc(-c3ccccc3)nc2)cc1] | 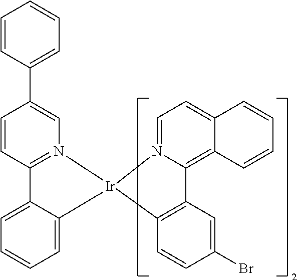 | 59% |
| Ir(L1Br)₂(CL10) | [Ir(L1Br)₂Cl]₂ | 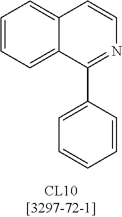 [SMILES: c1ccc(-c2nccc3ccccc23)cc1] | 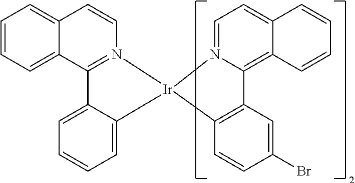 | 47% |
| Ir(L1Br)₂(CL11) | [Ir(L1Br)₂Cl]₂ | 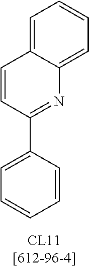 [SMILES: c1ccc(-c2ccc3ccccc3n2)cc1] | 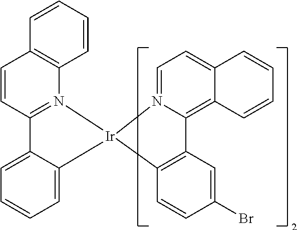 | 50% |
| Ir(L1Br)₂(CL12) | [Ir(L1Br)₂Cl]₂ | 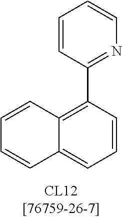 [SMILES: c1ccc(-c2cccc3ccccc23)nc1] | 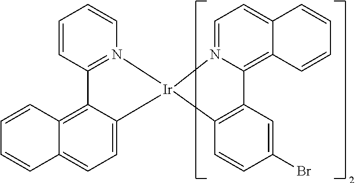 | 42% |
| Ir(L1Br)₂(L6) | [Ir(L1Br)₂Cl]₂ | 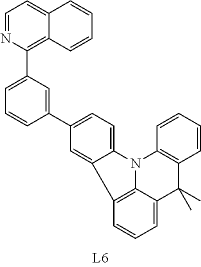 [SMILES: CC1(C)c2ccccc2-n2c3ccc(-c4cccc(-c5nccc6ccccc56)c4)cc3c3cccc1c32] | 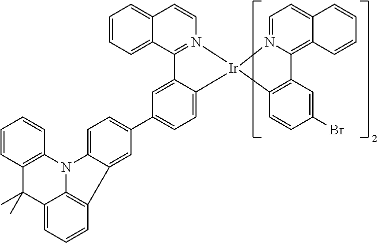 | 53% |
| Ir(L5Br)₂(L6) | [Ir(L5Br)₂Cl]₂ | 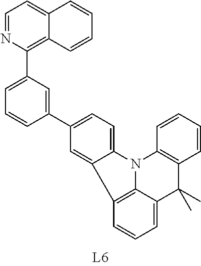 [SMILES: CC1(C)c2ccccc2-n2c3ccc(-c4cccc(-c5nccc6ccccc56)c4)cc3c3cccc1c32] | 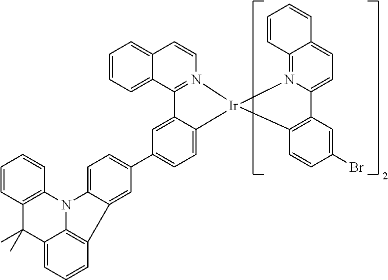 | 36% |
| Ir(L1Br)₂(L7) | [Ir(L1Br)₂Cl]₂ | 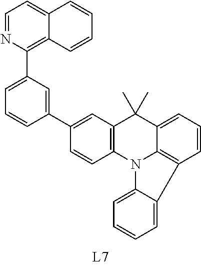 [SMILES: CC1(C)c2cc(-c3cccc(-c4nccc5ccccc45)c3)ccc2-n2c3ccccc3c3cccc1c32] | 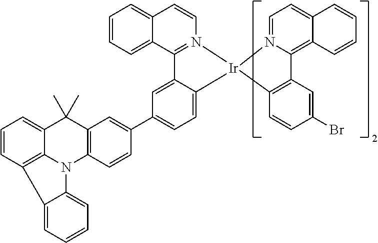 | 48% |
| Ir(L1Br)₂(L8) | [Ir(L1Br)₂Cl]₂ | 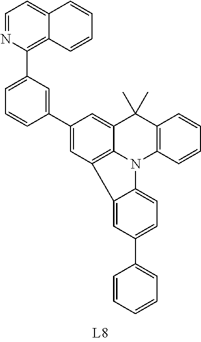 [SMILES: CC1(C)c2ccccc2-n2c3ccc(-c4ccccc4)cc3c3cc(-c4cccc(-c5nccc6ccccc56)c4)cc1c32] | 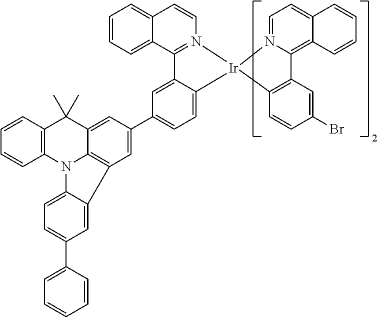 | 55% |
| Ir(L5Br)₂(L8) | [Ir(L5Br)₂Cl]₂ | 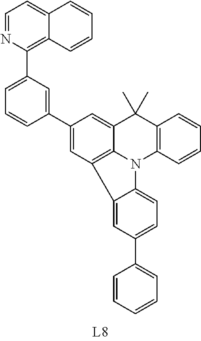 [SMILES: CC1(C)c2ccccc2-n2c3ccc(-c4ccccc4)cc3c3cc(-c4cccc(-c5nccc6ccccc56)c4)cc1c32] | 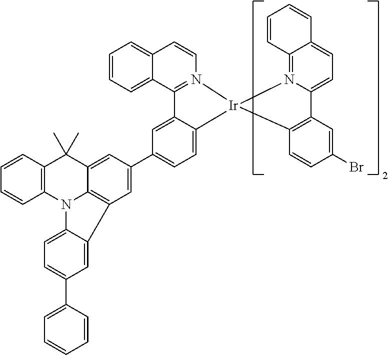 | 39% |
| Ir(L1Br)₂(L9) | [Ir(L1Br)₂Cl]₂ | 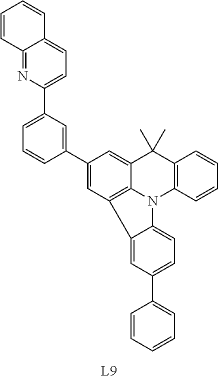 [SMILES: CC1(C)c2ccccc2-n2c3ccc(-c4ccccc4)cc3c3cc(-c4cccc(-c5ccc6ccccc6n5)c4)cc1c32] | 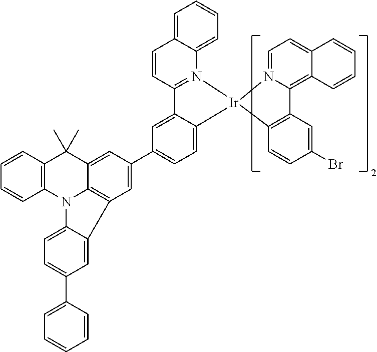 | 49% |
| Ir(L1Br)₂(L10) | [Ir(L1Br)₂Cl]₂ | 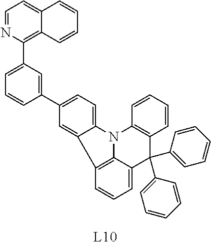 [SMILES: c1ccc(C2(c3ccccc3)c3ccccc3-n3c4ccc(-c5cccc(-c6nccc7ccccc67)c5)cc4c4cccc2c43)cc1] | 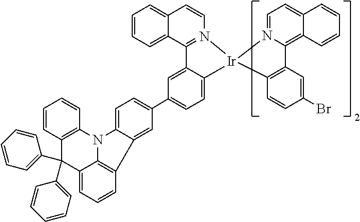 | 65% |
| Ir(L1Br)₂(L11) | [Ir(L1Br)₂Cl]₂ | 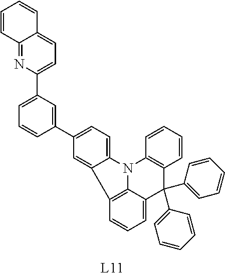 [SMILES: c1ccc(C2(c3ccccc3)c3ccccc3-n3c4ccc(-c5cccc(-c6ccc7ccccc7n6)c5)cc4c4cccc2c43)cc1] | 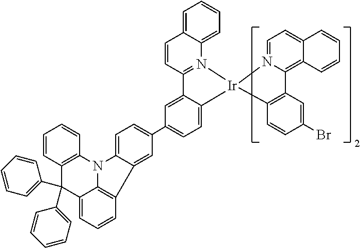 | 56% |
| Ir(L1Br)₂(L12) | [Ir(L1Br)₂Cl]₂ | 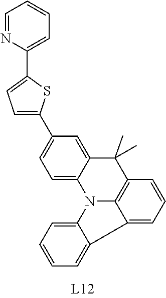 [SMILES: CC1(C)c2cc(-c3ccc(-c4ccccn4)s3)ccc2-n2c3ccccc3c3cccc1c32] | 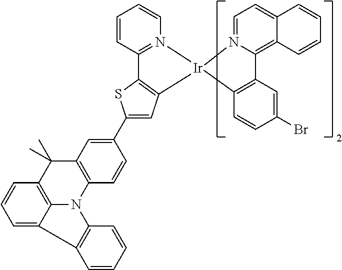 | 61% |
| Ir(L1Br)₂(L13) | [Ir(L1Br)₂Cl]₂ | 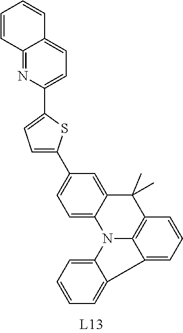 [SMILES: CC1(C)c2cc(-c3ccc(-c4ccc5ccccc5n4)s3)ccc2-n2c3ccccc3c3cccc1c32] | 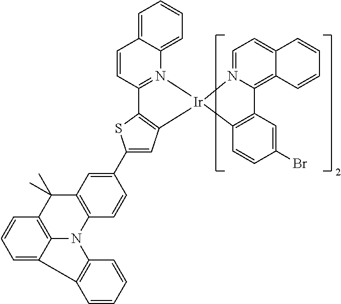 | 47% |
| Ir(L1Br)₂(L14) | [Ir(L1Br)₂Cl]₂ | 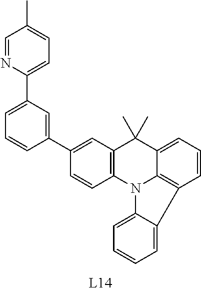 [SMILES: Cc1ccc(-c2cccc(-c3ccc4c(c3)C(C)(C)c3cccc5c6ccccc6n-4c35)c2)nc1] | 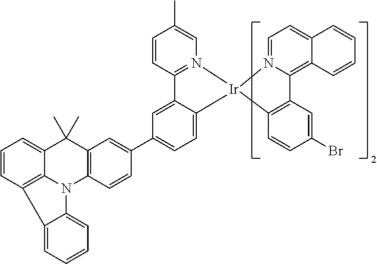 | 52% |
| Ir(L2Br)₂(L15) | [Ir(L2Br)₂Cl]₂ | 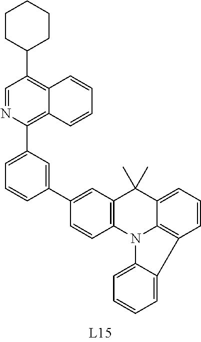 [SMILES: CC1(C)c2cc(-c3cccc(-c4ncc(C5CCCCC5)c5ccccc45)c3)ccc2-n2c3ccccc3c3cccc1c32] | 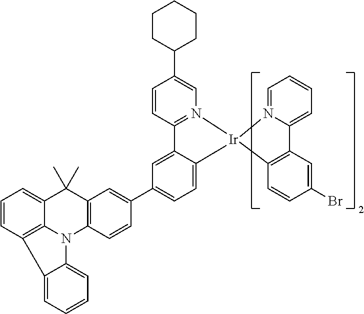 | 63% |
| Ir(L2Br)₂(L16) | [Ir(L2Br)₂Cl]₂ | 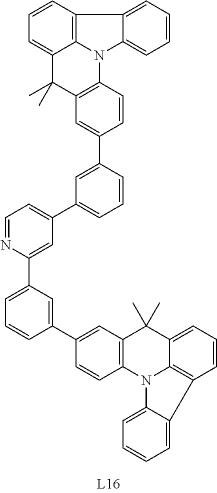 [SMILES: CC1(C)c2cc(-c3cccc(-c4ccnc(-c5cccc(-c6ccc7c(c6)C(C)(C)c6cccc8c9ccccc9n-7c68)c5)c4)c3)ccc2-n2c3ccccc3c3cccc1c32] | 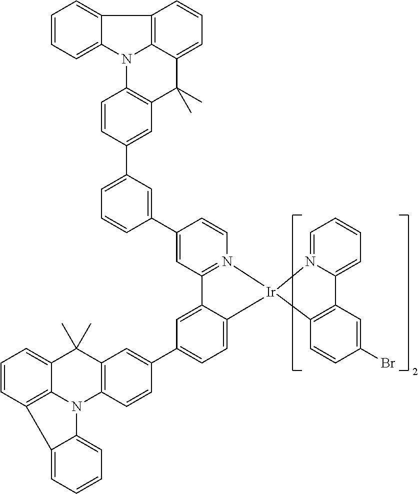 | 25% |
| Ir(L2Br)₂(L15) | [Ir(L2Br)₂Cl]₂ | 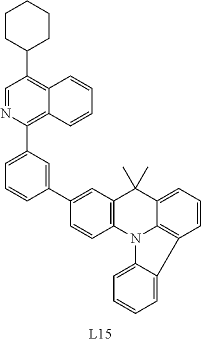 [SMILES: CC1(C)c2cc(-c3cccc(-c4ncc(C5CCCCC5)c5ccccc45)c3)ccc2-n2c3ccccc3c3cccc1c32] | 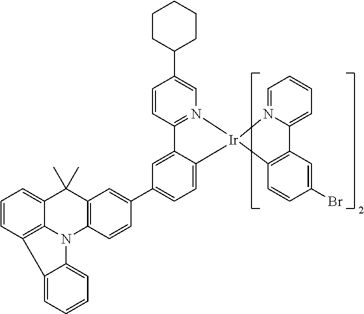 | 63% |
| Ir(L2Br)₂(L16) | [Ir(L2Br)₂Cl]₂ | 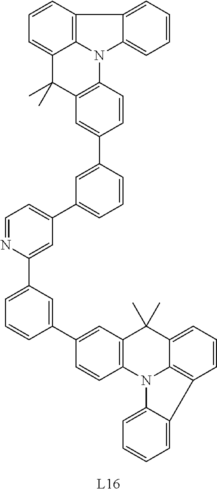 [SMILES: CC1(C)c2cc(-c3cccc(-c4ccnc(-c5cccc(-c6ccc7c(c6)C(C)(C)c6cccc8c9ccccc9n-7c68)c5)c4)c3)ccc2-n2c3ccccc3c3cccc1c32] | 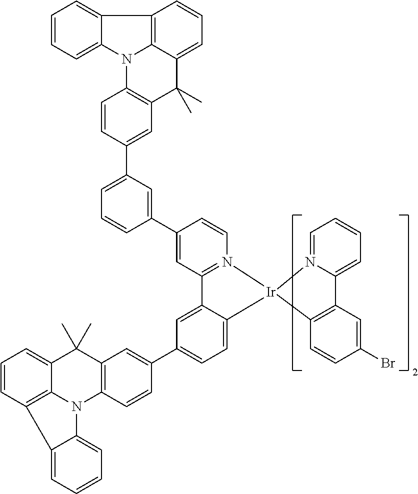 | 25% |

### F) Preparation of the Complexes of the Invention

### F.1) Homoleptic 1-phenylisoquinoline-Iridium complexes

### K1/tris{1-[3-(8,8-dimethyl-8H-indolo[3,2,1-de]acridin-3-yl)phen-1-yl]isoquinolinato}iridium(III)

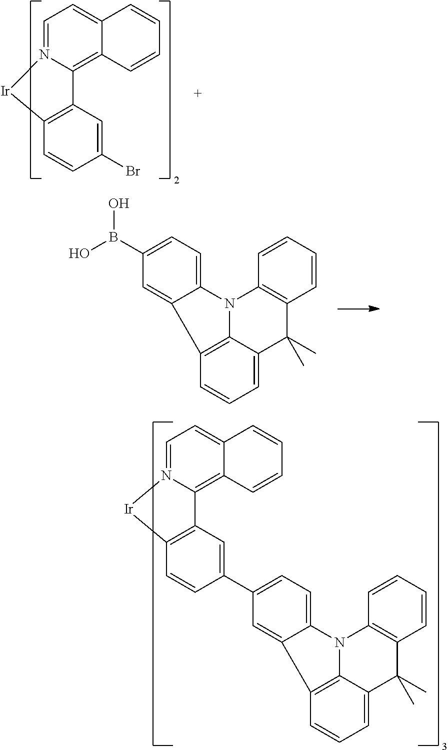

7.50 g (7.2 mmol) of Ir(L1Br)₃, 7.10 g (21.7 mmol) of 8,8-dimethyl-8H-indolo[3,2,1-de]acridin-3-ylboronic acid [1307793-50-5], 12.62 g (54.8 mmol) of potassium phosphate monohydrate, 49.4 mg (0.22 mmol) of palladium(II) acetate and 0.3 mL (0.30 mmol) of tri-t-butylphosphine solution (1M in toluene) are heated to reflux in a mixture of 150 mL of toluene, 100 mL of dioxane and 175 mL of water while stirring vigorously for 15 h. After cooling to room temperature, the phases are separated. The aqueous phase is washed three times with 100 mL each time of toluene and twice with 100 mL each time of dichloromethane. The combined organic phases are washed three times with 250 mL each time of water, dried over MgSO₄ and concentrated under reduced pressure to about 150 mL. 450 mL of ethanol are slowly added dropwise while stirring, then the suspension is stirred for a further 1 h. The solids are filtered off with suction, washed twice with 50 mL each time of ethanol, dried under reduced pressure and then extracted in a hot extractor with about 250 mL of toluene over 75 g of alumina (basic, activity level 1). The solvent is concentrated under reduced pressure to about 75 mL. The suspension is stirred for a further 1 h, then the solids are filtered off with suction and dried under reduced pressure. The product is purified by chromatography using silica gel with a THF/MeOH mixture (90:10 v:v), freed of the solvent under reduced pressure and finally heated at 300° C. under high vacuum (pressure about 10⁻⁶ mbar). This leaves 4.95 g (3.0 mmol, 42% of theory) as a red powder having a purity of 99.8% by HPLC.

In an analogous manner, it is possible to prepare the complexes K2 to K36. When solubility in toluene is too low, the hot extraction can optionally be conducted with chlorobenzene or dichlorobenzene. Illustrative typical eluents for the chromatographic purification are THF/MeOH, dichloromethane/heptane, dichloromethane/ethyl acetate, toluene/ethyl acetate and pure toluene.

| Ex. | Boronic acid/ester [CAS] or Ex. | Product | Yield |
|---|---|---|---|
| K2 | 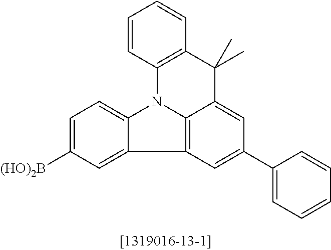 [SMILES: CC1(C)c2ccccc2-n2c3ccc(B(O)O)cc3c3cc(-c4ccccc4)cc1c32] | 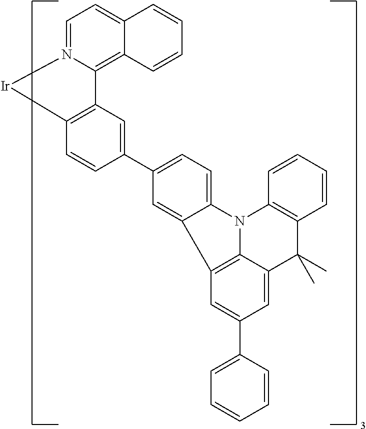 | 47% |
| K3 | 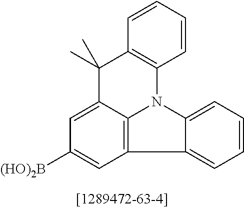 [SMILES: CC1(C)c2ccccc2-n2c3ccccc3c3cc(B(O)O)cc1c32] | 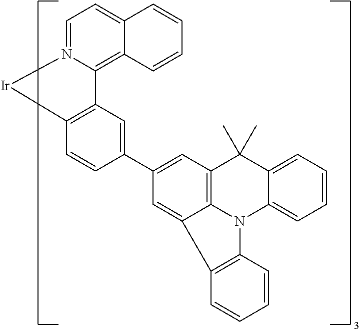 | 52% |
| K4 | 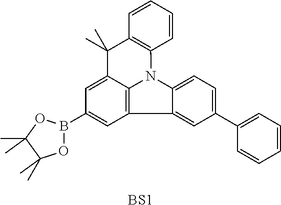 [SMILES: CC1(C)c2ccccc2-n2c3ccc(-c4ccccc4)cc3c3cc(B4OC(C)(C)C(C)(C)O4)cc1c32 ; "BS1"] | 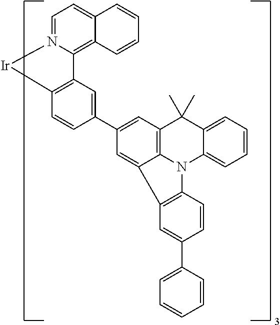 | 61% |
| K5 | 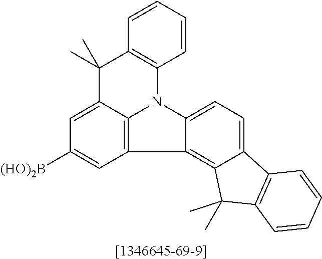 | 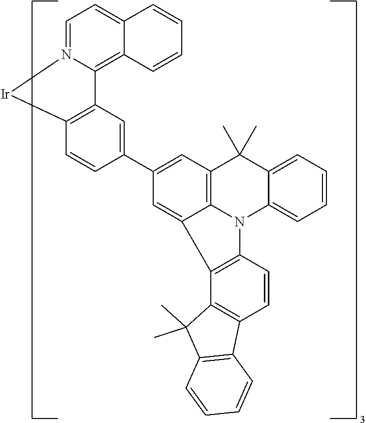 | 39% |
| K6 | 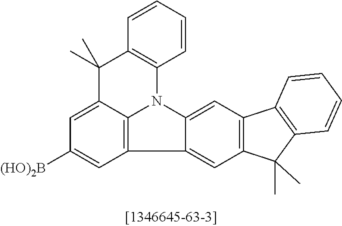 [SMILES: CC1(C)c2ccccc2-c2cc3c(cc21)c1cc(B(O)O)cc2c1n3-c1ccccc1C2(C)C] | 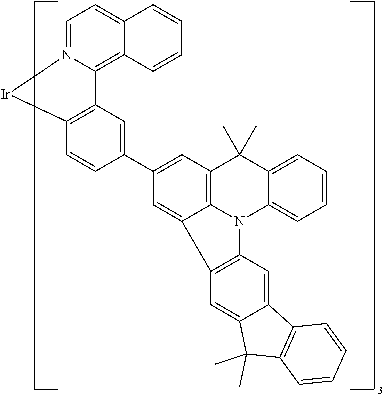 | 32% |
| K7 | 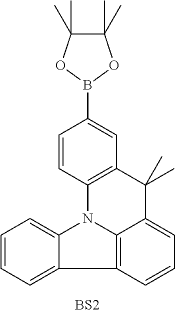 | 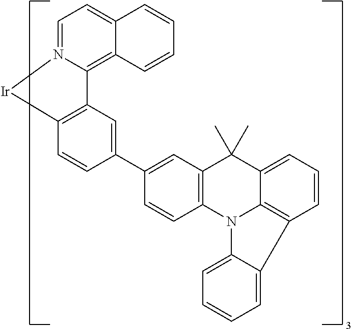 | 58% |
| K8 | 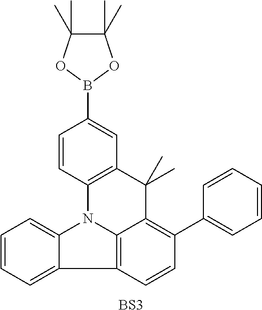 | 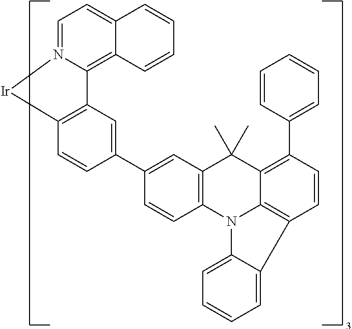 | 44% |
| K9 | 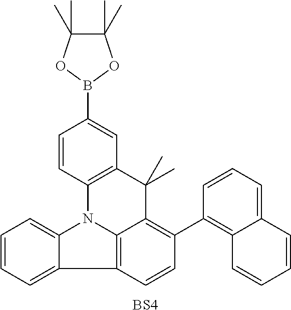 | 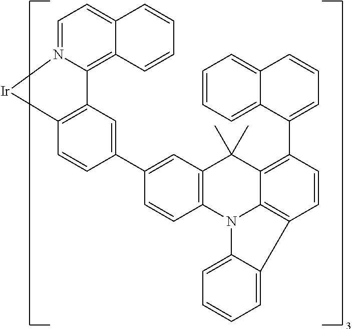 | 31% |
| K10 | 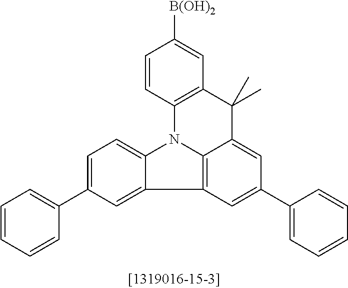 [SMILES: CC1(C)c2cc(B(O)O)ccc2-n2c3ccc(-c4ccccc4)cc3c3cc(-c4ccccc4)cc1c32] | 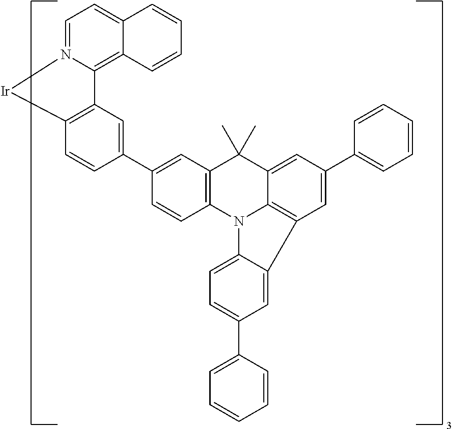 | 47% |
| K11 | 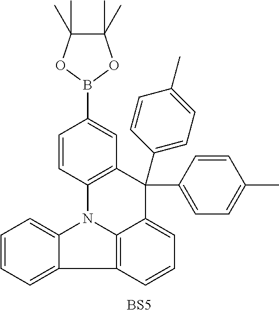 | 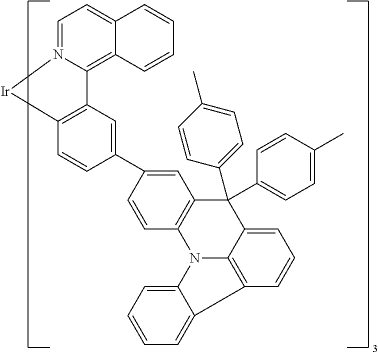 | 52% |
| K12 | 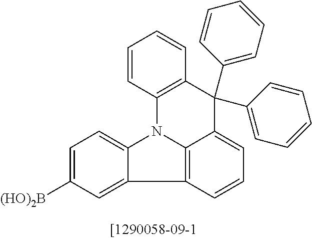 [SMILES: OB(O)c1ccc2c(c1)c1cccc3c1n2-c1ccccc1C3(c1ccccc1)c1ccccc1] | 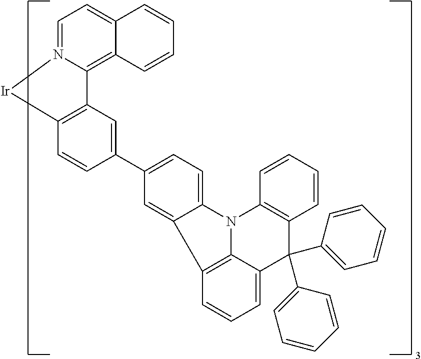 | 57% |
| K13 | 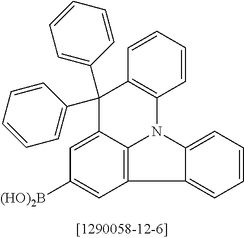 [SMILES: OB(O)c1cc2c3c(c1)c1ccccc1n3-c1ccccc1C2(c1ccccc1)c1ccccc1] | 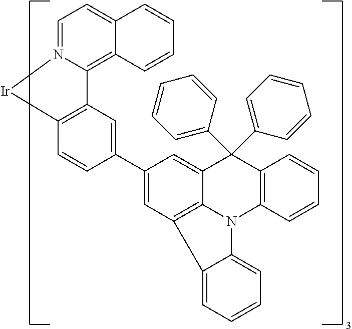 | 40% |
| K14 | 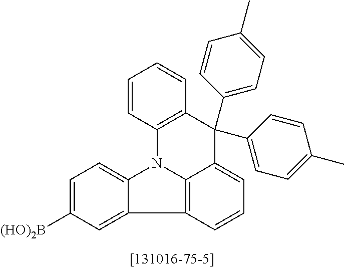 [SMILES: Cc1ccc(C2(c3ccc(C)cc3)c3ccccc3-n3c4ccc(B(O)O)cc4c4cccc2c43)cc1] | 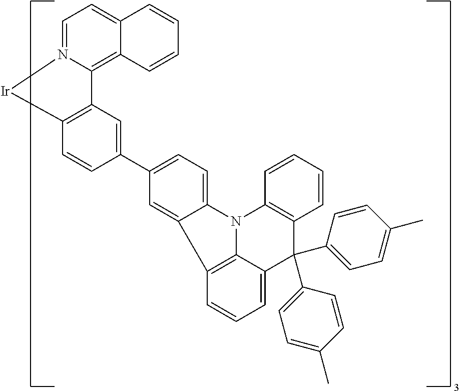 | 52% |
| K15 | 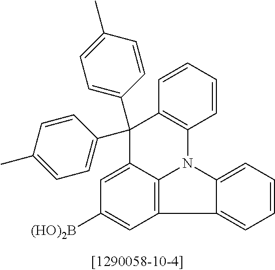 [SMILES: Cc1ccc(C2(c3ccc(C)cc3)c3ccccc3-n3c4ccccc4c4cc(B(O)O)cc2c43)cc1] | 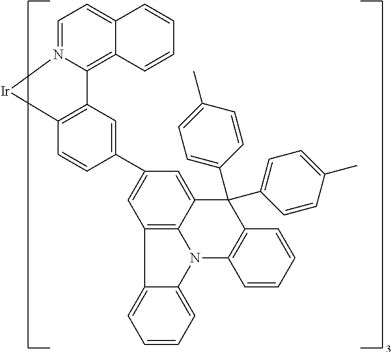 | 43% |
| K16 | 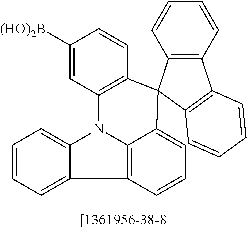 [SMILES: OB(O)c1ccc2c(c1)-n1c3ccccc3c3cccc(c31)C21c2ccccc2-c2ccccc21] | 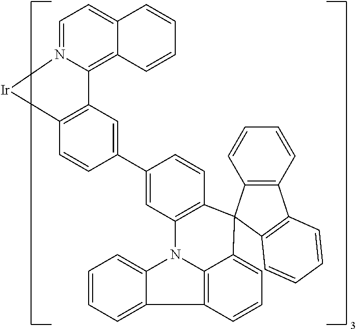 | 38% |
| K17 | 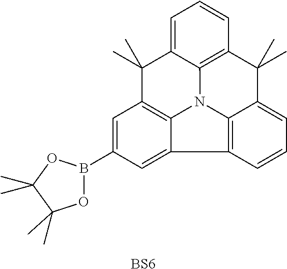 | 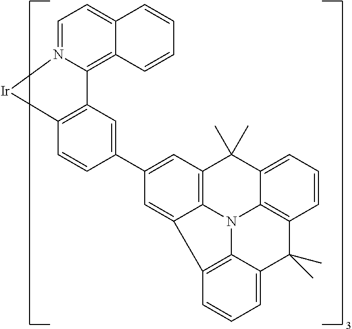 | 11% |
| K18 | 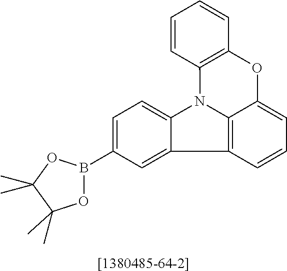 | 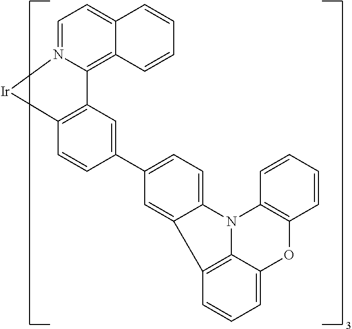 | 33% |
| K19 | 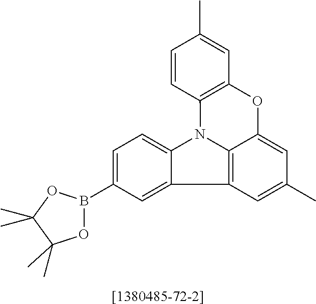 | 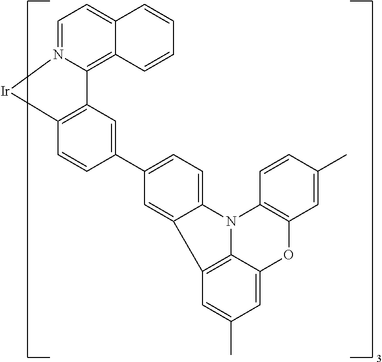 | 38% |
| K20 | 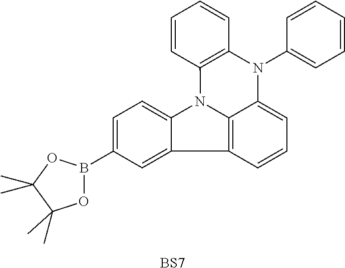 | 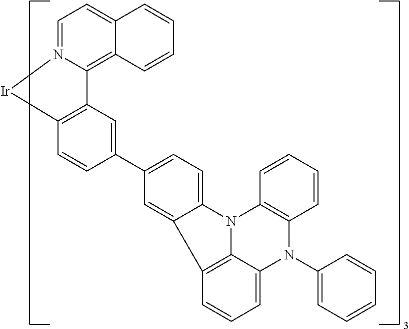 | 42% |
| K21 | 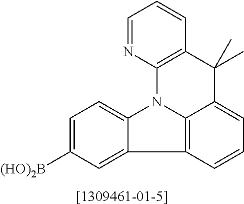 | 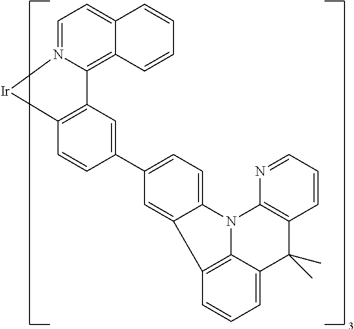 | 42% |
| K22 | 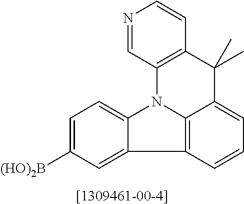 | 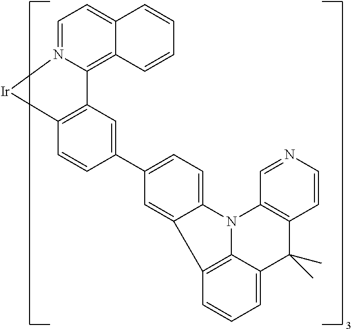 | 39% |
| K23 | 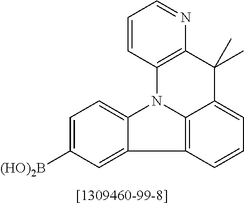 | 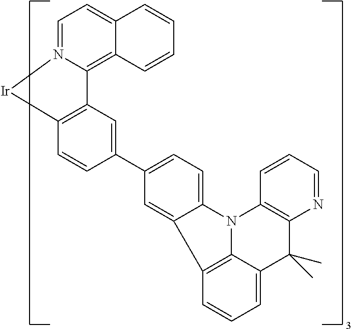 | 47% |
| K24 | 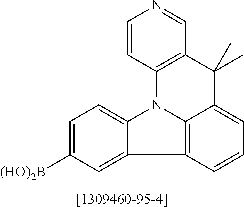 | 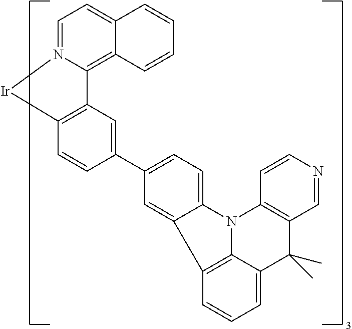 | 46% |
| K25 | 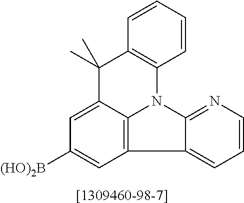 | 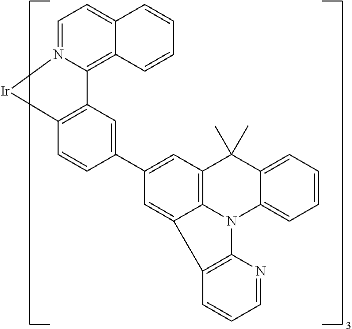 | 51% |
| K26 | 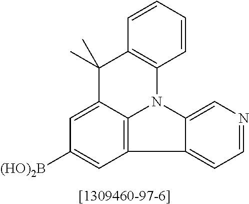 | 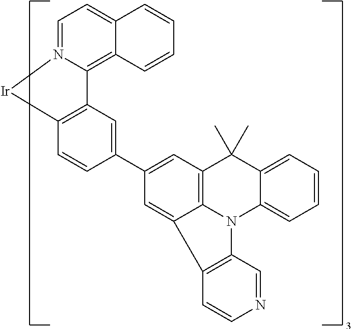 | 48% |
| K27 | 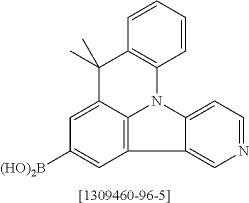 | 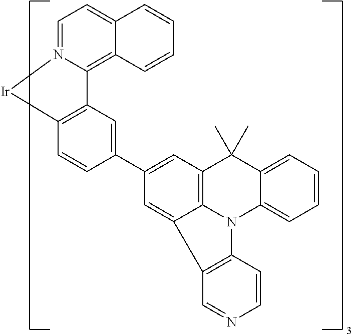 | 36% |
| K28 | 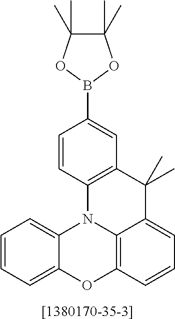 | 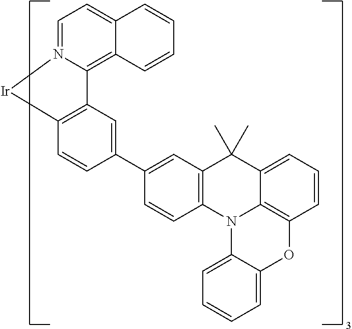 | 28% |
| K29 | 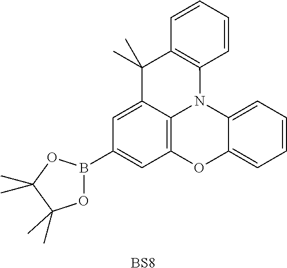 | 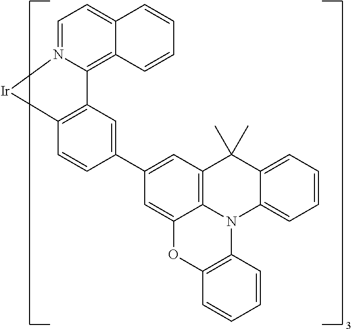 | 37% |
| K30 | 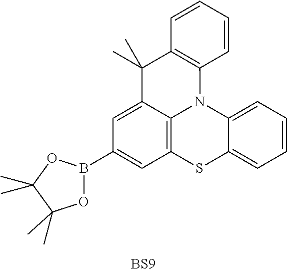 | 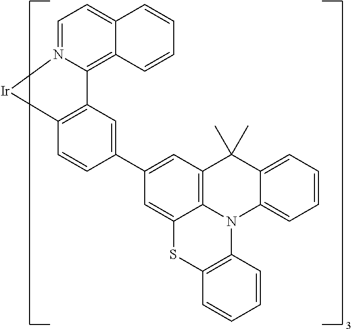 | 32% |
| K31 | 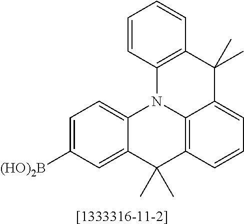 | 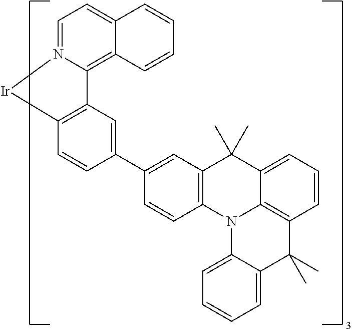 | 21% |
| K32 | 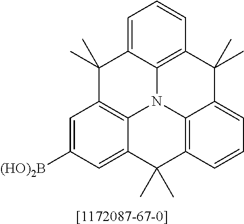 | 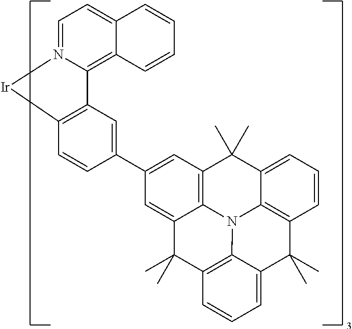 | 4% |
| K33 | 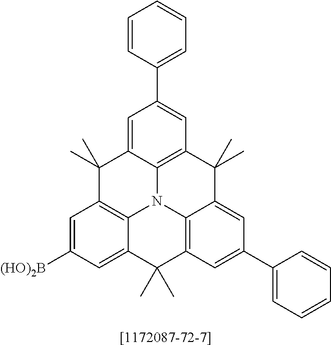 | 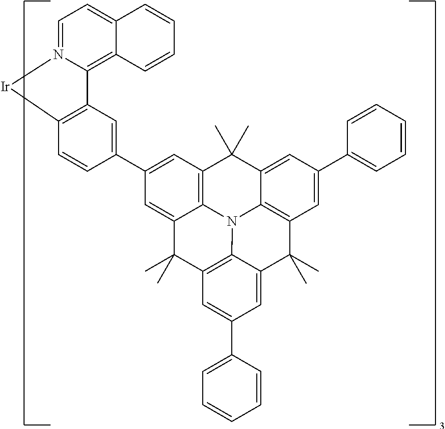 | 9% |
| K34 | 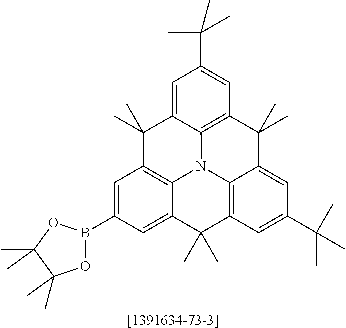 | 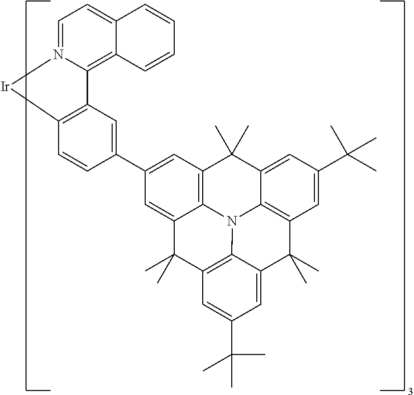 | 16% |
| K35 | 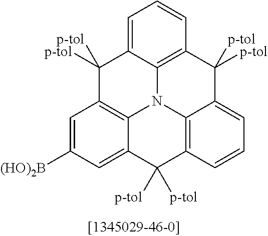 | 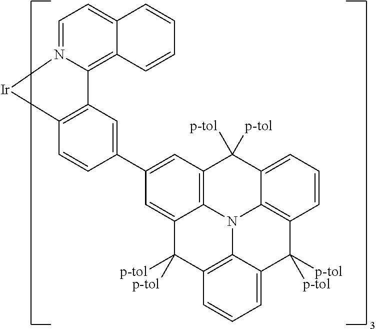 | 11% |
| K36 | 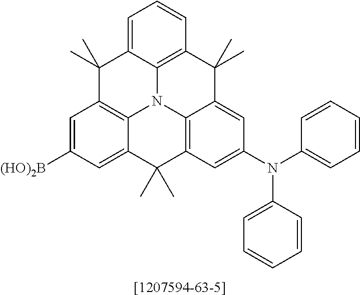 | 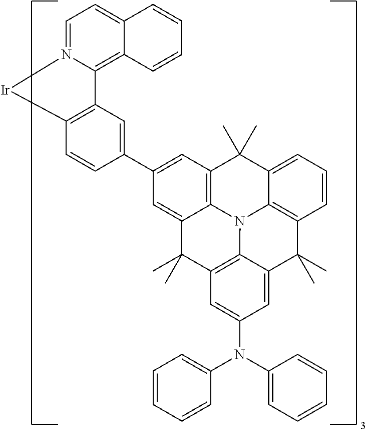 | 17% |

### F.2) Homoleptic 3-phenylisoquinoline-irdium complexes

Analogously to the method described under F.1, it is possible to prepare the complexes K37 to K42 from Ir(L3Br)₃:

| Ex. | Boronic acid/ester [CAS] or Ex. | Product | Yield |
|---|---|---|---|
| K37 | 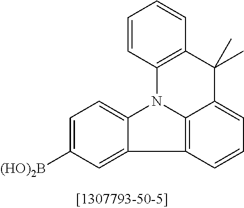 [SMILES: CC1(C)c2ccccc2-n2c3ccc(B(O)O)cc3c3cccc1c32] | 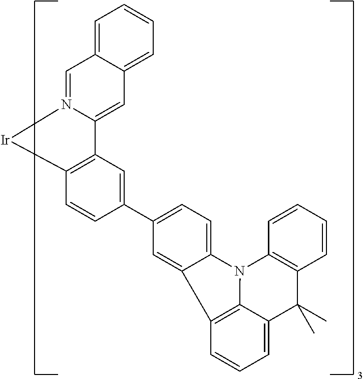 | 39% |
| K38 | 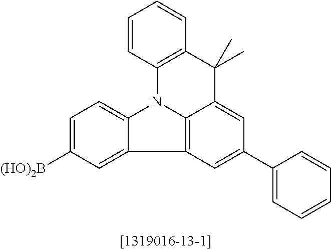 [SMILES: CC1(C)c2ccccc2-n2c3ccc(B(O)O)cc3c3cc(-c4ccccc4)cc1c32] | 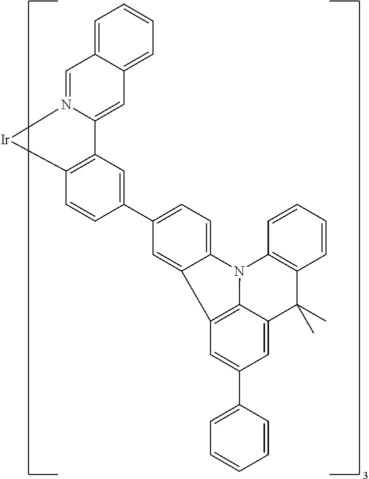 | 48% |
| K39 | 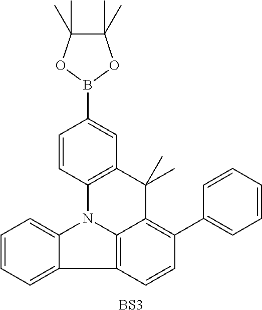 | 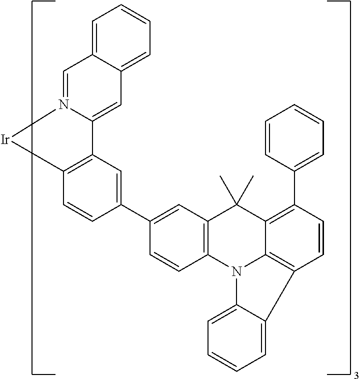 | 36% |
| K40 | 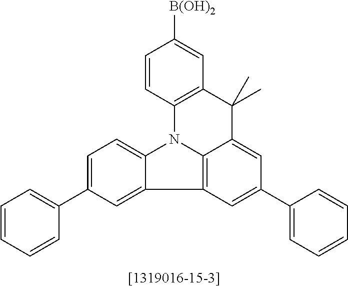 | 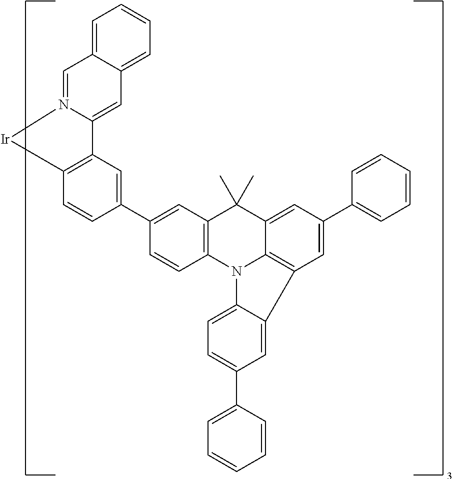 | 51% |
| K41 | 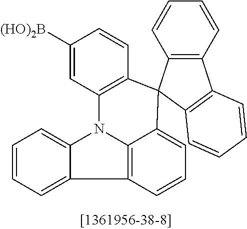 [SMILES: OB(O)c1ccc2c(c1)-n1c3ccccc3c3cccc(c31)C21c2ccccc2-c2ccccc21] | 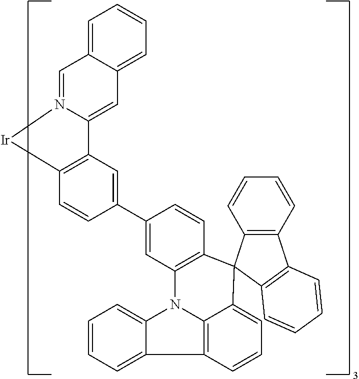 | 49% |
| K42 | 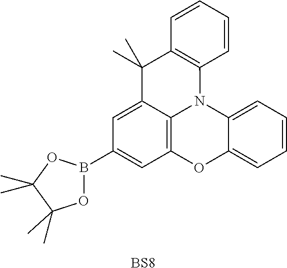 | 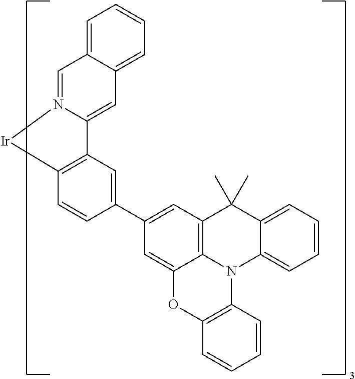 | 28% |

### F.3) Homoleptic 2-phenylpyridine-iridium complexes

Analogously to the method described under F.1, it is possible to prepare the complexes K43 to K58 from Ir(L2Br)₃:

| | Boronic acid/ester | | |
|---|---|---|---|
| Ex. | [CAS] or Ex. | Product | Yield |
| K43 | 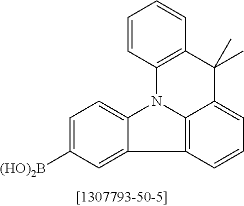 [SMILES: CC1(C)c2ccccc2-n2c3ccc(B(O)O)cc3c3cccc1c32] | 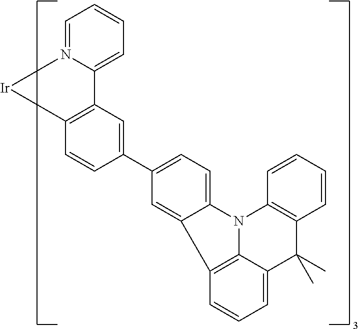 | 57% |
| K44 | 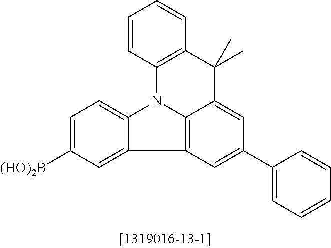 [SMILES: CC1(C)c2ccccc2-n2c3ccc(B(O)O)cc3c3cc(-c4ccccc4)cc1c32] | 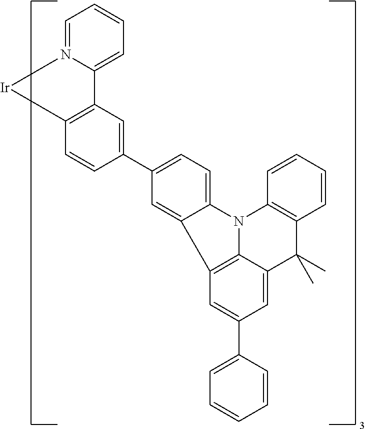 | 48% |
| K45 | 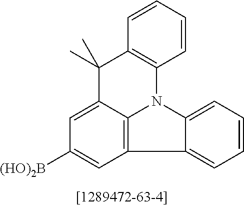 [SMILES: CC1(C)c2ccccc2-n2c3ccccc3c3cc(B(O)O)cc1c32] | 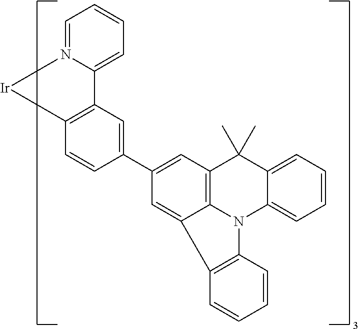 | 41% |
| K46 | 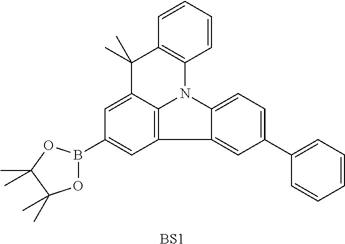 [SMILES: CC1(C)c2ccccc2-n2c3ccc(-c4ccccc4)cc3c3cc(B4OC(C)(C)C(C)(C)O4)cc1c32 ; "BS1"] | 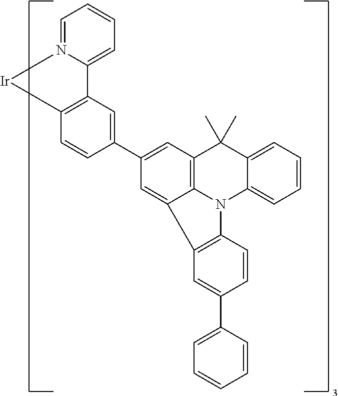 | 49% |
| K47 | 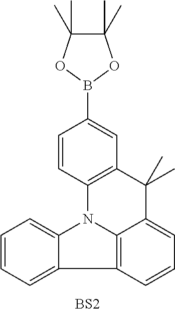 | 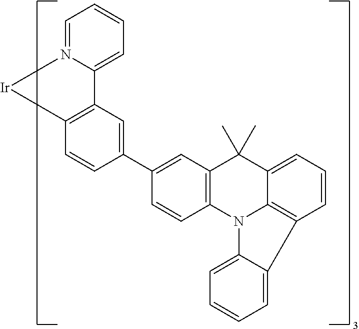 | 44% |
| K48 | 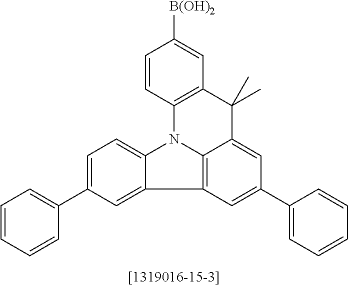 [SMILES: CC1(C)c2cc(B(O)O)ccc2-n2c3ccc(-c4ccccc4)cc3c3cc(-c4ccccc4)cc1c32] | 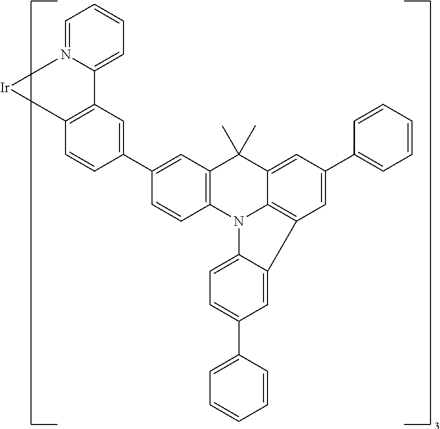 | 53% |
| K49 | 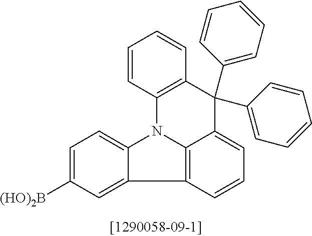 [SMILES: OB(O)c1ccc2c(c1)c1cccc3c1n2-c1ccccc1C3(c1ccccc1)c1ccccc1] | 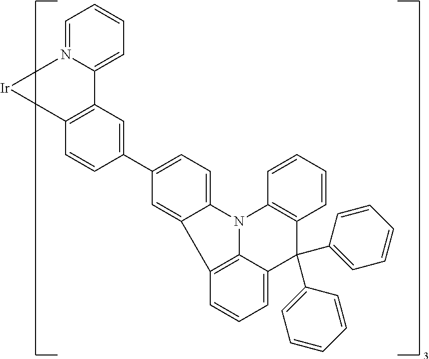 | 36% |
| K50 | 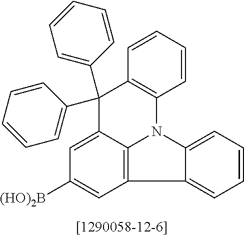 [SMILES: OB(O)c1cc2c3c(c1)c1ccccc1n3-c1ccccc1C2(c1ccccc1)c1ccccc1] | 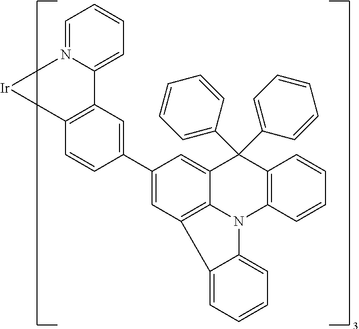 | 21% |
| K51 | 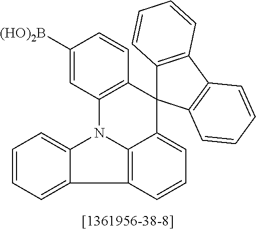 [SMILES: OB(O)c1ccc2c(c1)-n1c3ccccc3c3cccc(c31)C21c2ccccc2-c2ccccc21] | 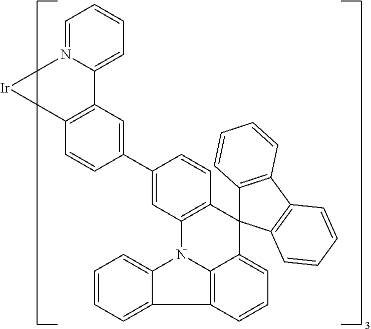 | 29% |
| K52 | 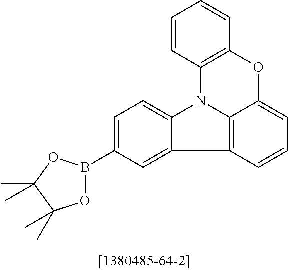 [SMILES: CC1(C)OB(c2ccc3c(c2)c2cccc4c2n3-c2ccccc2O4)OC1(C)C] | 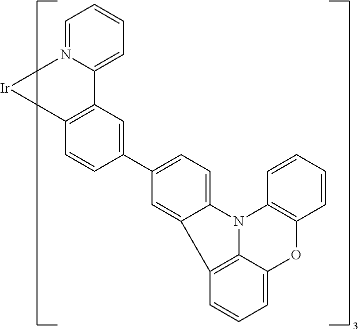 | 32% |
| K53 | 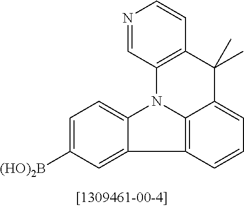 [SMILES: CC1(C)c2ccncc2-n2c3ccc(B(O)O)cc3c3cccc1c32] | 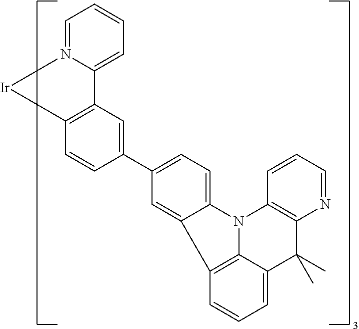 | 41% |
| K54 | 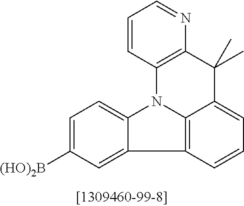 [SMILES: CC1(C)c2ncccc2-n2c3ccc(B(O)O)cc3c3cccc1c32] | 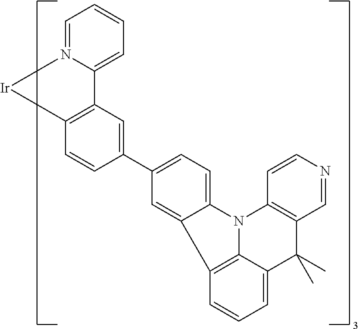 | 38% |
| K55 | 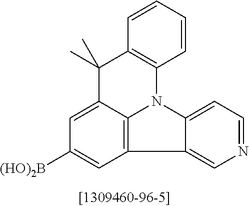 [SMILES: CC1(C)c2ccccc2-n2c3ccncc3c3cc(B(O)O)cc1c32] | 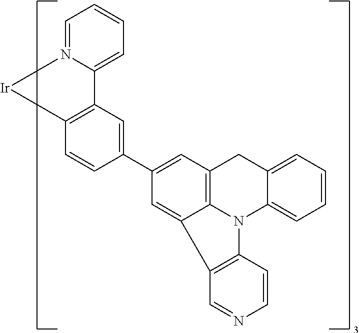 | 27% |
| K56 | 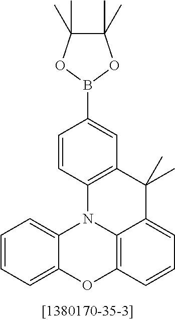 [SMILES: CC1(C)c2cc(B3OC(C)(C)C(C)(C)O3)ccc2N2c3ccccc3Oc3cccc1c32] | 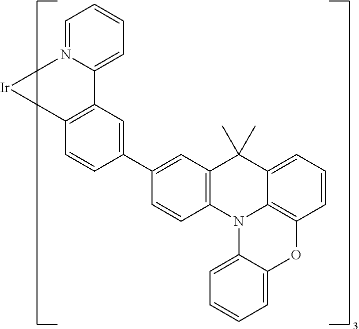 | 17% |
| K57 | 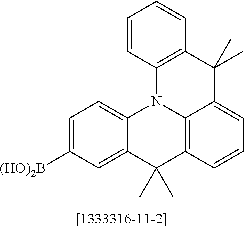 [SMILES: CC1(C)c2ccccc2N2c3ccc(B(O)O)cc3C(C)(C)c3cccc1c32] | 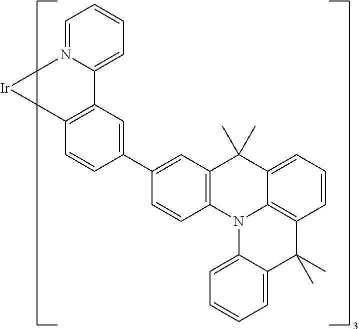 | 39% |
| K58 | 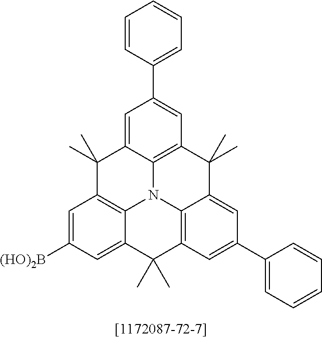 [SMILES: CC1(C)c2cc(B(O)O)cc3c2N2c4c1cc(-c1ccccc1)cc4C(C)(C)c1cc(-c4ccccc4)cc(c12)C3(C)C] | 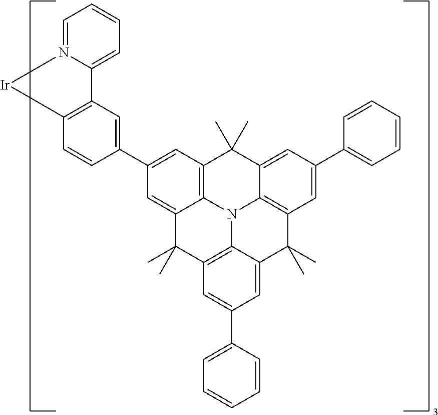 | 8% |

### F.4) Homoleptic benzo[4,5]imidazo[1,2-c]quinazoline-iridium complexes

Analogously to the method described under F.1, it is possible to prepare the complexes K59 to K66 from Ir(L4Br)₃:

| | Boronic acid/ester | | |
|---|---|---|---|
| Ex. | [CAS] or Ex. | Product | Yield |
| K59 | 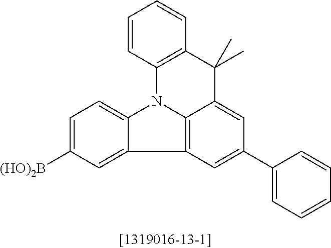 [SMILES: CC1(C)c2ccccc2-n2c3ccc(B(O)O)cc3c3cc(-c4ccccc4)cc1c32] | 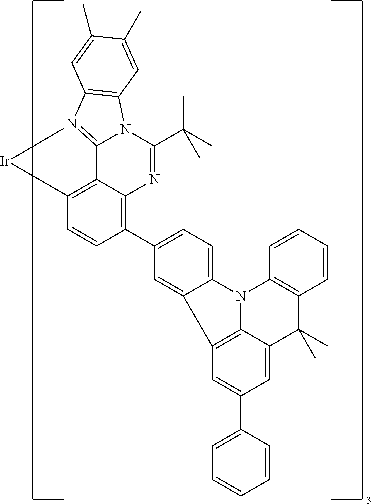 | 40% |
| K60 | 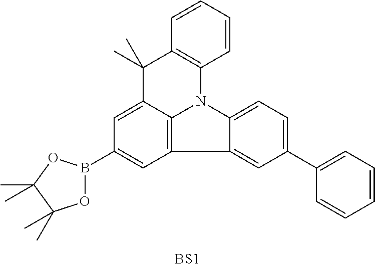 [SMILES: CC1(C)c2ccccc2-n2c3ccc(-c4ccccc4)cc3c3cc(B4OC(C)(C)C(C)(C)O4)cc1c32 ; "BS1"] | 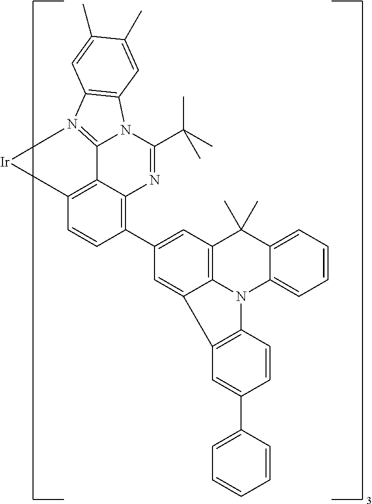 | 38% |
| K61 | 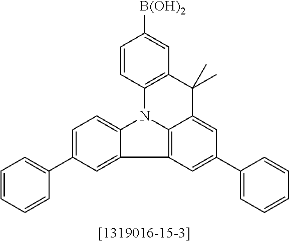 [SMILES: CC1(C)c2cc(B(O)O)ccc2-n2c3ccc(-c4ccccc4)cc3c3cc(-c4ccccc4)cc1c32] | 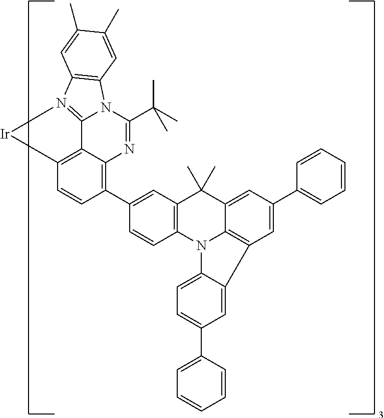 | 52% |
| K62 | 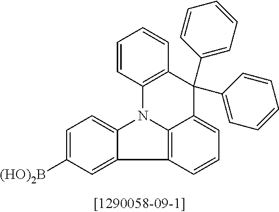 [SMILES: OB(O)c1ccc2c(c1)c1cccc3c1n2-c1ccccc1C3(c1ccccc1)c1ccccc1] | 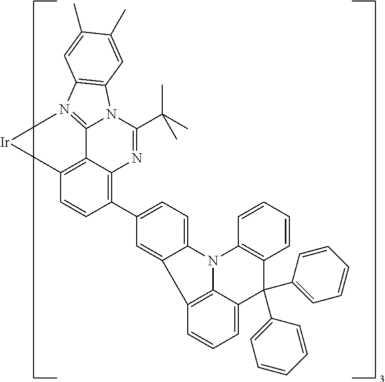 | 39% |
| K63 | 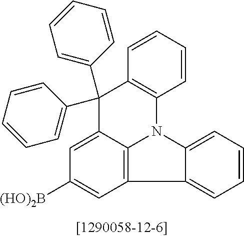 [SMILES: OB(O)c1cc2c3c(c1)c1ccccc1n3-c1ccccc1C2(c1ccccc1)c1ccccc1] | 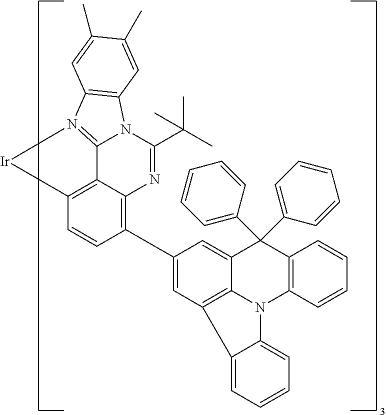 | 28% |
| K64 | 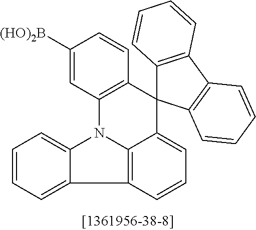 [SMILES: OB(O)c1ccc2c(c1)-n1c3ccccc3c3cccc(c31)C21c2ccccc2-c2ccccc21] | 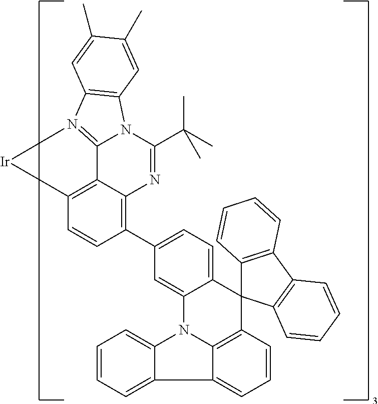 | 12% |
| K65 | 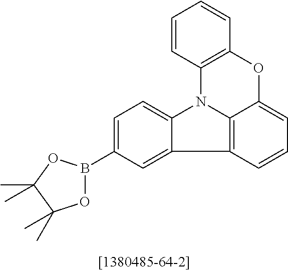 [SMILES: CC1(C)OB(c2ccc3c(c2)c2cccc4c2n3-c2ccccc2O4)OC1(C)C] | 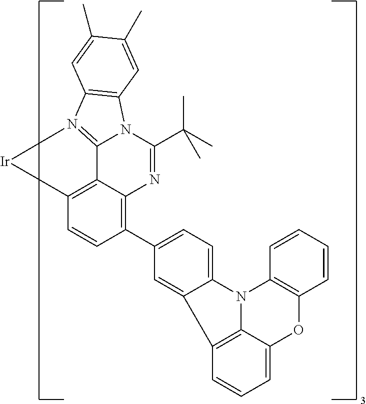 | 23% |
| K66 | 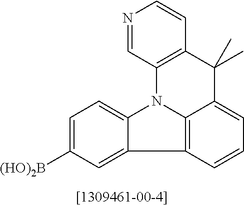 [SMILES: CC1(C)c2ccncc2-n2c3ccc(B(O)O)cc3c3cccc1c32] | 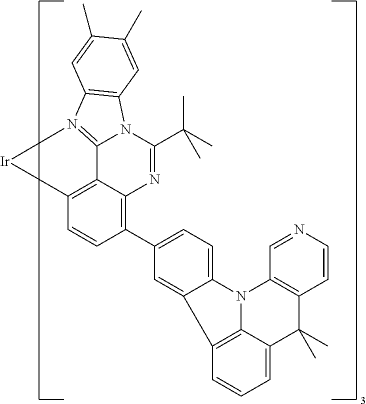 | 17% |

### F.5) Heteroleptic Complexes

### F.5.1) K67/(O,O′-Acetylacetonato)-bis-{1-[3-(8,8-dimethyl-8H-indolo[3,2,1-de]acridin-3-yl)phen-1-yl]isoquinolinato}iridium(III)

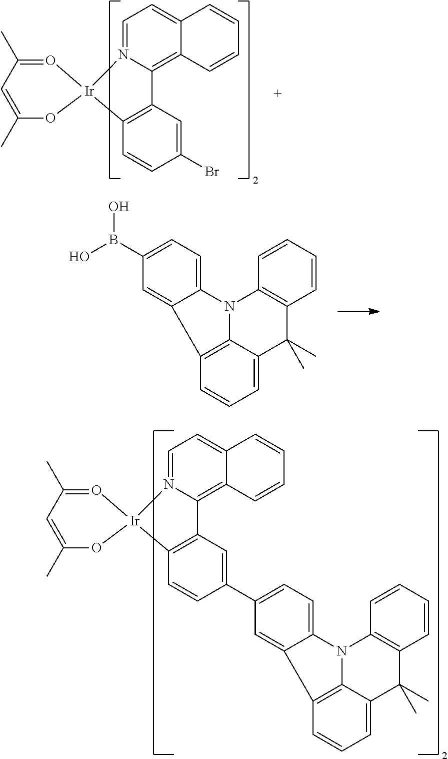

6.78 g (7.9 mmol) of Ir(L1Br)₂(CL1), 5.24 g (16.0 mmol) of 8,8-dimethyl-8H-indolo[3,2,1-de]acridin-3-ylboronic acid [1307793-50-5], 3.07 g (52.8 mmol) of potassium fluoride, 44.9 mg (0.20 mmol) of palladium(II) acetate and 0.3 mL (0.3 mmol) of tri-t-butylphosphine solution (1M in toluene) are heated to reflux in 300 mL of THF while stirring vigorously for 12 h. After cooling to room temperature, the solvent is removed completely under reduced pressure. The remaining residue is extracted in a hot extractor with 250 mL of toluene over about 50 g of alumina (basic, activity level 1). The solvent is removed under reduced pressure and the remaining residue is purified by chromatography using silica gel with a THF/MeOH mixture (98:2 v:v). The solvent is removed under reduced pressure and the residue is heated at 250° C. under high vacuum (pressure about 10⁻⁶ mbar). This leaves 2.79 g (2.2 mmol, 28% of theory) as a red powder having a purity of 99.9% by HPLC.

In an analogous manner, it is possible to prepare the complexes K68 to K85. Illustrative typical eluents for the chromatographic purification are THF/MeOH, dichloromethane/heptane, dichloromethane/ethyl acetate, toluene/ethyl acetate and pure toluene.

| | | Boronic acid/ester | | |
|---|---|---|---|---|
| Ex. | Ir reactant | [CAS] or Ex. | Product | Yield |
| K68 | Ir(L1Br)₂(CL2) | 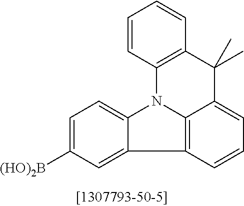 [SMILES: CC1(C)c2ccccc2-n2c3ccc(B(O)O)cc3c3cccc1c32] | 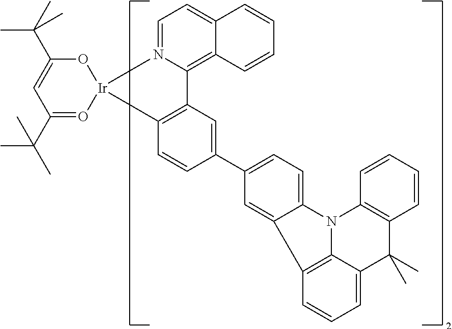 | 43% |
| K69 | Ir(L1Br)₂(CL2) | 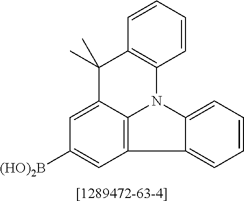 | 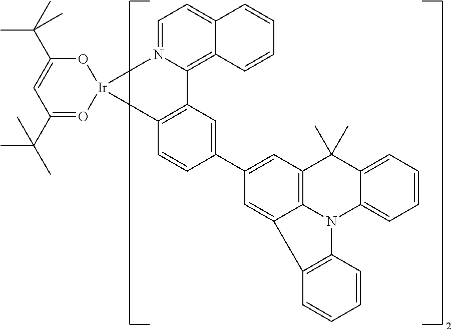 | 36% |
| K70 | Ir(L1Br)₂(CL2) | 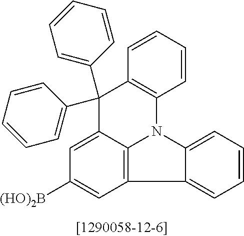 [SMILES: OB(O)c1cc2c3c(c1)c1ccccc1n3-c1ccccc1C2(c1ccccc1)c1ccccc1] | 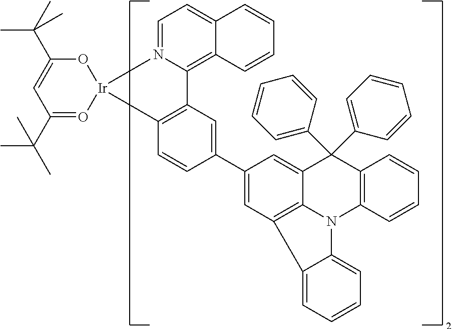 | 29% |
| K71 | Ir(L1Br)₂(CL2) | 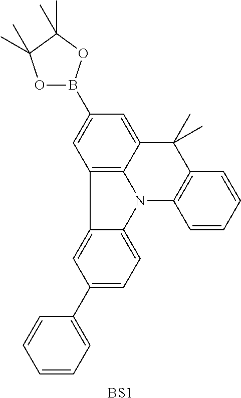 | 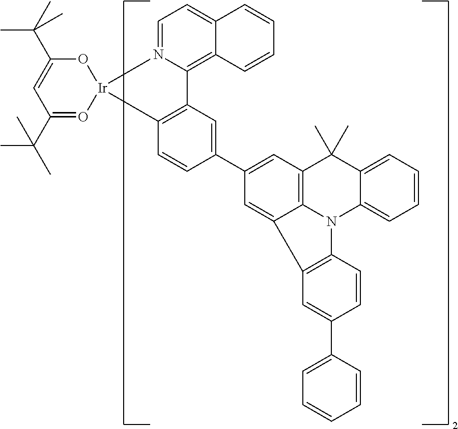 | 44% |
| K72 | Ir(L1Br)₂(CL2) | 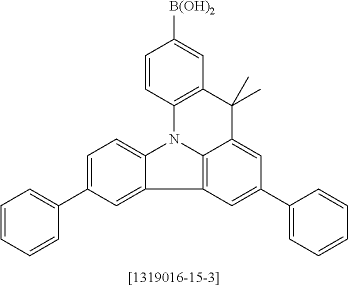 [SMILES: CC1(C)c2cc(B(O)O)ccc2-n2c3ccc(-c4ccccc4)cc3c3cc(-c4ccccc4)cc1c32] | 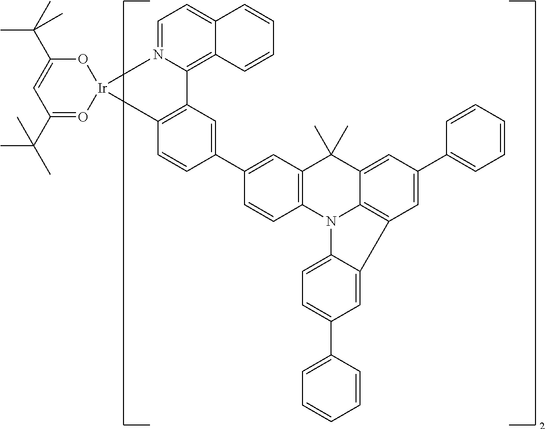 | 39% |
| K73 | Ir(L1Br)₂(CL2) | 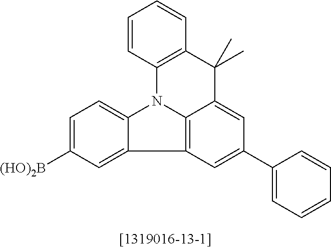 [SMILES: CC1(C)c2ccccc2-n2c3ccc(B(O)O)cc3c3cc(-c4ccccc4)cc1c32] | 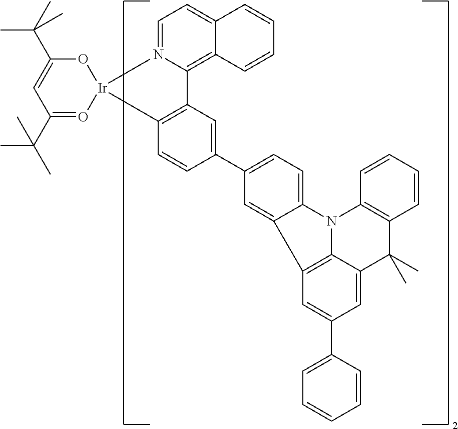 | 41% |
| K74 | Ir(L1Br)₂(CL3) | 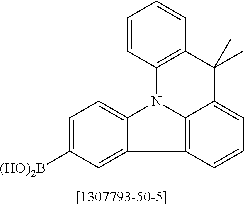 [SMILES: CC1(C)c2ccccc2-n2c3ccc(B(O)O)cc3c3cccc1c32] | 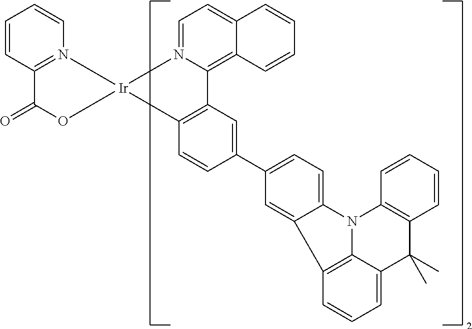 | 27% |
| K75 | Ir(L1Br)₂(CL4) | 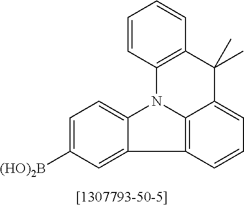 [SMILES: CC1(C)c2ccccc2-n2c3ccc(B(O)O)cc3c3cccc1c32] | 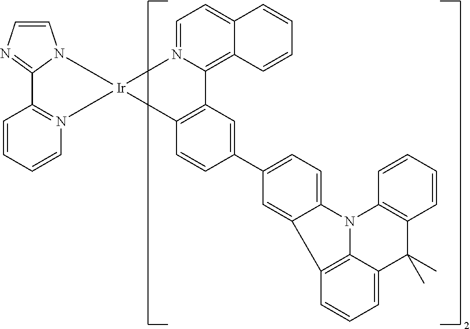 | 33% |
| K76 | Ir(L1Br)₂(CL5) | 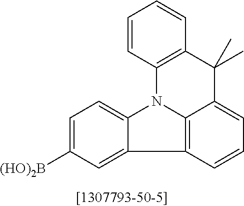 [SMILES: CC1(C)c2ccccc2-n2c3ccc(B(O)O)cc3c3cccc1c32] | 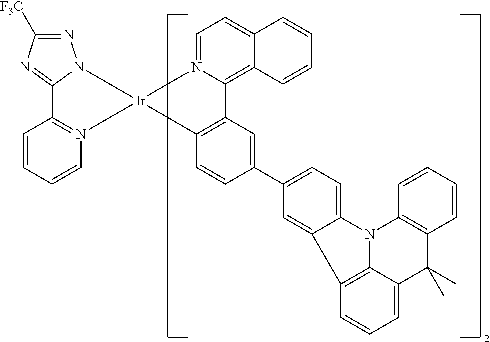 | 38% |
| K77 | Ir(L1Br)₂(CL6) | 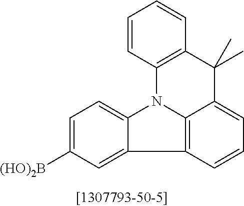 [SMILES: CC1(C)c2ccccc2-n2c3ccc(B(O)O)cc3c3cccc1c32] | 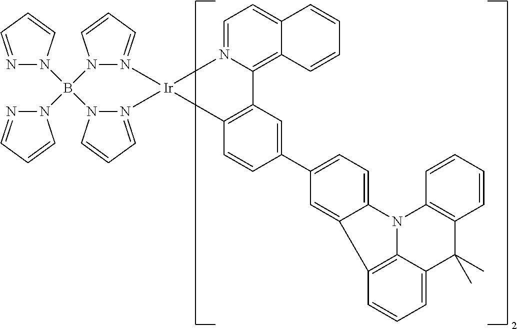 | 19% |
| K78 | Ir(L5Br)₂(CL1) | 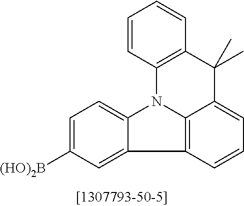 [SMILES: CC1(C)c2ccccc2-n2c3ccc(B(O)O)cc3c3cccc1c32] | 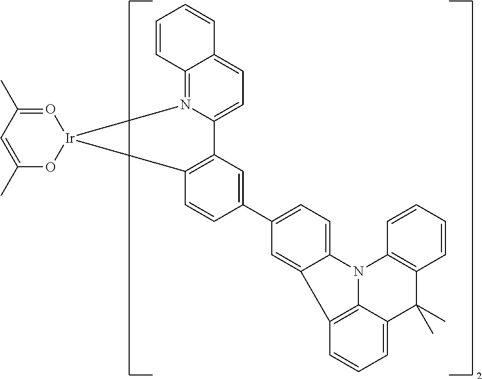 | 42% |
| K79 | Ir(L2Br)₂(CL1) | 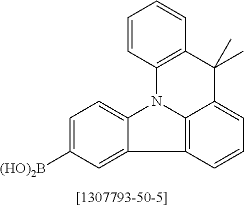 [SMILES: CC1(C)c2ccccc2-n2c3ccc(B(O)O)cc3c3cccc1c32] | 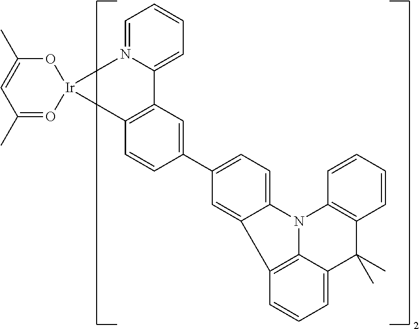 | 57% |
| K80 | Ir(L2Br)₂(CL2) | 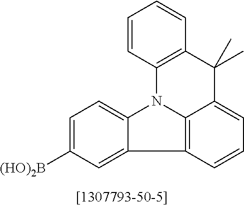 [SMILES: CC1(C)c2ccccc2-n2c3ccc(B(O)O)cc3c3cccc1c32] | 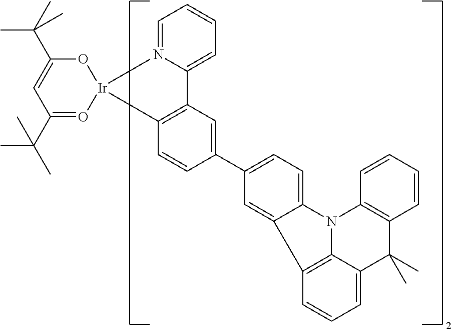 | 43% |
| K81 | Ir(L2Br)₂(CL2) | 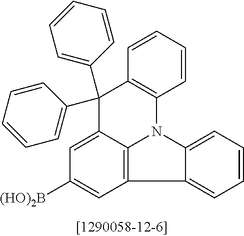 [SMILES: OB(O)c1cc2c3c(c1)c1ccccc1n3-c1ccccc1C2(c1ccccc1)c1ccccc1] | 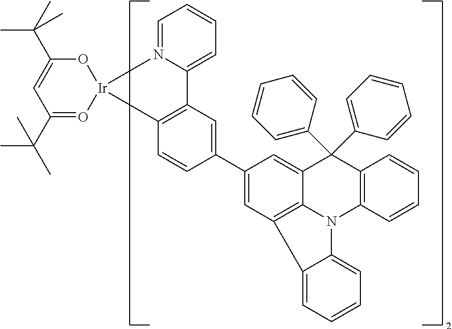 | 28% |
| K82 | Ir(L2Br)₂(CL2) | 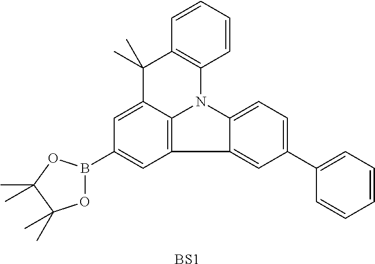 [SMILES: CC1(C)c2ccccc2-n2c3ccc(-c4ccccc4)cc3c3cc(B4OC(C)(C)C(C)(C)O4)cc1c32 ; "BS1"] | 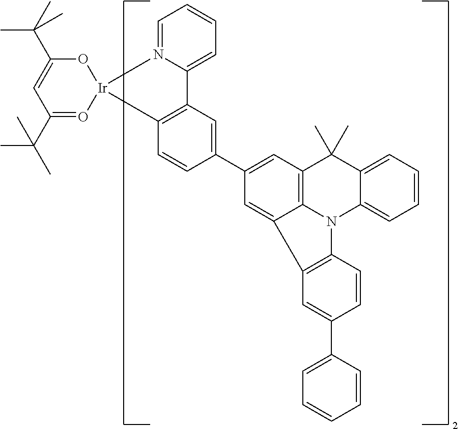 | 35% |
| K83 | Ir(L2Br)₂(CL2) | 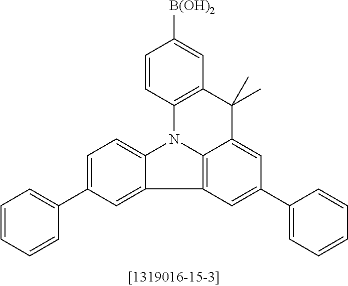 [SMILES: CC1(C)c2cc(B(O)O)ccc2-n2c3ccc(-c4ccccc4)cc3c3cc(-c4ccccc4)cc1c32] | 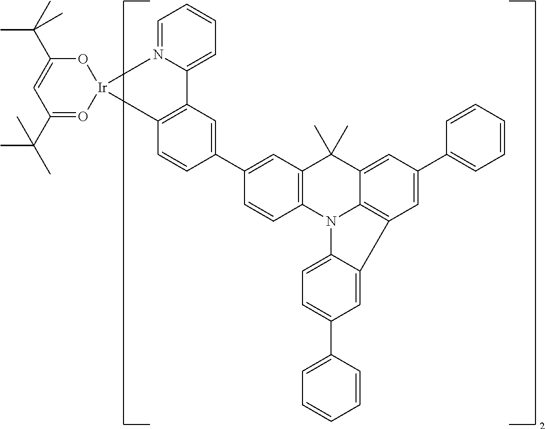 | 31% |
| K84 | Ir(L2Br)₂(CL2) | 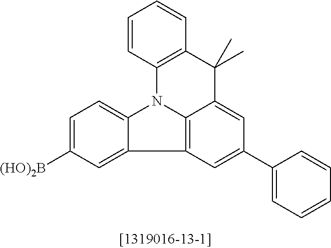 [SMILES: CC1(C)c2ccccc2-n2c3ccc(B(O)O)cc3c3cc(-c4ccccc4)cc1c32] | 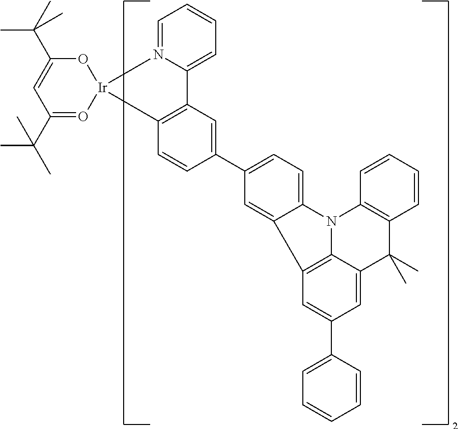 | 36% |
| K85 | Ir(L2Br)₂(CL3) | 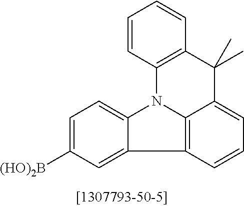 [SMILES: CC1(C)c2ccccc2-n2c3ccc(B(O)O)cc3c3cccc1c32] | 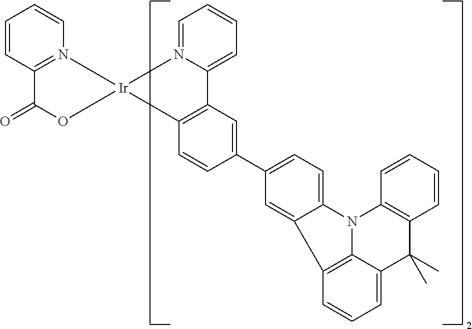 | 40% |

### F.5.2) K86/Bis-{1-[3-(8,8-dimethyl-4H-indolo[3,2,1-de]acridin-3-yl)phen-1-yl]isoquinolinato}-(2-phenylpyridinato)iridium(III)

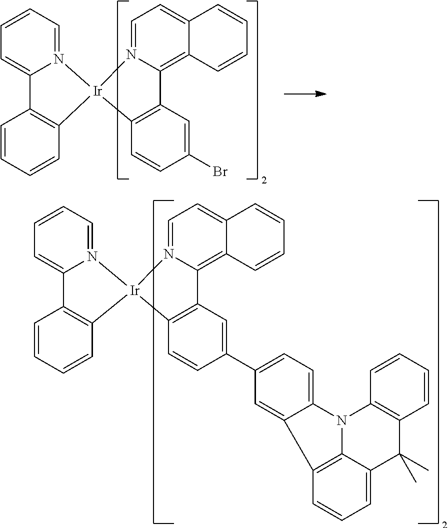

3.65 g (4.0 mmol) of bis-[1-(3-bromophenyl)isoquinolinato]-(2-phenylpyridinato)iridium(III) are heated to reflux together with 2.91 g (8.9 mmol) of 8,8-dimethyl-8H-indolo[3,2,1-de]acridin-3-ylboronic acid [1307793-50-5], 4.15 g (18.0 mmol) of potassium phosphate monohydrate, 53.9 mg (0.24 mmol) of palladium(II) acetate and 0.3 mL (0.30 mmol) of tri-t-butylphosphine solution (1M in toluene) in a mixture of 150 mL of toluene, 100 mL of dioxane and 50 mL of water while stirring vigorously for 15 h. After cooling to room temperature, the phases are separated. The aqueous phase is washed three times with 100 mL each time of toluene. The combined organic phases are washed three times with 250 mL each time of water, dried over MgSO₄ and concentrated under reduced pressure to about 150 mL. 450 mL of ethanol are slowly added dropwise while stirring, then the suspension is stirred for a further 1 h. The solids are filtered off with suction, washed twice with 50 mL each time of ethanol, dried under reduced pressure and then extracted in a hot extractor with about 250 mL of xylene over 50 g of alumina (basic, activity level 1). The solvent is concentrated under reduced pressure to about 50 mL. The suspension is stirred for a further 1 h, then the solids are filtered off with suction and dried under reduced pressure. The product is purified by chromatography using silica gel with a heptane/dichloromethane mixture (90:10 v:v), freed of the solvent under reduced pressure and finally heated at 300° C. under high vacuum (pressure about 10⁻⁶ mbar). This leaves 2.16 g (1.6 mmol, 41% of theory) as a red powder having a purity of 99.8% by HPLC.

In an analogous manner, it is possible to prepare the complexes K87 to K108.

| | | Reactant 2 | | |
|---|---|---|---|---|
| Ex. | Reactant 1 | [CAS] or Ex. | Product | Yield |
| K87 | Ir(L5Br)₂(CL7) | 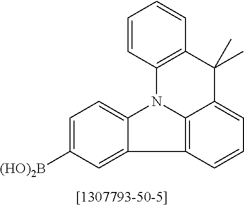 [SMILES: CC1(C)c2ccccc2-n2c3ccc(B(O)O)cc3c3cccc1c32] | 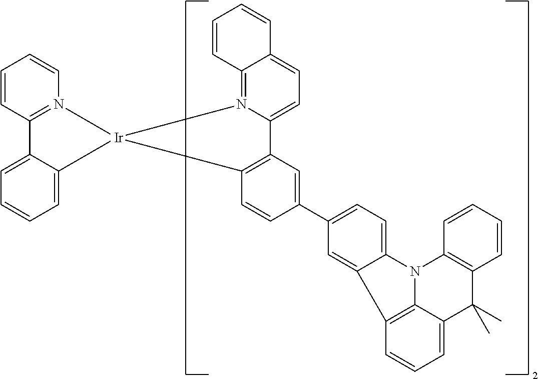 | 47% |
| K88 | Ir(L5Br)₂(CL7) | 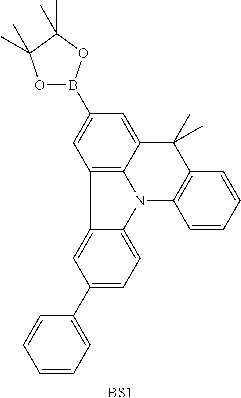 | 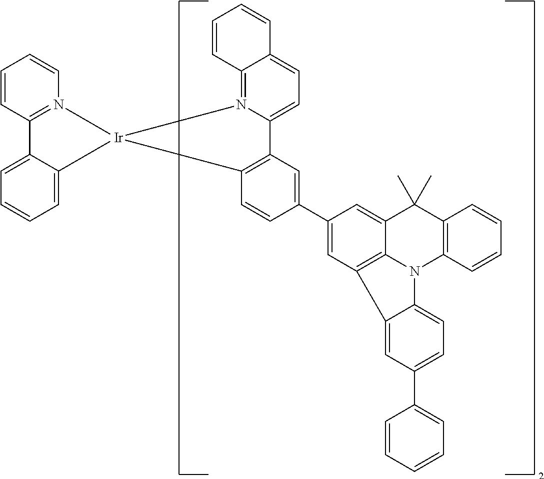 | 38% |
| K89 | Ir(L1Br)₂(CL8) | 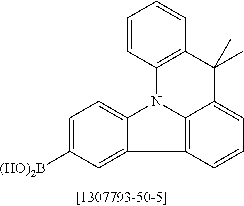 [SMILES: CC1(C)c2ccccc2-n2c3ccc(B(O)O)cc3c3cccc1c32] | 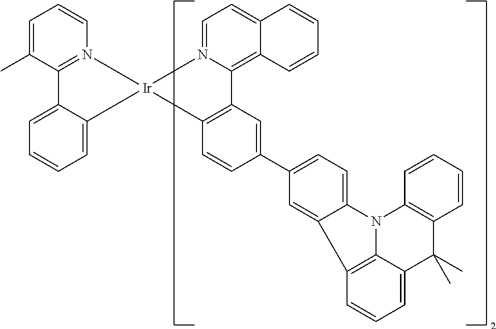 | 42% |
| K90 | Ir(L1Br)₂(CL9) | 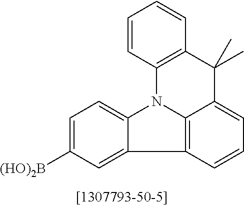 [SMILES: CC1(C)c2ccccc2-n2c3ccc(B(O)O)cc3c3cccc1c32] | 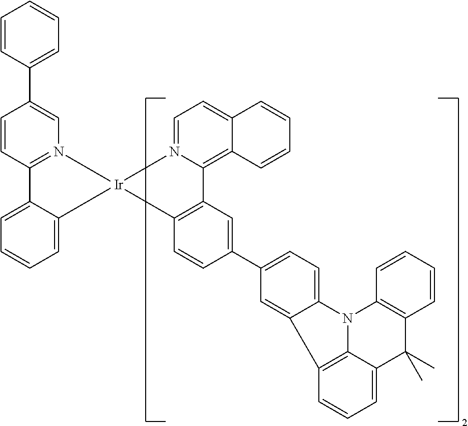 | 39% |
| K91 | Ir(L1Br)₂(CL10) | 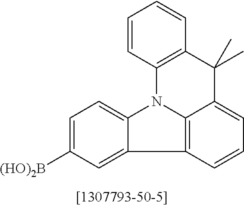 [SMILES: CC1(C)c2ccccc2-n2c3ccc(B(O)O)cc3c3cccc1c32] | 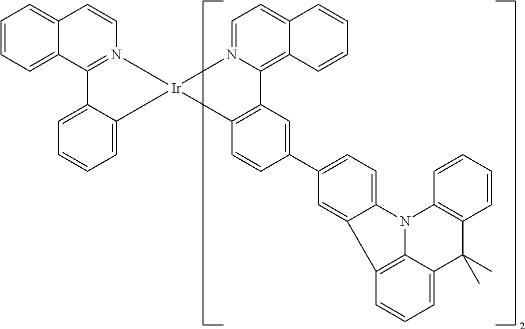 | 38% |
| K92 | Ir(L1Br)₂(CL10) | 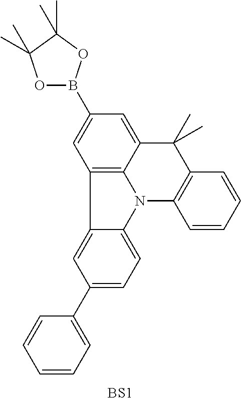 | 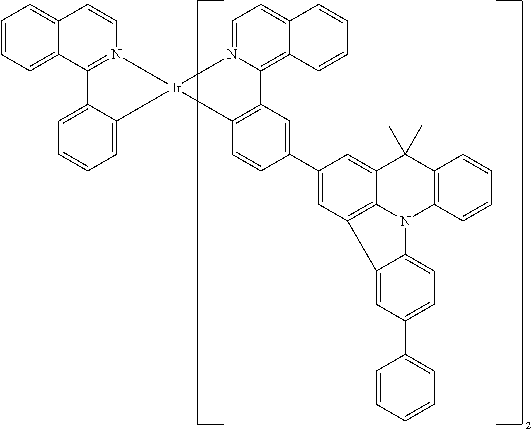 | 28% |
| K93 | Ir(L1Br)₂(CL11) | 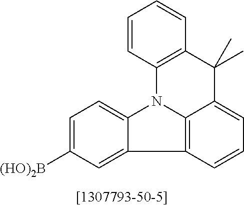 [SMILES: CC1(C)c2ccccc2-n2c3ccc(B(O)O)cc3c3cccc1c32] | 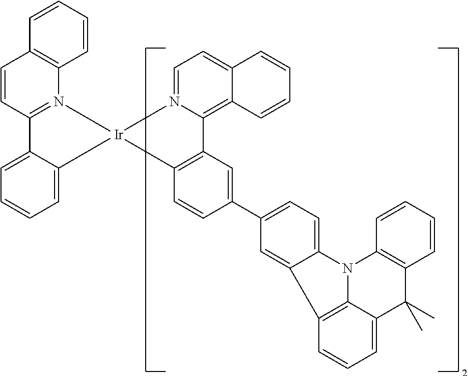 | 31% |
| K94 | Ir(L1Br)₂(CL12) | 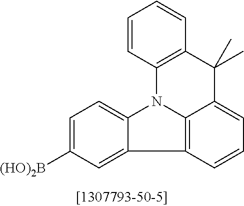 [SMILES: CC1(C)c2ccccc2-n2c3ccc(B(O)O)cc3c3cccc1c32] | 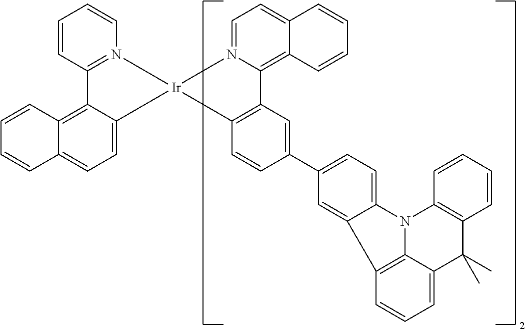 | 40% |
| K95 | Ir(L1Br)₂(L6) | 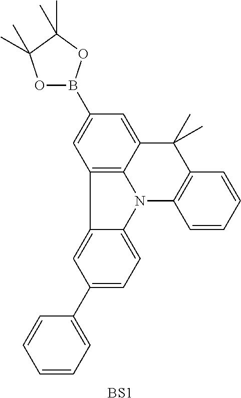 | 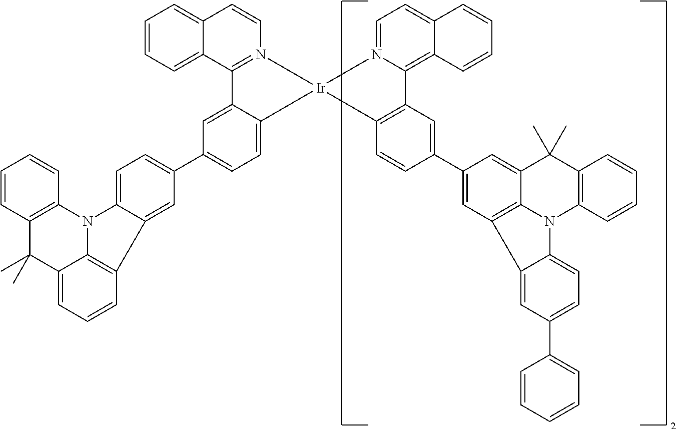 | 34% |
| K96 | Ir(L5Br)₂(L6) | 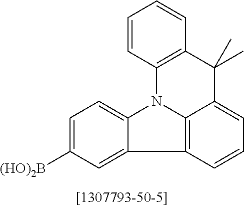 [SMILES: CC1(C)c2ccccc2-n2c3ccc(B(O)O)cc3c3cccc1c32] | 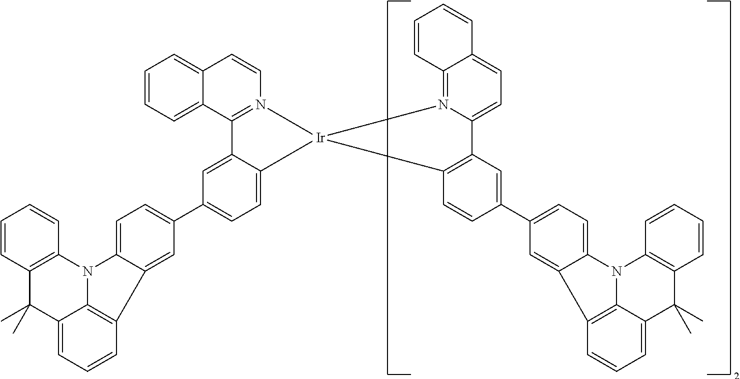 | 21% |
| K97 | Ir(L5Br)₂(L6) | 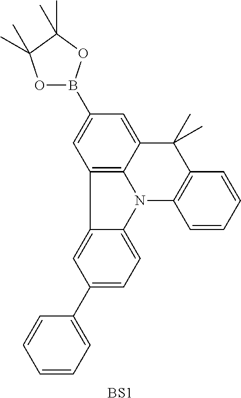 | 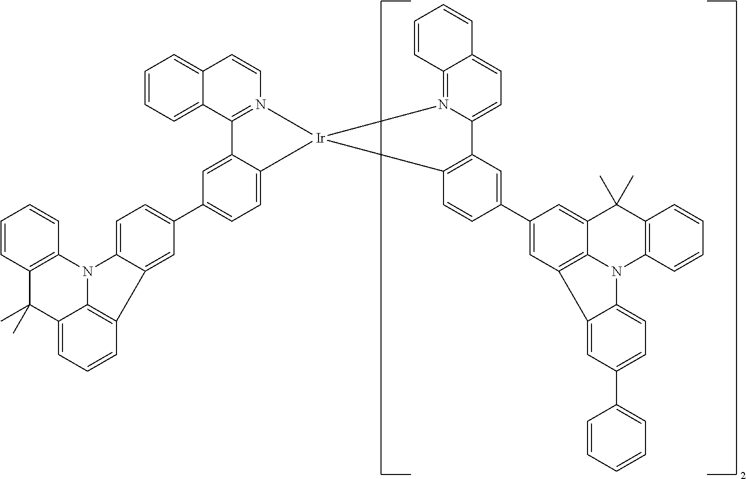 | 17% |
| K98 | Ir(L1Br)₂(L7) | 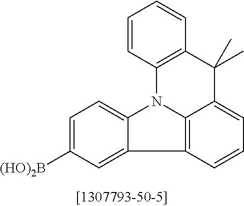 [SMILES: CC1(C)c2ccccc2-n2c3ccc(B(O)O)cc3c3cccc1c32] | 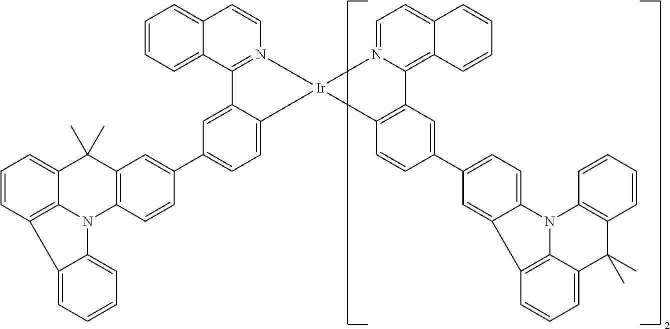 | 32% |
| K99 | Ir(L1Br)₂(L8) | 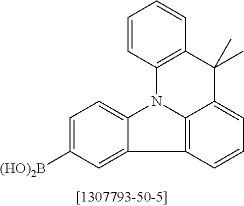 [SMILES: CC1(C)c2ccccc2-n2c3ccc(B(O)O)cc3c3cccc1c32] | 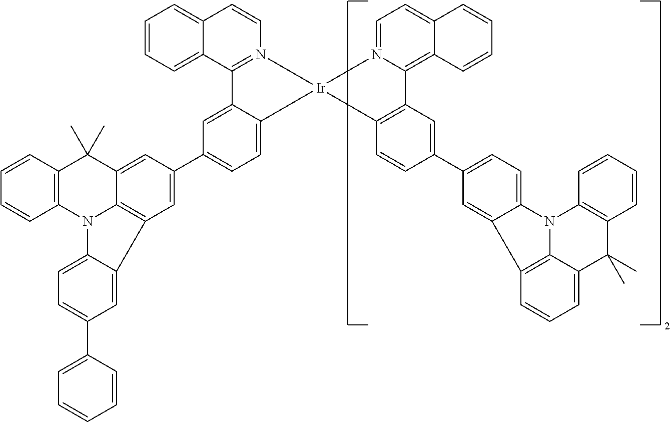 | 39% |
| K100 | Ir(L5Br)₂(L8) | 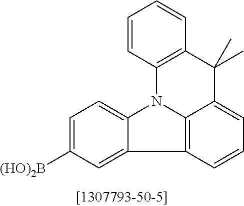 [SMILES: CC1(C)c2ccccc2-n2c3ccc(B(O)O)cc3c3cccc1c32] | 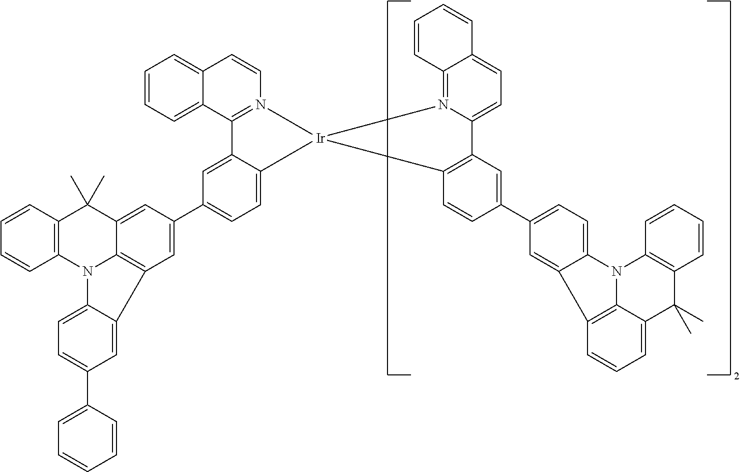 | 21% |
| K101 | Ir(L1Br)₂(L9) | 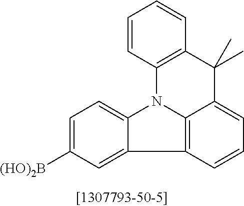 [SMILES: CC1(C)c2ccccc2-n2c3ccc(B(O)O)cc3c3cccc1c32] | 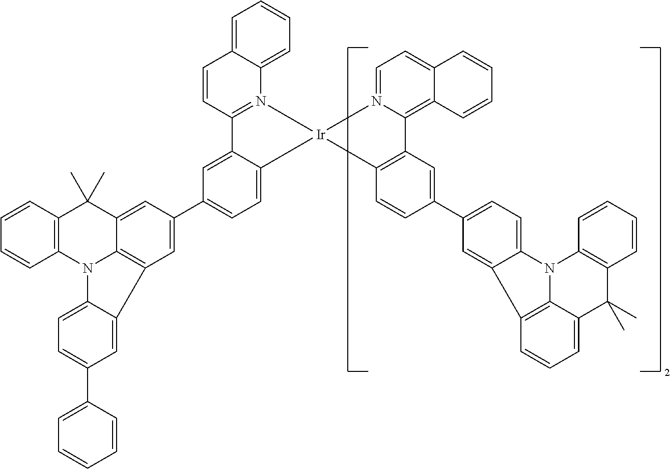 | 15% |
| K102 | Ir(L1Br)₂(L10) | 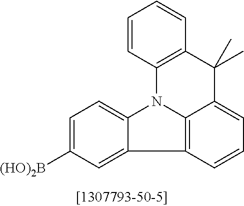 [SMILES: CC1(C)c2ccccc2-n2c3ccc(B(O)O)cc3c3cccc1c32] | 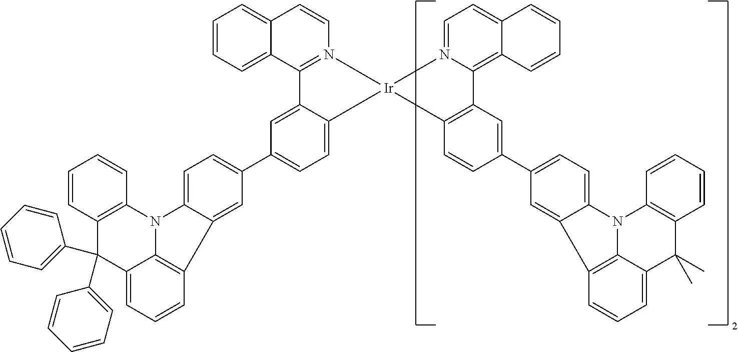 | 27% |
| K103 | Ir(L1Br)₂(L11) | 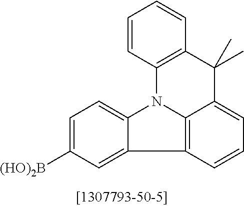 [SMILES: CC1(C)c2ccccc2-n2c3ccc(B(O)O)cc3c3cccc1c32] | 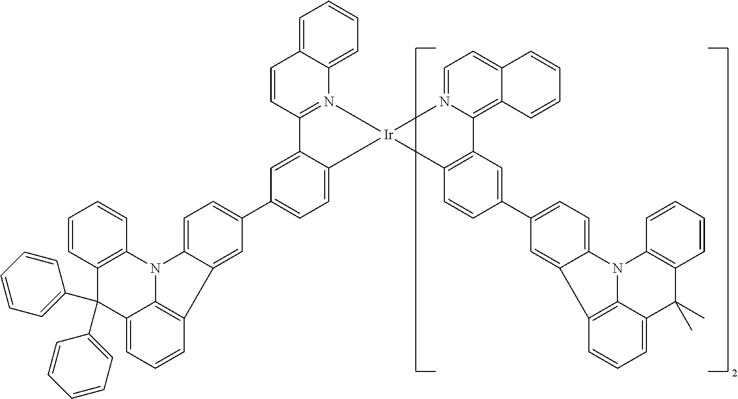 | 12% |
| K104 | Ir(L1Br)₂(L12) | 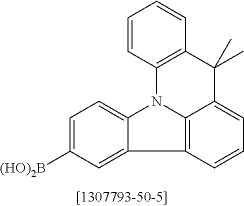 [SMILES: CC1(C)c2ccccc2-n2c3ccc(B(O)O)cc3c3cccc1c32] | 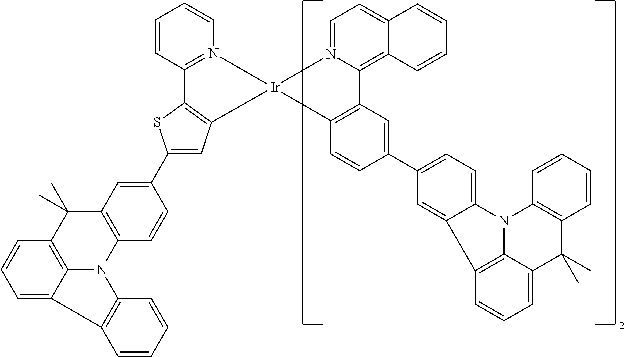 | 24% |
| K105 | Ir(L1Br)₂(L13) | 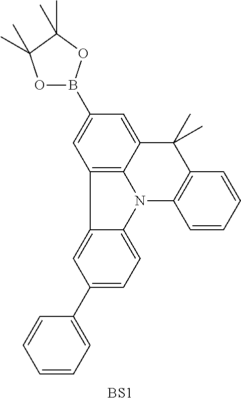 | 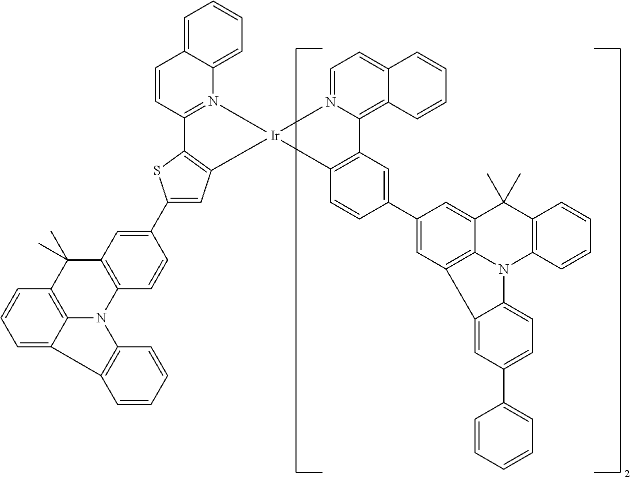 | 19% |
| K106 | Ir(L1Br)₂(L14) | 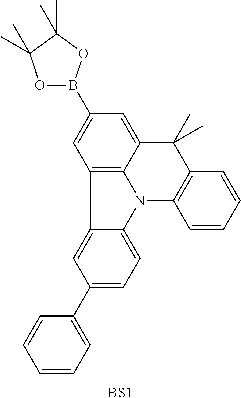 | 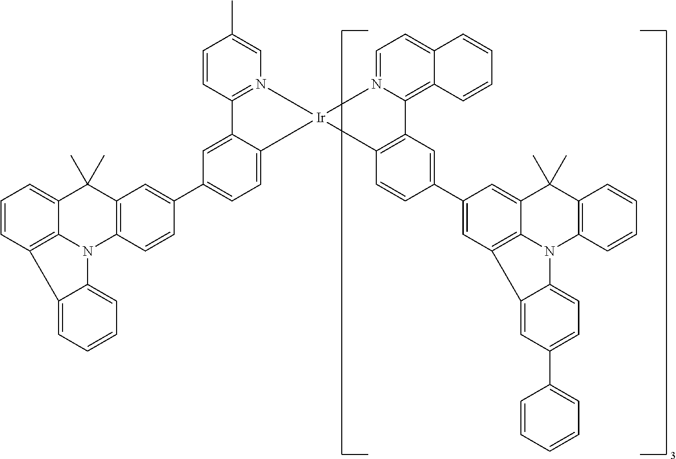 | 37% |
| K107 | Ir(L2Br)₂(L15) | 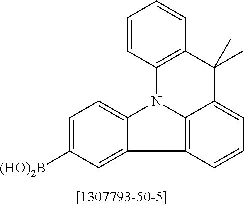 [SMILES: CC1(C)c2ccccc2-n2c3ccc(B(O)O)cc3c3cccc1c32] | 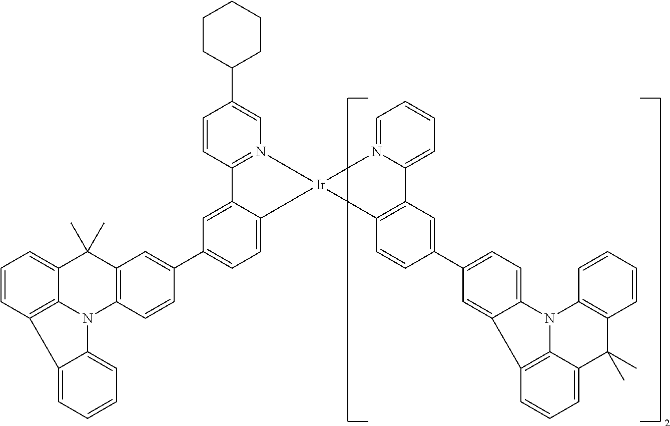 | 38% |
| K108 | Ir(L2Br)₂(L16) | 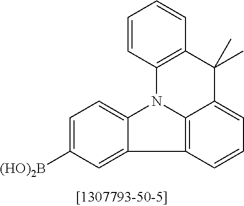 [SMILES: CC1(C)c2ccccc2-n2c3ccc(B(O)O)cc3c3cccc1c32] | 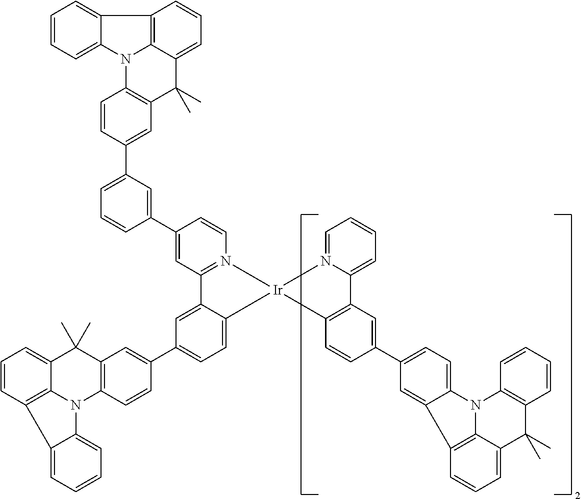 | 33% |

### G) Preparation of K109/bis-{1-[3-(8,8-dimethyl-8H-indolo[3,2,1-de]acridin-3-yl)phen-1-yl]pyridinato}platinum(II)

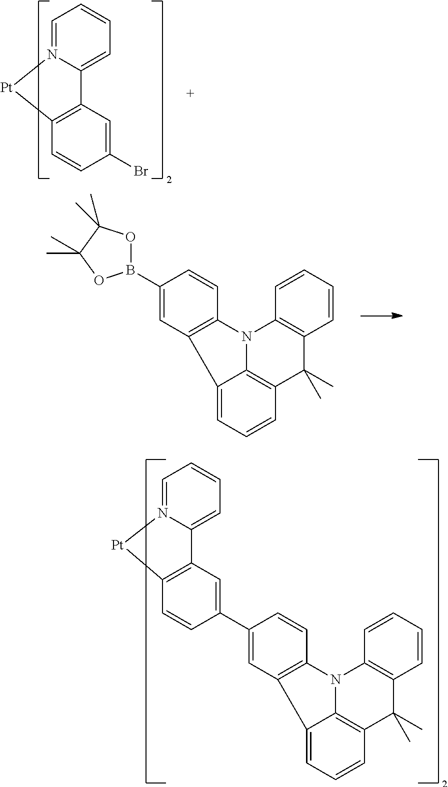

Bis[(3-bromophen-1-yl)pyridinato]platinum(II) can be prepared as described in WO 2004/041835. Bis{1-[3-(8,8-dimethyl-8H-indolo[3,2,1-de]acridin-3-yl)phen-1-yl]pyridinato}platinum(II) can be prepared therefrom analogously to the method described in F.1 from bis-[(3-bromophen-1-yl)pyridinato]platinum(II) and 8,8-dimethyl-8H-indolo[3,2,1-de]acridin-3-ylboronic acid [1307793-50-5].

### H) Preparation of Comparative Examples

### H.1) Preparation of Comparative Examples C1 and C2

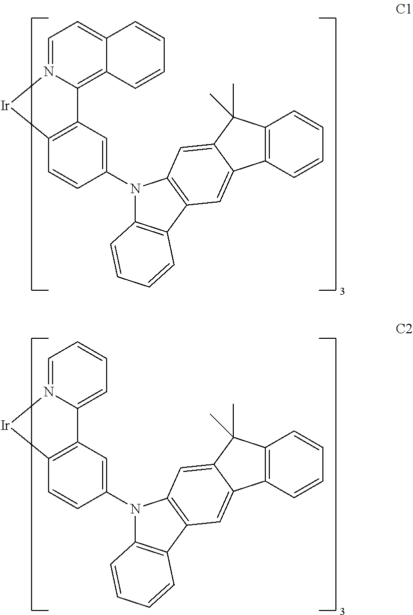

Comparative examples C1 and C2 can be prepared according to WO 2011/141120.

### H.2) Preparation of Comparative Examples C3 to C6

Comparative examples C3 to C6 can be prepared analogously to the methods described above:

| | | | | Preparation |
|---|---|---|---|---|
| Ex. | Reactant 1 | Reactant 2 | Product | as per |
| C3 | Ir(L1Br)₃ | 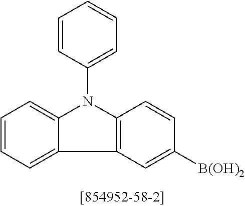 [SMILES: OB(O)c1ccc2c(c1)c1ccccc1n2-c1ccccc1] | 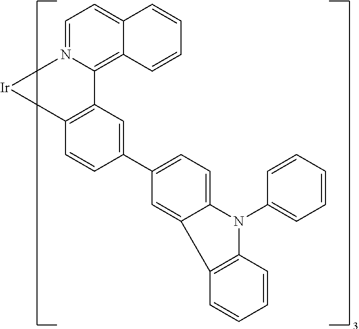 | F.1 |
| C4 | Ir(L3Br)₃ | 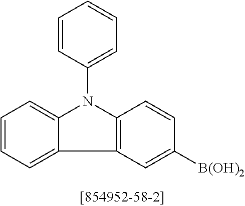 [SMILES: OB(O)c1ccc2c(c1)c1ccccc1n2-c1ccccc1] | 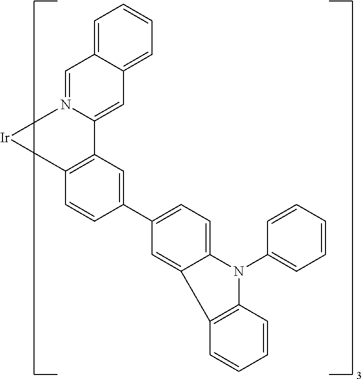 | F.2 |
| C5 | Ir(L4Br)₃ | 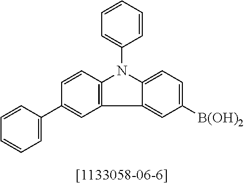 [SMILES: OB(O)c1ccc2c(c1)c1cc(-c3ccccc3)ccc1n2-c1ccccc1] | 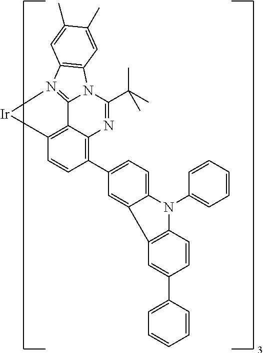 | F.4 |
| C6 | Ir(L5Br)₂(CL1) | 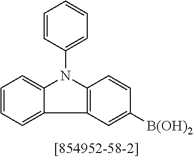 [SMILES: OB(O)c1ccc2c(c1)c1ccccc1n2-c1ccccc1] | 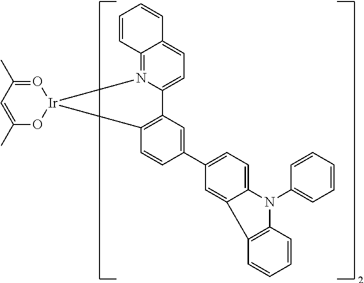 | F.5 |
| C7 | Ir(L1Br)₃ | 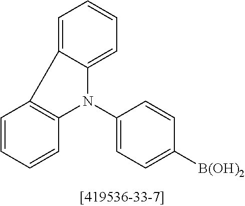 [SMILES: OB(O)c1ccc(-n2c3ccccc3c3ccccc32)cc1] | 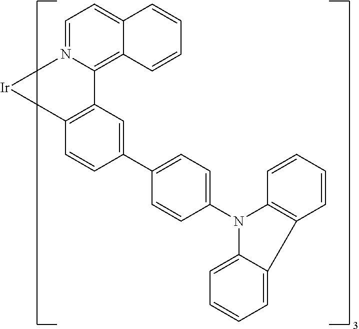 | F.1 |

### Example 1

### Photoluminescence in Solution

The complexes of the invention can be dissolved in toluene. The characteristic data of photoluminescence spectra of toluenic solutions of the complexes from table 1 are listed in table 2. This was done using solutions having a concentration of about 1 mg/mL and the optical excitation was conducted at the local absorption maximum (at about 450 nm for red complexes, about 380 nm for blue complexes, about 410 nm for green complexes). In the spectra, complexes of the invention exhibit a narrower half-height width and a red-shifted spectrum.

TABLE 1
Structures of complexes of the invention and of corresponding
comparative complexes in a photoluminescence study

| | |
|---|---|
| 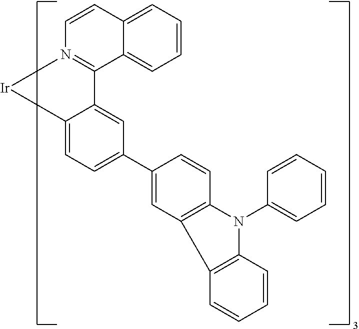 | C3 |
| 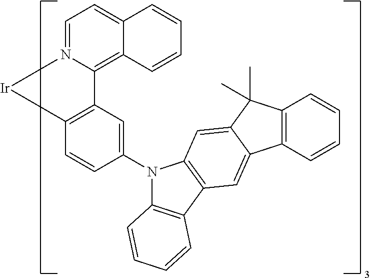 | C1 |
| 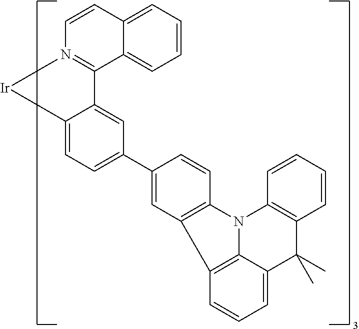 | K1 |
| 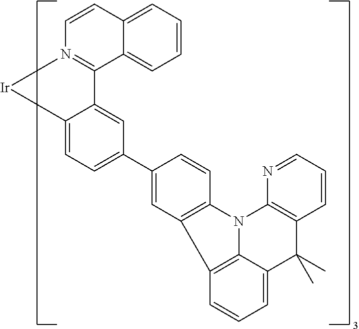 | K21 |
| 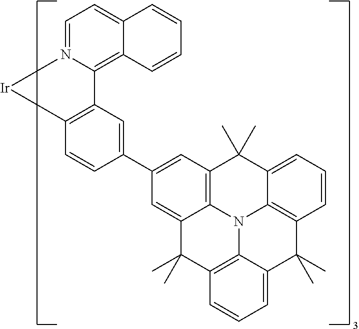 | K32 |
| 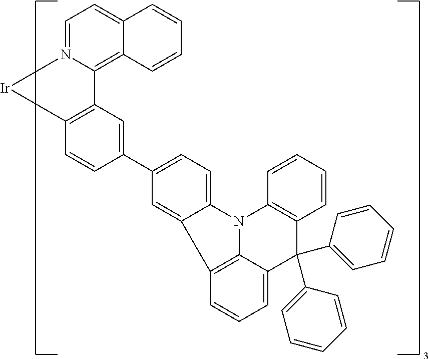 | K12 |
| 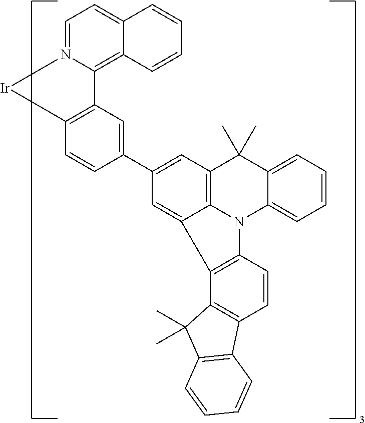 | K5 |
| 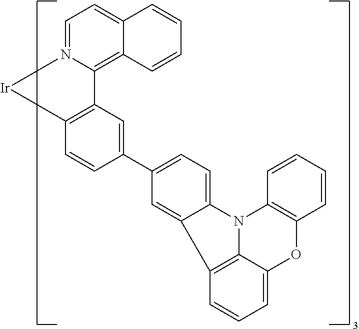 | K18 |
| 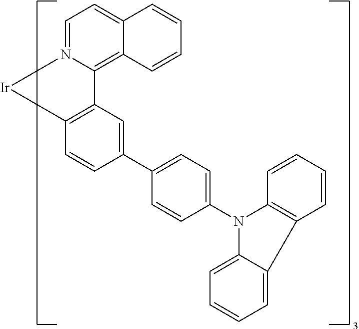 | C7 |
| 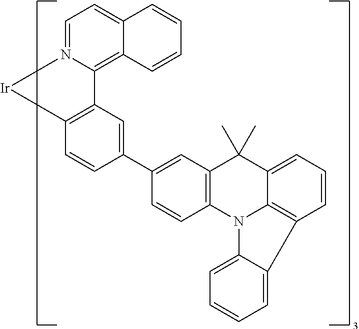 | K7 |
| 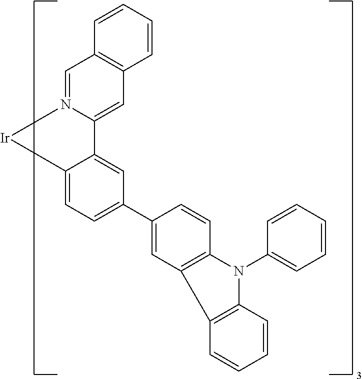 | C4 |
| 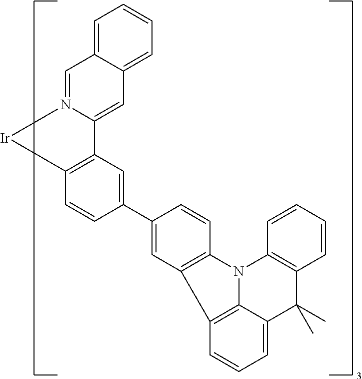 | K37 |
| 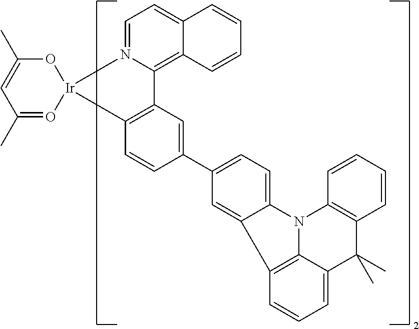 | K67 |
| 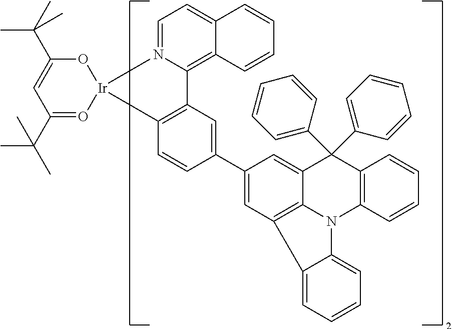 | K70 |
| 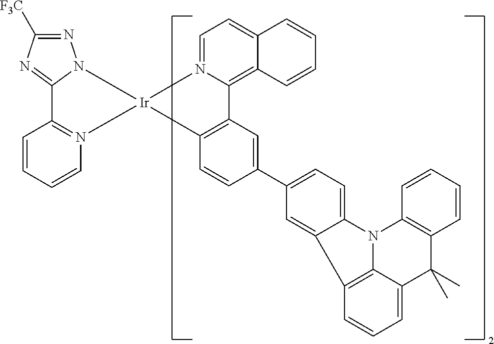 | K76 |
| 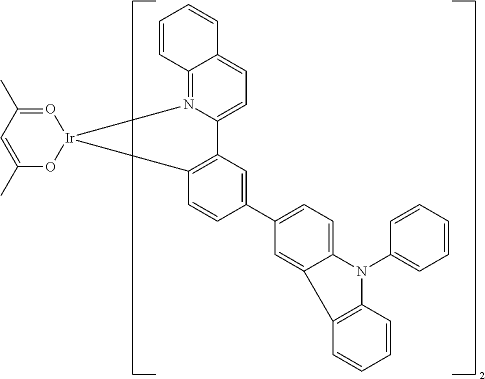 | C6 |
| 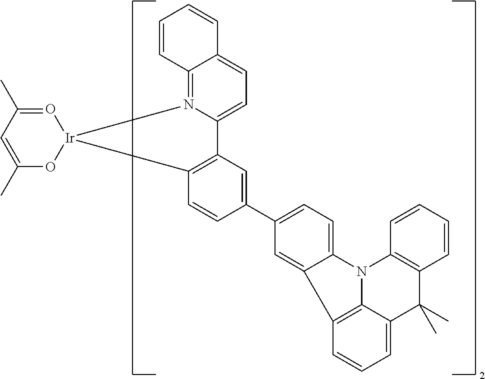 | K78 |
| 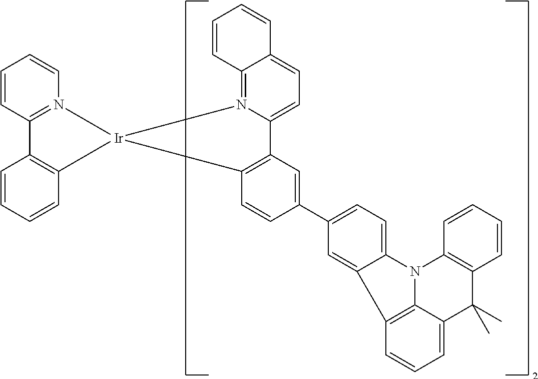 | K87 |
| 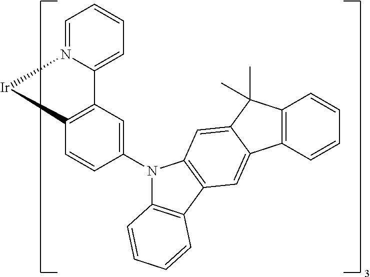 | C2 |
| 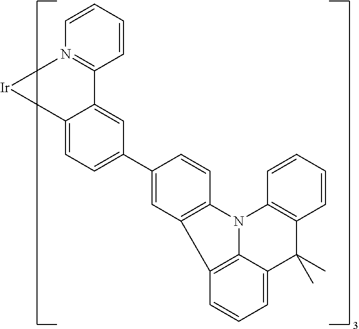 | K43 |
| 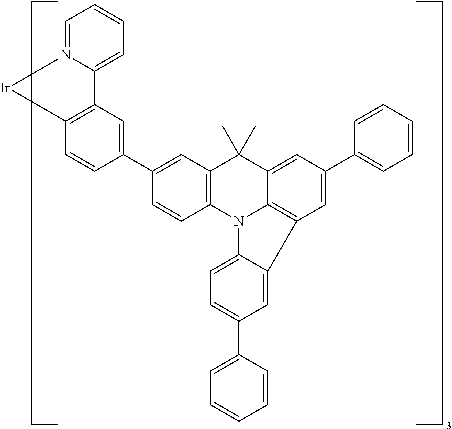 | K48 |
| 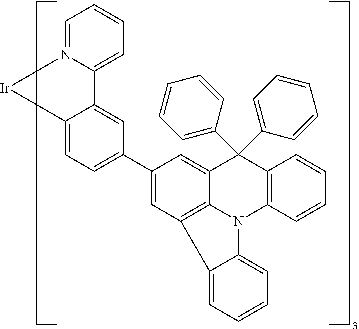 | K50 |
| 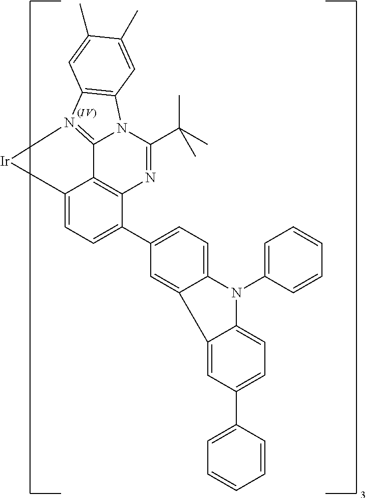 | C5 |
| 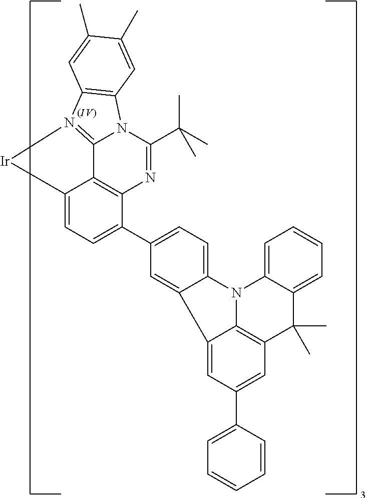 | K59 |

TABLE 2
Characteristic photoluminescence data

| | Emission max. | FWHM |
|---|---|---|
| | (nm) | (nm) |
| C3 | 620 | 74 |
| C1 | 617 | 73 |
| K1 | 628 | 65 |
| K21 | 629 | 66 |
| K32 | 631 | 62 |
| K12 | 624 | 64 |
| k5 | 624 | 64 |
| K18 | 628 | 62 |
| C7 | 620 | 75 |
| K7 | 627 | 65 |
| C4 | 589 | 87 |
| K37 | 591 | 75 |
| K67 | 634 | 61 |
| K70 | 626 | 66 |
| K76 | 629 | 66 |
| C6 | 603 | 70 |
| K78 | 611 | 61 |
| K87 | 599 | 66 |
| C2 | 517 | 62 |
| K43 | 519 | 57 |
| K48 | 525 | 57 |
| K50 | 518 | 56 |
| C5 | 483 | 55 |
| K59 | 485 | 49 |

### Example 2

### Production of the OLEDs

The complexes of the invention can be processed from solution and lead, compared to vacuum-processed OLEDs, to more easily producible OLEDs having properties that are nevertheless good. There are already many descriptions of the production of completely solution-based OLEDs in the literature, for example in WO 2004/037887. There have likewise been many previous descriptions of the production of vacuum-based OLEDs, including in WO 2004/058911.

In the examples discussed hereinafter, layers applied in a solution-based and vacuum-based manner were combined within an OLED, and so the processing up to and including the emission layer was effected from solution and in the subsequent layers (hole blocker layer and electron transport layer) from vacuum. For this purpose, the previously described general methods are matched to the circumstances described here (layer thickness variation, materials) and combined as follows:

The structure is as follows:
substrate,
ITO (50 nm),
PEDOT (80 nm or 20 nm, adapted for red or green emission layers),
interlayer (IL) (20 nm),
emission layer (EML) (60 nm),
hole blocker layer (HBL) (10 nm)
electron transport layer (ETL) (40 nm),
cathode.

Substrates used are glass plates coated with structured ITO (indium tin oxide) of thickness 50 nm. For better processing, they are coated with PEDOT:PSS (poly(3,4-ethylenedioxy-2,5-thiophene) polystyrenesulfonate, purchased from Heraeus Precious Metals GmbH & Co. KG, Germany). PEDOT:PSS is spun on from water under air and subsequently baked under air at 180° C. for 10 minutes in order to remove residual water. The interlayer and the emission layer are applied to these coated glass plates. The interlayer used serves for hole injection and is crosslinkable. A polymer of the structure shown below is used, which can be synthesized according to WO 2010/097155. The interlayer is dissolved in toluene. The typical solids content of such solutions is about 5 g/l when, as here, the layer thickness of 20 nm which is typical of a device is to be achieved by means of spin-coating. The layers are spun on in an inert gas atmosphere, argon in the present case, and baked at 180° C. for 60 minutes.

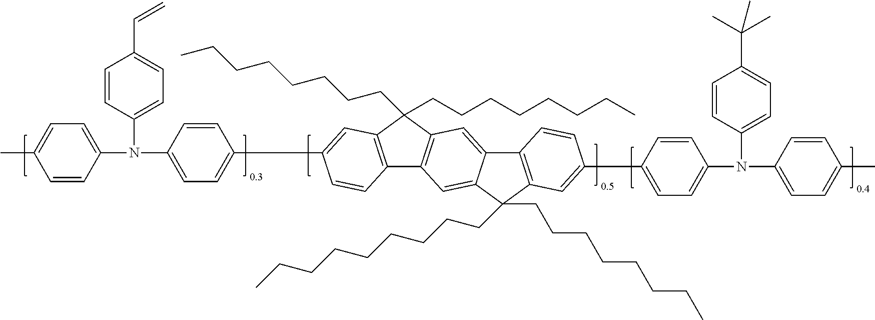

The emission layer is always composed of at least one matrix material (host material) and an emitting dopant (emitter). In addition, mixtures of a plurality of matrix materials and co-dopants may occur. Details given in such a form as TMM-A (92%):dopant (8%) mean here that the material TMM-A is present in the emission layer in a proportion by weight of 92% and dopant in a proportion by weight of 8%. The mixture for the emission layer is dissolved in toluene. The typical solids content of such solutions is about 18 g/l when, as here, the layer thickness of 60 nm which is typical of a device is to be achieved by means of spin-coating. The layers are spun on in an inert gas atmosphere, argon in the present case, and baked at 180° C. for 10 minutes. The materials used in the present case are shown in Table 3.

TABLE 3
EML materials used

| | |
|---|---|
| 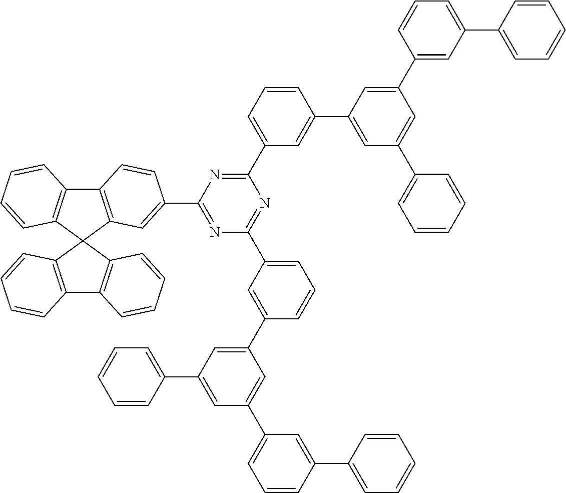 [SMILES: c1ccc(-c2cccc(-c3cc(-c4ccccc4)cc(-c4cccc(-c5nc(-c6cccc(-c7cc(-c8ccccc8)cc(-c8cccc(-c9ccccc9)c8)c7)c6)nc(-c6ccc7c(c6)C6(c8ccccc8-c8ccccc86)c6ccccc6-7)n5)c4)c3)c2)cc1] | TMM-A |
| 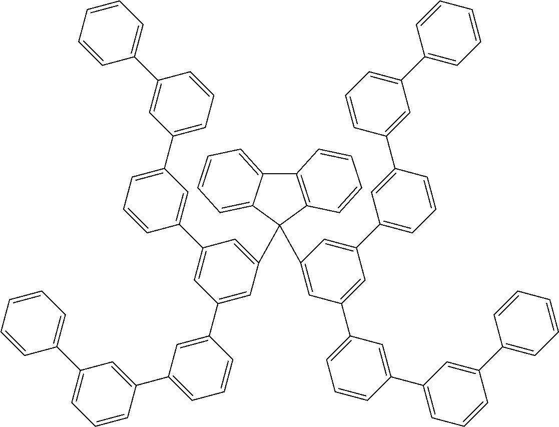 [SMILES: c1ccc(-c2cccc(-c3cccc(-c4cc(-c5cccc(-c6cccc(-c7ccccc7)c6)c5)cc(C5(c6cc(-c7cccc(-c8cccc(-c9ccccc9)c8)c7)cc(-c7cccc(-c8cccc(-c9ccccc9)c8)c7)c6)c6ccccc6-c6ccccc65)c4)c3)c2)cc1] | TMM-B |
| 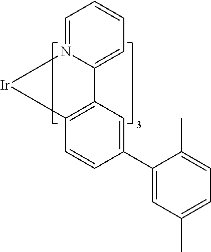 | Co-dopant C |

The materials for the hole blocker layer and electron transport layer are applied by thermal vapor deposition in a vacuum chamber. The electron transport layer, for example, may consist of more than one material, the materials being added to one another by co-evaporation in a particular proportion by volume. Details given in such a form as ETM1:ETM2 (50%:50%) mean here that the ETM1 and ETM2 materials are present in the layer in a proportion by volume of 50% each. The materials used in the present case are shown in Table 4.

TABLE 4
HBL and ETL materials used

| | |
|---|---|
| 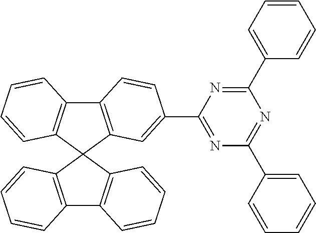 [SMILES: c1ccc(-c2nc(-c3ccccc3)nc(-c3ccc4c(c3)C3(c5ccccc5-c5ccccc53)c3ccccc3-4)n2)cc1] | ETM1 |
| 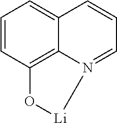 | ETM2 |

The cathode is formed by the thermal evaporation of a 100 nm aluminum layer. The OLEDs are characterized in a standard manner. For this purpose, the electroluminescence spectra, current-voltage-luminance characteristics (IUL characteristics) assuming Lambertian radiation characteristics and the (operating) lifetime are determined. The IUL characteristics are used to determine parameters such as the operating voltage (in V) and the external quantum efficiency (in %) at a particular brightness. The electroluminescence spectra are measured at a luminance of 1000 cd/m², and the CIE 1931 x and y color coordinates are calculated therefrom. LD80 @8000 cd/m² is the lifetime until the OLED, given a starting brightness of 8000 cd/m², has dropped to 80% of the starting intensity, i.e. to 6400 cd/m². Correspondingly, LD80 @10000 cd/m² is the lifetime until the OLED, given a starting brightness of 10 000 cd/m², has dropped to 80% of the starting intensity, i.e. to 8000 cd/m².

The data for OLEDs having an EML composed of 50% TMM-A, 35% TMM-B and 15% dopant D (according to table 1) are shown in table 5. In this case, ETM-1 is used as HBL and ETM1:ETM2 (50%: 50%) as ETL. It is found that complexes of the invention do not just have lower color coordinates, as already expected from the photoluminescence, but additionally also have an elevated external quantum efficiency coupled with comparable lifetime.

TABLE 5
Results for solution-processed OLEDs with EML mixtures of the
50% TMM-A, 35% TMM-B and 15% dopant D type

| | Efficiency at | Voltage at | CIE x/y at | | LD80 at |
|---|---|---|---|---|---|
| | 1000 cd/m² | 1000 cd/m² | 1000 cd/m² | | 8000 cd/m² |
| Dopant D | % EQE | [V] | x | y | [h] |
| C1 | 11.7 | 6.3 | 0.669 | 0.329 | 19 |
| K1 | 13.4 | 7 | 0.689 | 0.310 | 17 |
| K21 | 13.6 | 7.1 | 0.689 | 0.310 | 19 |
| K32 | 13.5 | 6.6 | 0.693 | 0.306 | 22 |
| K12 | 13.1 | 6.9 | 0.685 | 0.314 | 19 |
| K5 | 13.2 | 6.7 | 0.685 | 0.314 | 21 |
| K18 | 13 | 6.7 | 0.691 | 0.308 | 16 |
| C7 | 11.6 | 6.4 | 0.675 | 0.321 | 18 |
| K7 | 13.4 | 6.9 | 0.688 | 0.311 | 18 |
| K67 | 13.5 | 7.3 | 0.692 | 0.307 | 8 |
| K70 | 13.3 | 7 | 0.686 | 0.313 | 9 |
| K76 | 13.1 | 7 | 0.689 | 0.309 | 9 |
| C6 | 14.8 | 6.4 | 0.655 | 0.343 | 12 |
| K78 | 15.1 | 6.7 | 0.675 | 0.324 | 10 |
| K87 | 15.0 | 6.6 | 0.626 | 0.372 | 17 |

The data for OLEDs having an EML composed of 30% TMM-A, 34% TMM-B, 30% co-dopant C and 6% dopant D (according to table 1) are shown in table 6. In this case, ETM-1 is used as HBL and ETM1:ETM2 (50%:50%) as ETL. It is found that complexes of the invention generally have lower color coordinates and higher external quantum efficiencies than the corresponding reference complexes.

TABLE 6
Results for solution-processed OLEDs with EML mixtures of the
30% TMM-A, 34% TMM-B, 30% co-dopant C, 6% dopant D type

| | Efficiency at | Voltage at | CIE x/y at | | LD80 at |
|---|---|---|---|---|---|
| | 1000 cd/m² | 1000 cd/m² | 1000 cd/m² | | 8000 cd/m² |
| Dopant D | % EQE | [V] | x | y | [h] |
| C1 | 11.4 | 6 | 0.649 | 0.348 | 165 |
| K1 | 11.8 | 6.8 | 0.676 | 0.323 | 131 |
| K21 | 12.1 | 6.7 | 0.676 | 0.321 | 149 |
| K12 | 11.7 | 6.7 | 0.672 | 0.325 | 155 |
| K5 | 11.8 | 6.5 | 0.672 | 0.325 | 116 |
| K18 | 11.6 | 6.6 | 0.677 | 0.320 | 90 |
| K67 | 11.9 | 6.9 | 0.679 | 0.319 | 37 |
| K70 | 11.6 | 6.6 | 0.674 | 0.324 | 42 |
| K76 | 11.8 | 6.7 | 0.676 | 0.321 | 63 |
| C6 | 12.9 | 6.3 | 0.635 | 0.362 | 55 |
| K78 | 13.3 | 6.4 | 10.655 | 0.343 | 57 |

The data for OLEDs having an EML composed of 20% TMM-A, 50% TMM-B and 30% dopant D (according to table 1) are shown in table 7. In this case, ETM-1 is used as HBL and ETM1:ETM2 (50%:50%) as ETL. It is found that the complex of the invention has higher external quantum efficiencies than the reference complex.

TABLE 7
Results for solution-processed OLEDs with EML mixtures of the
20% TMM-A, 50% TMM-B and 30% dopant D type

| | Efficiency at | Voltage at | CIE x/y at | | LD80 at |
|---|---|---|---|---|---|
| | 1000 cd/m² | 1000 cd/m² | 1000 cd/m² | | 8000 cd/m² |
| Dopant D | % EQE | [V] | x | y | [h] |
| C2 | 17.9 | 4.9 | 0.313 | 0.639 | 128 |
| K43 | 19.1 | 5.2 | 0.322 | 0.630 | 142 |

1-15. (canceled)

16. A compound of formula (1):
M(L)ₙ(L′)ₘ (1)
wherein the compound of formula (1) contains a substructure M(L)ₙ of formula (2) or formula (3): 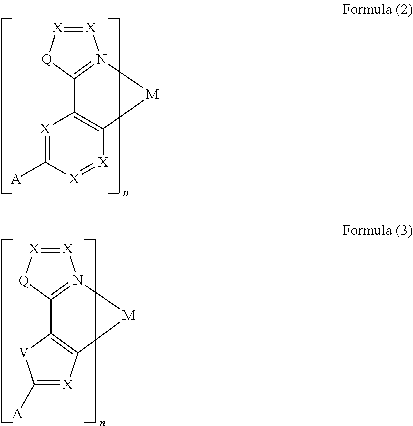
wherein A is the same or different in each instance and is a group of formula (A): 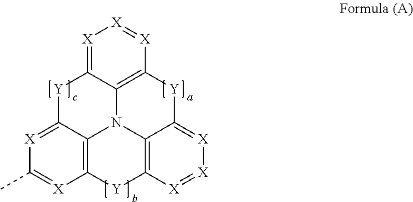
wherein the dotted bond in formula (A) denotes the position of the linkage of this group;
M is a metal selected from the group consisting of iridium, rhodium, platinum, and palladium;
X is the same or different in each instance and is CR¹ or N;
Q is the same or different in each instance and is R¹C═CR¹, R¹C═N, O, S, Se, or NR¹;
V is the same or different in each instance and is O, S, Se, or NR¹;
Y is the same or different in each instance and is a single bond or a bivalent group selected from the group consisting of C(R¹)₂, C(═O), O, S, NR¹, and BR¹;
R¹ is the same or different in each instance and is H, D, F, Cl, Br, I, N(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 40 carbon atoms, a straight-chain alkenyl or alkynyl group having 2 to 40 carbon atoms, or a branched or cyclic alkyl, alkenyl, alkynyl, alkoxy or thioalkoxy group having 3 to 40 carbon atoms, each of which is optionally substituted by one or more R² radicals, wherein one or more nonadjacent CH₂ groups are optionally replaced by R²C═CR², C≡C, Si(R²)₂, Ge(R²)₂, Sn(R²)₂, C═O, C═S, C═Se, C═NR², P(═O)(R²), SO, SO₂, NR², O, S, or CONR² and wherein one or more hydrogen atoms are optionally replaced by D, F, Cl, Br, I, CN, or NO₂, an aromatic or heteroaromatic ring system having 5 to 60 aromatic ring atoms and is optionally substituted in each case by one or more R² radicals, an aryloxy or heteroaryloxy group having 5 to 60 aromatic ring atoms and is optionally substituted by one or more R² radicals, or a diarylamino group, diheteroarylamino group, or arylheteroarylamino group having 10 to 40 aromatic ring atoms and is optionally substituted by one or more R² radicals, or a combination of two or more of these groups; and wherein two or more R¹ radicals together optionally define a mono- or polycyclic, aliphatic, aromatic and/or benzofused ring system;
R² is the same or different in each instance and is H, D, F, Cl, Br, I, N(R³)₂, CN, NO₂, Si(R³)₃, B(OR³)₂, C(═O)R³, P(═O)(R³)₂, S(═O)R³, S(═O)₂R³, OSO₂R³, a straight-chain alkyl, alkoxy, or thioalkoxy group having 1 to 40 carbon atoms, a straight-chain alkenyl or alkynyl group having 2 to 40 carbon atoms, or a branched or cyclic alkyl, alkenyl, alkynyl, alkoxy, or thioalkoxy group having 3 to 40 carbon atoms, each of which is optionally substituted by one or more R³ radicals, wherein one or more nonadjacent CH₂ groups are optionally replaced by R³C═CR³, C≡C, Si(R³)₂, Ge(R³)₂, Sn(R³)₂, C═O, C═S, C═Se, C═NR³, P(═O)(R³), SO, SO₂, NR³, O, S, or CONR³ and wherein one or more hydrogen atoms are optionally replaced by D, F, Cl, Br, I, CN, or NO₂, an aromatic or heteroaromatic ring system having 5 to 60 aromatic ring atoms and is optionally substituted by one or more R³ radicals, an aryloxy or heteroaryloxy group having 5 to 60 aromatic ring atoms and is optionally substituted by one or more R³ radicals, or a diarylamino group, diheteroarylamino group, or arylheteroarylamino group having 10 to 40 aromatic ring atoms and is optionally substituted by one or more R³ radicals, or a combination of two or more of these groups; and wherein two or more adjacent R² radicals together optionally define a mono- or polycyclic, aliphatic, aromatic, and/or benzofused ring system;
R³ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R³ substituents together optionally define a mono- or polycyclic, aliphatic, aromatic, and/or benzofused ring system;
L′ is the same or different in each instance and is a co-ligand;
n is 1, 2, or 3 when M is iridium or rhodium and is 1 or 2 when M is platinum or palladium;
m is 0, 1, 2, 3, or 4;
a, b, and c
is the same or different in each instance and is 0 or 1, wherein when a is 0 or b is 0 or c is 0, the respective Y group is absent and, instead, an R¹ radical is bonded to the corresponding carbon atoms in each case, with the proviso that a+b+c≧2; and
wherein two or more ligands L are optionally joined to one another or L is optionally joined to L′ via any bridge Z, thus forming a tridentate, tetradentate, pentadentate, or hexadentate ligand system.

17. The compound of claim 16, wherein zero or one X per cycle is N and the other X are CR¹.

18. The compound of claim 16, wherein in the group of formula (A), two of the indices a, b, and c is 1 and the third is 0.

19. The compound of claim 16, wherein the group of formula (A) is the same or different in each instance and is selected from the group consisting of formulae (A-1), (A-2), and (A-3): 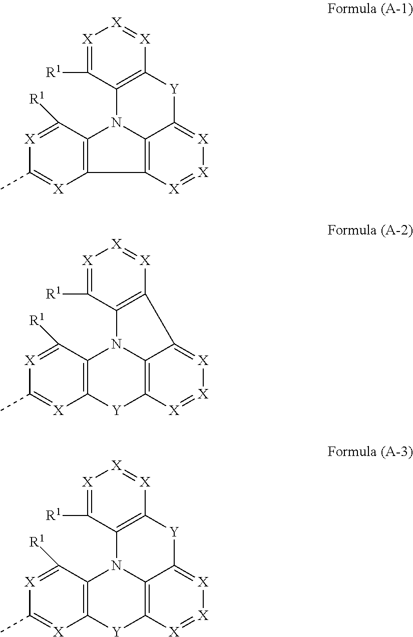
wherein Y is C(R¹)₂, NR¹, O, or S.

20. The compound of claim 19, wherein X is CR¹.

21. The compound of claim 16, wherein the group of formula (A) is the same or different in each instance and is selected from the group consisting of formulae (A-1b), (A-2b), and (A-3b):

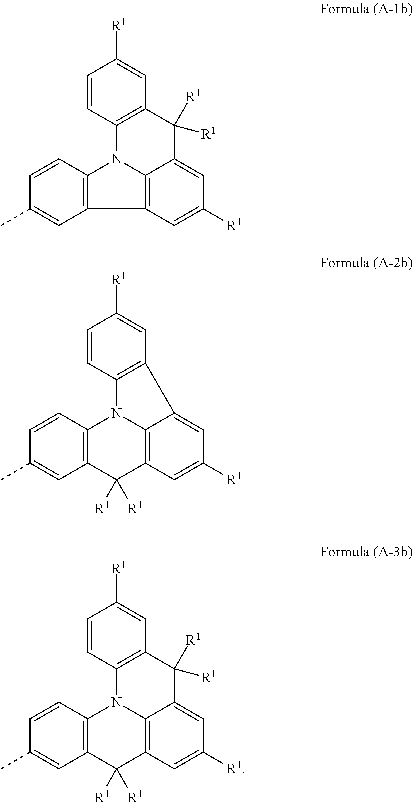

22. The compound of claim 19, wherein:
M is iridium or platinum;
X is the same or different in each instance and is CR¹;
Q is the same or different in each instance and is R¹C═CR¹ or R¹C═N;
V is the same or different in each instance and is O, S, or NR¹; and
Y is the same or different in each instance and is C(R¹)₂, NR¹, or O.

23. The compound of claim 21, wherein:
M is iridium;
X is the same or different at each instance and is CR¹;
Q is the same or different at each instance and is R¹C═CR¹;
V is S; and
Y is the same or different at each instance and is C(R¹)₂, NR¹, or O.

24. The compound of claim 16, wherein adjacent R¹ radicals together define a ring, wherein the substructures of formulae (2) or (3) are selected from the group consisting of substructures of formulae (4-1), (4-2), (4-3), (4-4), (5-1), (5-2), and (5-3):

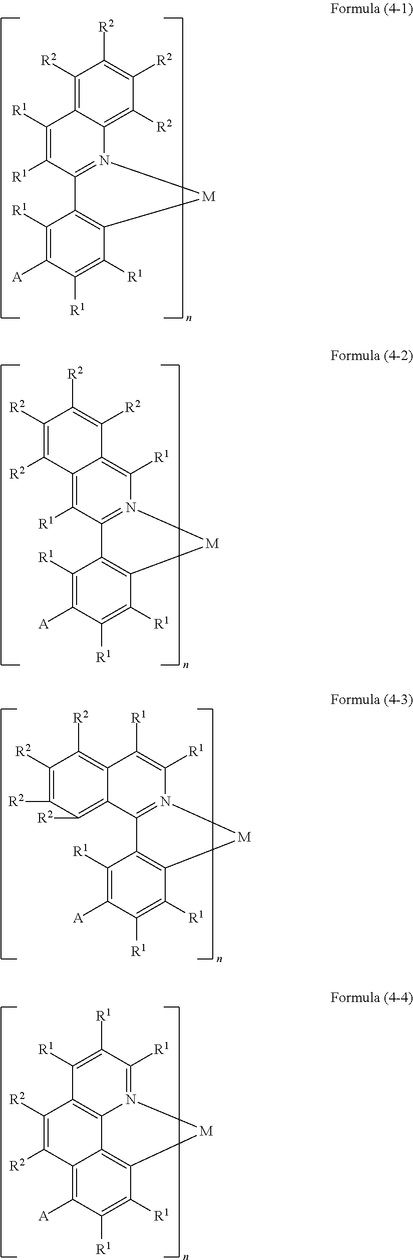

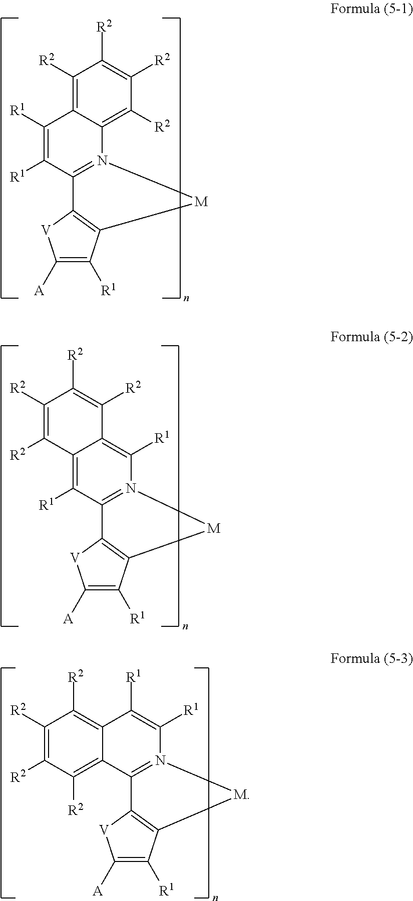

25. The compound of claim 16, wherein rather than one of the R¹ radicals, a bridging Z unit is present, and the compounds are selected from the group consisting of groups of formulae (6) to (9): 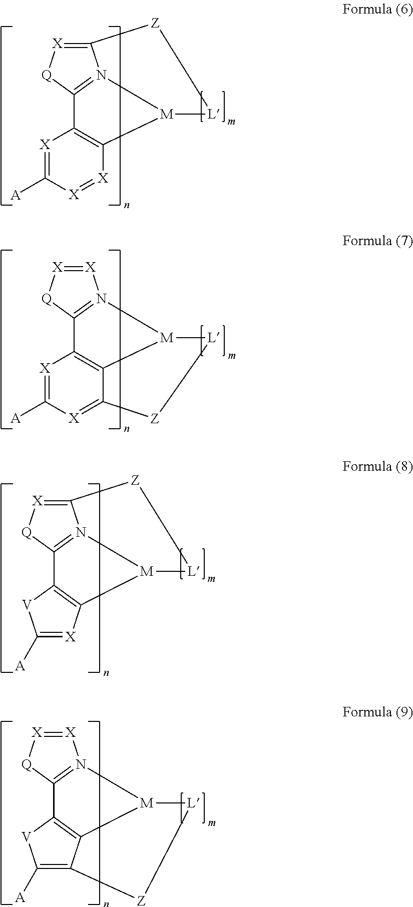
wherein Z is a bridging unit containing 1 to 80 atoms from the third, fourth, fifth, and/or sixth main groups or a 3- to 6-membered homo- or heterocycle which covalently bonds the sub-ligands L to one another or L to L′.

26. The compound of claim 16, wherein L′ is selected from the group consisting of carbon monoxide, nitrogen monoxide, alkyl cyanides, aryl cyanides, alkyl isocyanides, aryl isocyanides, amines, phosphines, phosphites, arsines, stibines, nitrogen-containing heterocycles, carbenes, hydride, deuteride, F⁻, Cl⁻, Br⁻, I⁻, alkylacetylidene, arylacetylidene, cyanide, cyanate, isocyanate, thiocyanate, isothiocyanate, aliphatic alkoxides, aromatic alkoxides, aliphatic thioalkoxides, aromatic thioalkoxides, amides, carboxylates, aryl groups, O²⁻, S²⁻, carbides, nitrenes, diamines, imines, diphosphines, 1,3-diketonates derived from 1,3-diketones, 3-ketonates derived from 3-keto esters, carboxylates derived from aminocarboxylic acids, salicyliminates derived from salicylimines, dialkoxides, dithiolates, borates of nitrogen-containing heterocycles, and bidentate monoanionic ligands which have, together with the metal, a cyclometalated five-membered ring or six-membered ring having at least one metal-carbon bond.

27. A process for preparing a compound of claim 16, comprising reacting the corresponding free ligands with a metal alkoxide of formula (55), a metal ketoketonate of formula (56), a metal halide of formula (57), a dimeric metal complex of formula (58), or a metal compound bearing both alkoxide and/or halide and/or hydroxyl radicals and ketoketonate radicals; 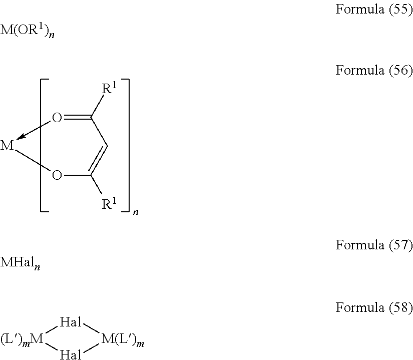
wherein Hal i F, Cl, Br, or I.

28. A formulation comprising at least one compound of claim 16 and at least one solvent.

29. An electronic device comprising at least one compound of claim 1.

30. The electronic device of claim 29, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells and organic laser diodes.

31. The electronic device of claim 30, wherein the electronic device is an organic electroluminescent device, wherein the compound is used as an emitting compound in one or more emitting layers, optionally in combination with a matrix material.
